(19) United States
(12) Patent Application Publication
(10) Pub. No.: US 2012/0313196 A1
(43) Pub. Date: Dec. 13, 2012

(54) 3-D TRENCH ELECTRODE DETECTORS

(75) Inventor: Zheng Li, South Setauket, NY (US)

(73) Assignee: Brookhaven Science Associates ,LLC et al., Upton, NY (US)

(21) Appl. No.: 13/503,015

(22) PCT Filed: Oct. 15, 2010
(86) PCT No.: PCT/US2010/052887

§ 371 Date: Jul. 10, 2012

Related U.S. Application Data
(60) Provisional application No. 61/252,756, filed on Oct. 19, 2009.

(51) Int. Cl. H01L 31/0224

(52) U.S. Cl. 257/429; 257/431; 257/443; 438/56; 438/57; 438/73; 257/E31.124

(57) ABSTRACT

A three-dimensional (3D) Trench detector and a method for fabricating the detector are disclosed. The 3D-Trench detector includes a bulk of semiconductor material that has first and second surfaces separated from each other by a bulk thickness, a first electrode in the form of a 3D-Trench, and a second electrode in the form of a 3D column. The first and second electrodes extend into the bulk along the bulk thickness. The first and second electrodes are separated from each other by a predetermined electrode distance, and the first electrode completely surrounds the second electrode along essentially the entire distance that the two electrodes extend into the bulk such that the two electrodes are substantially concentric to each other. The fabrication method includes doping a first narrow and deep region around the periphery of the bulk to form the first electrode, and doping a second narrow and deep region in the center of the bulk to form the second electrode.

### CROSS-REFERENCE TO A RELATED APPLICATION

This application claims the benefit under 35 U.S.C. 119(e) of U.S. Provisional Application No. 61/252,756 filed on Oct. 19, 2009, the content of which is incorporated herein in its entirety.

### STATEMENT OF GOVERNMENT LICENSE RIGHTS

The present invention was made with government support under contract number DE-AC02-98CH 10886 awarded by the U.S. Department of Energy. The United States government has certain rights in this invention.

### BACKGROUND OF THE INVENTION

I. Field of the Invention

This invention relates to radiation detectors. In particular, this invention relates to three dimensional detectors in which at least one of a plurality of electrodes is configured as a three-dimensional trench electrode.

II. Background of the Related Art

Radiation detectors are well known and are regularly used in various fields. Although originally developed for atomic, nuclear and elementary particle physics, radiation detectors can now be found in many other areas of science, engineering and everyday life. Some examples of the areas where radiation detectors are found are imaging in astronomy, medical imaging in medicine (e.g., positron emission tomography), and tracking detectors in high-energy physics, radiation-trace imaging in national security, among others. In experimental and applied particle physics and nuclear engineering, a radiation detector is a device used to detect, track and/or identify high-energy particles such as those produced by nuclear decay, cosmic radiation, or particles generated by reactions in particle accelerators. In order to detect radiation, it must interact with matter; and that interaction must be recorded. The main process by which radiation is detected is ionization, in which a particle interacts with atoms of the detecting medium and gives up part or all of its energy to the ionization of electrons (or generation of electron-hole pairs in semiconductors). The energy released by the particle is collected and measured either directly (e.g., by a proportional counter or a solid-state semiconductor detector) or indirectly (e.g., by a scintillation detector). Thus, there are many different types of radiation detectors. Some of the more widely known radiation detectors are gas-filed detectors, scintillation detectors and semiconductor detectors.

Gas-filled detectors are generally known as gas counters and consist of a sensitive volume of gas between two electrodes. The electrical output signal is proportional to the energy deposited by a radiation event or particle in the gas volume. Scintillation detectors consist of a sensitive volume of a luminescent material (liquid or solid), where radiation is measured by a device that detects light emission induced by the energy deposited in the sensitive volume.

Semiconductor detectors generally include a sensitive volume of semiconductor material placed between a positive electrode (anode) and a negative electrode (cathode). Incident radiation or particles are detected through their interactions with the semiconductor material, which creates electron-hole pairs. The number of electron-hole pairs created depends on the energy of the incident radiation/particles. A bias voltage is supplied to the electrodes, and thereby a strong electric field is applied to the semiconductor material. Under the influence of the strong electric field, the electrons and holes drift respectively towards the anode (+) and cathode (−). During the drift of the electrons and holes an induced charge is collected at the electrodes. The induced charge generates an electrical current which can be measured as a signal by external circuitry. Since the output signal is proportional to the energy deposited by a radiation event or particle in the semiconductor material, charge collection efficiency primarily depends on the depth of interaction of the incident radiation with the semiconductor material and on the transport properties (e.g., mobility and lifetime) of the electrons and holes generated. Thus, for optimal operation (e.g., maximum signal and resolution) of the detector, the collection of all electron-hole pairs (i.e. full depletion) is desirable. However, there are various aspects that prevent the semiconductor material from becoming fully depleted, and thus hinder optimal operation of the detector. Semiconductor detectors are produced mainly in two configurations: planar or two dimensional (2D) and three-dimensional (3D).

In FIG. 1A, a planar of 2D radiation detector 10 generally includes a bulk 20 of semiconductor material doped with n- or p-type dopant having a predetermined thickness d. A first region heavily doped with a first dopant (p⁺) formed on a first surface 22 of the semiconductor material defines a first collection electrode 30 (or anode); and a second region heavily doped with a second dopant (n⁺) formed on a second surface 24 of the bulk 20 defines a second collection electrode 40 (or cathode). The region of bulk 20 contained between first electrode 30 and second electrode 40 forms the sensitive volume (known as the depletion region) of the detector. A bias voltage is supplied to the collection electrodes 30, 40. Under irradiation, an ionizing particle 90 interacts with the sensitive volume of bulk 20 and generates pairs of electrons 60 and holes 50. The electrons and holes move under the influence of the applied voltage and induce an electrical current which can be measured as a signal by external circuitry.

In 2D detectors, one aspect that prevents full depletion is the thickness of the semiconductor material under a given bias voltage. Specifically, the drift path that the electrons and holes (charges) traverse before being collected by the electrodes can be very long. For example, some charges may be generated as far away as the full thickness of the semiconductor material from the collection electrode. In such a case, the collection of the charge can take a long time. Alternatively, if some radiation-generated charges occur close to the collection electrode, the collection of the charge can occur in a relatively short time. The average distance traveled by the collected charges is defined as the “drift length,” while the average time required for the electrons and/or holes to traverse the drift length and reach the electrode is defined as the “collection time.” The collection time of the induced charge depends, among other things, on the carrier's velocity which in turn depends on the electric field generated by the applied voltage. Accordingly, a high electric field (and thus a high bias voltage) is desirable for fast detector response and also for improved charge collection efficiency (CCE). The collection time can be reduced by operating the detector at bias voltages that exceed full depletion voltage (i.e., at “over depletion” voltages).

Another aspect that prevents full depletion in 2D detectors is radiation damage. The signal induced by the electron-hole pairs generated by an ionizing particle, for example, is proportional to the fraction of the thickness semiconductor material traversed by the particle. If the particle is stopped inside the semiconductor material, the measured charge is proportional to the energy of the particle; otherwise, if the particle traverses the semiconductor material, the measured signal is proportional to the energy loss of the particle. Particle stoppage or energy loss is due to, among other things, Coulomb interaction (e.g., scattering) of the electrons with the core of atoms of the semiconductor material. In particular, upon interaction of a high-energy particle with the semiconductor material, some atoms of the semiconductor material are displaced from their normal lattice position. The displacement of an atom leaves behind a vacancy which, together with the original atom at an interstitial (displaced) position, constitutes a Frenkel-Pair. Cascade of originally displaced atoms will cause more displacements, and vacancies and interstitials generated in the process can find themselves or impurities in the semiconductor to form stable point defects and defect clusters. Point defects and defect clusters act as trapping sites for the electron-hole pairs. The trapping site can capture a hole or an electron and keep it immobilized for a relatively long period of time. Although the trapping site may eventually release the trapped carrier, the time delay is often sufficiently long to delay the average collection time and/or to prevent the carrier from contributing to the measurable induced charge. Point defects and defect clusters also contribute significantly to the space charge in a semiconductor resulting in a significant increase in the detector full depletion voltage. This increase in the detector full depletion voltage prevents full depletion in a 2D detector in given, reasonable bias voltage.

In high-fluence irradiation environments, radiation effects such as carrier trapping in the semiconductor material significantly reduce the charge collection efficiency of a detector. At high irradiation fluences, there is a significant increase in trapping sites, which leads to incomplete depletion and reduces the effective drift length for both electrons and holes. In conventional 2D radiation detectors where the bulk thickness, and thus electrode spacing, is typically between 300 μm and 500 μm, the effective drift length of the generated carriers may be reduced to less than 50 μm after heavy irradiation. In effect, it has been generally observed that in 2D silicon (Si) detectors, for example, the effective drift length is reduced to about 20 μm after an irradiation of 1×10¹⁶ n^{eq}/cm². Thus, in conventional 2D detectors under high irradiation levels, the induced signal becomes small and could even be undetectable.

As a result, it is evident that excessively high bias voltages and/or extremely high irradiation levels not only negatively affect the charge collection efficiency of the detector, but may also physically damage the semiconductor material of the detector. In an effort to overcome the above described problems in conventional 2D detectors, a three-dimensional (3D) detector architecture has been developed. Conventional 3D semiconductor detectors (hereafter “3D detectors”) include an array of thin cylindrical electrodes that penetrate into the detector bulk. The basic components of a conventional 3D detector are depicted in FIG. 1B.

In FIG. 1B, 3D detector 100 is typically formed of a bulk 120 of semiconductor material, such as a wafer of silicon, and includes a plurality of cylindrical column-like electrodes penetrating into the bulk at a predetermined distance λ_{C} from each other. For good charge carrier detection, an electrode diameter of 10 μm and a separation between the electrodes of about 50 μm to 100 μm have been recognized as appropriate. Fabrication of the 3D detector involves forming an array of cylindrical holes in the bulk 120, and thereafter doping the surfaces or internal walls of the holes with predetermined doping materials and/or metals to thereby form the column-like cylindrical electrodes. In FIG. 1, bulk 120 has a predetermined thickness d which may range between a few hundred microns (μm) to a few millimeters (mm). Bulk 120 is typically made of a single crystal of semiconductor material, such as silicon, that is slightly doped with a predetermined type of dopant (p- or n-type). A first electrode 150 heavily doped with n-type dopant (n⁺) and a second electrode 160 heavily doped with p-type dopant (p⁺) penetrate bulk 120 and typically traverse the entire bulk 120 from a first surface 130 to a second surface 140. In the context of semiconductor diode junctions, in FIG. 1B, a p-n junction is formed between the first electrode 150 and the bulk 120 or between the second electrode 160 and the bulk 120, depending on the type of dopant of the bulk 120. For example, if bulk 120 is of the n-type, a p-n junction is formed in the region where the surface of second electrode 160 meets the semiconductor material of bulk 120. In such a case, the second electrode 160 is considered a “junction electrode.” Under the influence of the applied voltage (bias voltage) the electric field for charge collection is primarily radial, with a high field concentration in the region around the junction electrode and a low field concentration in the region close to the other electrode.

Radiation or particle 190 incident upon the sensitive volume of the 3D detector enters the bulk 120 in a direction substantially perpendicular to the first surface 130, and generates electron-hole pairs as it travels along the thickness d of the bulk 120 in a path substantially parallel to electrodes 150 and 160. The charge carriers (electron-hole pairs) generated along the path of particle 190 drift laterally towards electrodes 150 and 160. The drift of charge carriers induces a charge that is collected at the electrodes. As a result, charge carriers generated in a 3D detector only have to traverse the small distance separating the electrodes before being collected. Because the depletion of charge carriers in 3D detectors no longer depends on the thickness of the semiconductor material, but only on the separation of the electrodes, one of the advantages of 3D detectors over their 2D counterparts is that the detector full depletion voltage is independent of the bulk thickness. In order to improve CCE, the electrode separation can be made as close as physically possible. Placing the electrodes at a short distance from each other typically yields significantly shorter average drift lengths and a reduced collection time as compared to the drift lengths and collection time encountered in a 2D detector. Given that the path of the incident particle is substantially parallel to the electrodes, and given that the drift lengths are much shorter, the induced signal is detected much faster in a 3D detector than it is in a 2D detector.

A direct consequence of the above described structure is that the full depletion voltage in a 3D detector is insensitive to bulk thickness and depends on the electrode separation. Since the separation between electrodes can be made very small, a much lower voltage is required to fully deplete the 3D detector compared to that required in a 2D detector. In addition, with such a reduced electrode spacing, carrier trapping can be greatly reduced and the detector's CCE is improved. It is evident, therefore, that the 3D detector architecture provides faster collection times and higher radiation tolerance at much lower voltage biases compared to a conventional 2D detector architecture. However, 3D detectors still present major disadvantages and shortcomings, particularly under extremely high irradiation.

At least one such a shortcoming of 3D detectors is charge sharing due to the close electrode spacing. Specifically, as described above, in order to improve CCE, 3D electrodes in conventional 3D detectors are necessarily spaced very close to each other. On one hand, the small inter-electrode distance implies a higher capacitance between the electrodes, as compared to 2D detectors. On the other hand, at such short spacing distance, in multi-element (multi-pixel) detectors, charge sharing between adjacent pixels often occurs. In order to limit charge sharing between adjacent pixels, metal grids (also referred to as “collimators”) are accommodated on the surface of the detector. The application of a metal grid, which generally takes up a few hundred micrometers of space, disadvantageously adds a large dead space within the sensitive surface of the detector. Moreover, fabricating and implementing the metallic grid on the detector surface adds detector manufacturing costs and complicates detector operation.

Other disadvantages of conventional 3D detectors are the creation of highly non-uniform electric fields around the thin column electrodes and the possibility of radiation damage of the semiconductor material under extremely high levels of irradiation. In particular, the electric field is highly non-uniform within a unit cell (pixel) of the detector, and it gets worse under extremely high irradiation levels. During detection of high energy radiation, the electric field tends to be highly concentrated near the narrow junction electrode column. This highly concentrated electric field could reach, and sometimes surpass, the intrinsic breakdown limit of the detector's semiconductor material and substantially damage either the thin electrode or the bulk itself. This phenomenon may be particularly disadvantageous to detectors in high-energy physics applications. For example, it has been observed that after heavy irradiation, such as that experienced in particle colliders, the silicon lattice suffers severe radiation-induced defects that lead to excessive carrier trapping and ultimately to poor carrier collection efficiency. Thus, extremely high levels of irradiation in conventional 3D detectors can cause: 1) a non-uniform electric field highly concentrated around the narrow junction electrode which can induce intrinsic breakdown near or at the junction electrode; 2) regions with saddle electric potential that provides no or low electric field; 3) long carrier drift time in the low field region (causing incomplete charge collection); and 4) the need for a much higher depletion voltage, as compared to a 2D detector with a thickness equivalent to the column spacing of a 3D detector.

### SUMMARY

The existence of highly non-uniform electric fields around thin columnar electrodes, and radiation damage of the semiconductor material under high levels of radiation may be overcome by a 3D-Trench detector that has a plurality of electrodes and in which at least one of the plurality of electrodes is formed as a three-dimensional trench that surrounds a thin columnar electrode. In accordance with at least one embodiment of the present invention, a 3D-Trench detector so formed provides the following advantages: (1) the electric field profile in the detector is nearly uniform throughout the entire surface, preventing or minimizing the concentration of highly non-uniform electric fields around thin columnar electrodes; (2) the maximum electric field intensity required for full and over depletion of the detector is much lower than that of conventional 3D and 2D detectors, allowing for operation at bias voltages well bellow the breakdown limit of known semiconductor materials; (3) the detector thickness can be made as large as 2 mm, allowing for better detection efficiencies; (4) the pixel pitch in multi-pixel detectors can be made as large as 1 mm without requiring large bias voltages because much lower full depletion voltages are required in a 3D-Trench detector than in other detector structures; (5) the capacitance due to very a small area of the collecting electrode is small, improving the detector energy resolution; and (6) adjacent pixels are naturally isolated due to a dead space created by the trench walls, further improving detector energy resolution.

In a preferred embodiment, a radiation detector includes a bulk of semiconductor material that has first and second surfaces separated from each other by a predetermined bulk thickness. A first electrode highly doped with a first conductivity type dopant in the form of a hexagonal 3D trench, and a second electrode highly doped with a second conductivity type dopant in the form of a hexagonal 3D column are formed within the bulk. Preferably the first conductivity type dopant is different from the second conductivity type dopant. The first and second electrodes extend into the bulk from one of the first and second surfaces along the bulk thickness. The 3D-Trench detector of this embodiment is formed such that the first electrode surrounds the second electrode and the two electrodes are substantially parallel and concentric to each other; also the first and second electrodes are separated from each other by a predetermined distance determined by a region of the bulk contained between the first and second electrodes. The bulk of semiconductor material is lightly doped with one of the first and second conductivity type dopants such that a semiconductor junction between the first conductivity type dopant and the second conductivity type dopant is formed at a plane where the first electrode joins the semiconductor material. Preferably the first and second electrodes extend into the bulk a predetermined depth equal to or less than 95% of the bulk thickness, however it is also envisioned in one of the embodiment that the first and second electrodes extend the full depth (100%) into the bulk thickness.

In other embodiments, the first electrode may be shaped in the form of a rectangular, square, triangular or cylindrical 3D trench, and the second electrode may be shaped in the form of a rectangular, square, or cylindrical 3D column. A single-cell 3D-Trench detector may be formed by combining any one of the first electrode shapes with a corresponding one of the second electrode shapes, or combinations thereof. In a 3D-Trench detector so formed, the first electrode is formed of a material doped with a first conductivity type dopant and the second electrode is formed of a material doped with a second conductivity type dopant that is different from the first conductivity type dopant, and the bulk is lightly doped with only one of the first and second conductivity dopant such that a semiconductor junction of opposite dopants is made between the first electrode and the bulk or between the second electrode and the bulk. In one embodiment, a central junction electrode is formed at a plane where the bulk joins the second electrode. In other embodiments, an outer-ring-junction is formed at a plane where the bulk joins the first electrode.

In a preferred embodiment, the first and second electrodes extend into the bulk from the same one of the first and second surfaces along the bulk thickness. In alternate embodiments, the first and second electrodes may extend into the bulk from a different one of the first and second surfaces along the bulk thickness. In a preferred embodiment, the first and second electrodes extend into the bulk a predetermined depth equal to or less than 95% of the bulk thickness.

In another embodiment, the first and second electrodes extend into the bulk 100% of the bulk thickness, in which case a support wafer may be needed to prevent the pixel cells from falling off after etching. In an alternative embodiment, in order to avoid the use of the support wafer, the trench and column electrodes may be formed by the alternating steps of partial etching/diffusing around the periphery and in the center of the semiconductor material bulk, whereby during the doping step either the remaining bulk material in the trench or column is used as support or after the doping step the already set dopant is used as support.

A method for fabricating a 3D-Trench detector is also disclosed. In one embodiment, the fabrication method includes: providing a bulk of semiconductor material having a predetermined bulk thickness and defining thereon a first surface parallel to a second surface, the second surface separated from the first surface by the predetermined bulk thickness; etching, around the periphery of the bulk, a trench having a predetermined width and extending into the bulk from one of the first and second surfaces; etching, in the center of the bulk, a hole also having the predetermined width and extending into the bulk from one of the first and second surfaces along the bulk thickness; doping each of the trench and hole materials with one of a first conductivity type dopant and a second conductivity type dopant by diffusion or by filling of pre-doped polysilicon, and annealing said conductivity type dopants such that a first electrode in the shape of a 3D trench is formed in the trench and a second electrode in the shape of a 3D column is formed in the hole. In a preferred embodiment, etching the trench includes etching a hexagonal trench, and etching the hole includes etching a hexagonal or circular hole. In other embodiments, etching the trench includes etching a circular or polygonal such as triangular, square or rectangular trench. In a preferred embodiment the trench and the hole extend from one of the first and second surfaces into the bulk a depth equal to or less than 95% of bulk thickness. This allows for fabrication process including the etching, implanting, and annealing to be completely single-sided. In alternate embodiments, however, the trench and the hole may extend from either one of the first and second surfaces into the bulk 100% of the bulk thickness, in which case a support wafer may be required to prevent the pixel cells from falling off after etching.

In an alternative embodiment, the trench and the hole that extend from either one of the first and second surfaces into the bulk 100% of the bulk thickness may be produced without a support wafer if the etching is done in stages. Specifically, during the etching/diffusing step the bulk of the semiconductor material is etched/diffused and the trench and or column will be filled with a pre-doped material (e.g. polysilicon) so as to extend the trench and the hole to a predetermined distance of less than 100% from one of the first and second surfaces (only the filling of the trench is needed to provide the mechanical strength of the wafer—the column can be either filled or partially filled). Once the partial trench/column is formed and filled, it is doped with either an n-type or p-type dopant by driving (e.g. high temperature diffusion) the dopant from the pre-doped material into Si. After this stage, the formation of trench and column on one of the surface (the first surface, or the second surface) has been done. Then the etching of trench/column is performed, on the opposite surface (the second surface, or back surface) to match the pattern on the first surface, to extend the trench/column up to the doped portion and once again doped with either an n-type or p-type dopant depending on the dopant used to match the dopant from the first surface. The trench/column can be either partially filled or filled on the second surface (back surface). Thus the full thickness electrode can be produced without the need for a support wafer.

The issues arising from using metallic grids to prevent charge sharing between neighboring pixels may be addressed by providing a multi-pixel 3D-Trench detector comprising a plurality of detecting units in which each detecting unit includes at least one of a plurality of electrodes formed as a 3D trench electrode. More specifically, in a multi-pixel 3D-Trench detector, each detecting unit forming a pixel includes a first electrode shaped as a 3D trench and a second electrode shaped as a 3D column. The first electrode encloses the second electrode and serves to separate a detecting unit from an adjacent one so as to naturally prevent charge sharing between the detecting units. Accordingly, the use of a metallic grid to prevent charge sharing is no longer necessary.

Additional objects and advantages of this invention will be apparent from the following detailed description of preferred embodiments thereof which proceeds with reference to the accompanying drawings.

### BRIEF DESCRIPTION OF THE DRAWINGS

FIG. 1A illustrates an example of a conventional 2D detector;

FIG. 1B shows a perspective view of a conventional 3D-detector;

FIG. 2A illustrates a perspective view of a first embodiment of a single-cell 3D-Trench detector having a rectangular trench outer electrode and a rectangular column inner electrode;

FIG. 2B illustrates a top view of the first embodiment shown in FIG. 2A;

FIG. 3 illustrates an alternative embodiment of a single-cell 3D-Trench detector having a square 3D trench and a cylindrical center electrode;

FIG. 4A illustrates an independent coaxial detector array (ICDA) multi-pixel 3D-Trench detector of rectangular type;

FIG. 4B illustrates a multi-cell 3D-Trench strip detector;

FIG. 5A and FIG. 5B illustrate perspective and cross-sectional views, respectively, of an embodiment of a single-cell 3D-Trench detector of hexagonal type with a central junction (CJ) electrode;

FIG. 5C illustrates an example of an ICDA multi-pixel 3D-Trench-CJ detector of the hexagonal type;

FIG. 5D schematically illustrates a partial cross-sectional view of one unit from the ICDA multi-pixel system illustrated in FIG. 5C. For simplicity only four units are shown.

FIGS. 6A and 6B illustrate perspective and cross-sectional views, respectively, of a cylindrical geometry used to approximate the single-cell 3D-Trench-CJ detector of FIG. 5A;

FIG. 7 shows a Cartesian graph of a function that illustrates an electric field profile in a single-cell 3D-Trench-CJ detector of the hexagonal type in a non-irradiated state;

FIG. 8 shows a graph that illustrates a comparison of an electric field profile of a single-cell 3D-Trench-CJ detector versus that of a 2D planar detector;

FIG. 9 shows a graph that comparatively illustrates increases in full depletion voltage as a function of outer radius for an irradiated 3D-Trench-CJ detector, along with that of a planar 2D detector as a function of distance between its electrodes;

FIG. 10 shows a graph illustrating electronic field profiles in an over depletion state for a single-cell 3D-Trench-CJ detector as compared to that of a planar 2D detector;

FIG. 11 is graph that illustrates a simulated weighting field profile of a single-cell 3D-Trench-CJ detector;

FIG. 12 is graph showing products of carrier drift velocity and weighting field in a single-cell 3D-Trench-CJ detector;

FIG. 13 illustrates a preferred embodiment of a 3D-Trench detector of the hexagonal type with an outer-ring-junction (3D-Trench-ORJ);

FIGS. 14A and 14B illustrate perspective and cross-sectional views, respectively, of a cylindrical geometry used to approximate electric field calculations in a single-cell 3D-Trench-ORJ detector;

FIG. 15 shows a graph that illustrates comparisons of electric field profiles in a 3D-Trench-ORJ detector and that of a 2D planar detector for reference;

FIG. 16 shows a graph that illustrates full depletion voltage as a function of outer radius distance for an irradiated single-cell 3D-Trench-ORJ detector, along with that of a planar 2D detector for reference;

FIG. 17 shows a graph that illustrates comparisons of electric field profiles in a 3D-Trench-ORJ detector (at over-depletion) and that of a 2D detector for reference;

FIG. 18 shows a graph that illustrates electric field profiles in a singe-cell 3D-Trench-ORJ detector at three different over-depletion biases;

FIG. 19 shows a graph that illustrates an electric field profile in a 3D-Trench-ORJ detector biased at an optimal over-depletion voltage;

FIG. 20 shows a graph that illustrates products of carrier drift velocity and weighting field for electrons and holes in a 3D-Trench-ORJ detector;

FIG. 21A shows a graph that comparatively illustrates the products of carrier drift velocity and weighting field for electrons in a 3D-Trench-ORJ detector and that of a 3D-Trench-CJ detector;

FIG. 21B shows a graph that comparatively illustrates electric field profiles of a 3D-Trench-ORJ detector and a 3D-Trench-CJ detector;

FIG. 21C shows a graph that comparatively illustrates 3D electric field profiles of a 3D-Trench-ORJ (8V) and a 3D-Trench-CJ (52V) detector of hexagonal type.

FIG. 22 shows a graph that illustrates an example of electron- and hole-induced currents by a minimum ionizing particle (MIP) in an irradiated 3D-Trench-CJ detector;

FIG. 23 shows a graph that illustrates an example of electron- and hole-induced currents by a MIP in an irradiated 3D-Trench-ORJ detector at a bias voltage of 97V;

FIG. 24 shows a graph that illustrates an example of electron and hole induced currents by a MIP in an irradiated 3D-Trench-ORJ detector at a bias voltage 224V;

FIG. 25 schematically illustrates drifting of free carriers generated by a MIP in a single-cell 3D-Trench-ORJ detector;

FIG. 26A shows a graph that depicts the dependence of total collected charges and the contributions of electrons and holes thereof to the total charges as a function of the particle incident position r₀ for a 3D-Trench-CJ detector;

FIG. 26B shows a graph that depicts the dependence of total collected charges and the contributions of electrons and holes thereof to the total charges as a function of the particle incident position r₀ for a 3D-Trench-ORJ detector;

FIG. 27 shows a graph that illustrates dead space percentage as a function of the distance R for a single-cell 3D-Trench detector of the hexagonal type;

FIG. 28A schematically illustrates an example of a single-cell 3D-Trench-ORJ detector for x-ray applications;

FIG. 28B illustrates a multi-pixel 3D-Trench-ORJ detector that includes an array of single-cell units of the type shown in FIG. 28A;

FIG. 29A shows a single-cell 3D-Trench-ORJ detector with a p⁺ ion implanted guard ring system for reducing electric field concentration along the front surface;

FIG. 29B illustrates different configurations of multi-guard ring systems adapted to exemplary multi-pixel 3D-Trench detectors;

FIG. 29C shows simulations of electric field profiles which comparatively illustrate the electric field distribution in microstrip detectors with and without a multi guard ring system;

FIG. 30 is a flowchart illustrating exemplary manufacturing steps of a process used for manufacturing a 3D-Trench detector as contemplated by one embodiment of the present invention;

FIGS. 31A to 31D show perspective views of an exemplary single-cell 3D-Trench detector at progressive stages of fabrication;

FIG. 32A illustrates a 3D detector formed by an implantation process in a bulk of semiconductor material;

FIG. 32B illustrates another embodiment of a 3D detector in which 3D electrodes are formed by an enhanced implantation process.

### DETAILED DESCRIPTION

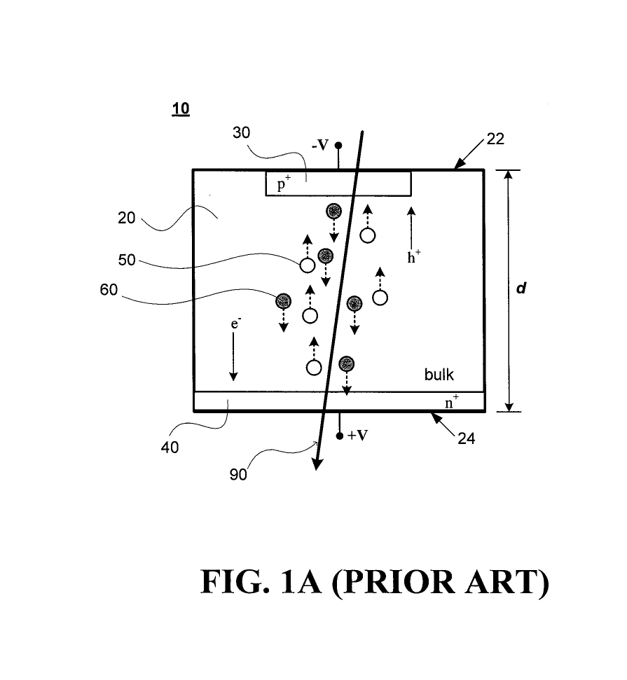

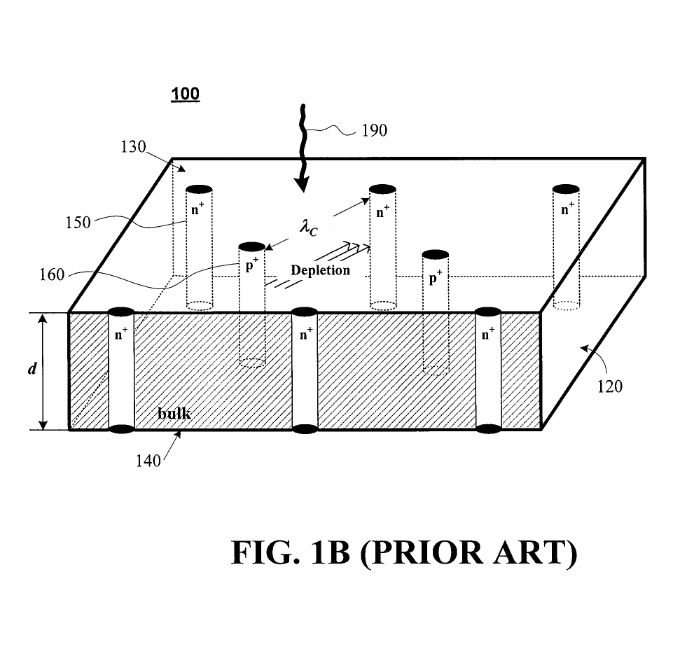

In order to avoid misunderstanding in nomenclature and structure with other 3D technologies and detectors, namely 3D stacking of detectors and electronics and 3D position-sensitive detectors, the inventive 3D detectors are referred to as “3D-Trench Electrode Detectors” in contrast to the conventional “3D detectors” described above and shown in FIG. 1B. Specifically, several embodiments of new and novel 3D detectors are disclosed that are based on a first electrode configuration fabricated in the form of a “trench” that encloses a second electrode in the form of a rod or a column. The term “trench,” as used in this specification, generally denotes a deep and narrow ditch or cut having a predetermined width and depth. Hence, the new type of 3D detectors will be generally described as “3D-Trench Electrode Detectors,” but for the sake of simplicity and brevity, a 3D-Trench electrode detector may also be interchangeably referred to as a “3D-Trench detector.” For the convenience of the reader, the Detailed Description has been ordered in the following sections:
1. EMBODIMENTS OF 3D-TRENCH DETECTORS
1.1.3D-Trench Detectors of Rectangular Type
1.1.1. Structure of a 3D-Trench Detector of Rectangular Type
1.1.2. Other Embodiments Based on the 3D-Trench Detector of Rectangular Type
1.1.3. Multi-pixel 3D-Trench Detector of Rectangular Type
1.2. 3D-Trench Detectors of Hexagonal Type
1.2.1. 3D-Trench Detectors with Central Junction (3D-Trench-CJ)
1.2.1.1 Structure of a Single-cell 3D-Trench-CJ Detector of Hexagonal Type
1.2.1.2 Multi-pixel 3D-Trench-CJ Detector of Hexagonal Type
1.2.2. 3D-Trench Detectors with Outer Ring Junction (3D-Trench-ORJ)
2. ELECTRIC FIELD CALCULATIONS
2.1. Electric Field Considerations in a 3D-Trench Detector of Rectangular Type
2.1.1. Electric Field Distribution
2.2. Electric Field Considerations in the 3D-Trench-CJ Detector of Hexagonal Type
2.2.1 Electric Field Distribution
2.2.1.1 Depletion Voltage in a Non-irradiated 3D-Trench-CJ detector
2.2.1.2. Depletion Voltage in an Irradiated 3D-Trench-CJ detector
2.2.1.3. Over Depletion Voltage in an Irradiated 3D-Trench-CJ detector
2.2.1.4. Electric Field in Non-irradiated vs. Irradiated 3D-Trench-CJ Detector
2.2.2. Calculation of Weighting Fields in a 3D-Trench-CJ Detector of Hexagonal Type
2.2.3. Induced Current in a 3D-Trench-CJ Detector
2.3. Electric Field Considerations in the 3D-Trench-ORJ Detector
2.3.1 Electric Field Distribution
2.3.1.1 Electric Field at Full Depletion Voltage
2.3.1.2 Electric Field at Over Depletion Voltage
2.3.2. Optimal Depletion Voltage in a 3D-Trench-ORJ Detector
2.3.3 Weighting Fields and Carrier Drift Dynamics in a 3D-Trench-ORJ Detector
2.4. Summary of Characteristics of 3D-Trench Detectors
3. ANALYSIS OF COLLECTED CHARGES IN 3D-TRENCH SILICON DETECTORS
3.1 Collected Charge in 3D-Trench-CJ Silicon Detectors
3.2 Collected Charge in 3D-Trench-ORJ Silicon Detectors
3.3 Dependence of Collected Charge on the Position of Particle Incidence and Carrier Trapping in 3D-Trench Electrode Detectors
3.4 Considerations of Dead Space between Pixels in a Multi-pixel 3D-Trench Detector
4. EXAMPLES OF 3D-TRENCH DETECTORS FOR PRACTICAL APPLICATIONS
4.1. Single-cell 3D-Trench Detector with Enhanced Electrode Separation
4.2. Multi-pixel 3D-Trench Detector with Enhanced Electrode Separation and Increased Pixel Pitch
5. METHOD OF FORMING A 3D-TRENCH DETECTOR
   In addition, in the interest of clarity in describing the various embodiments of present invention, the following acronyms, terms and symbols are defined follows:

### Abbreviations and Symbols

2D two-dimensional
3D three-dimensional
b is the proportionality constant of effective doping concentration to a 1 MeV neutron-equivalent fluence
d bulk thickness (distance from the first surface to the second surface)
d_{eff} effective bulk thickness (slightly less than d)
e electron charge
E_{w} weighting field
E electric field
E(x) electric field distribution in the x-direction
E(r) electric field distribution as function of radius (neglecting dependence on θ)
E(r_{c}) electric field distribution at r=r_{c}
E(R) electric field distribution at r=R
E^{optima} optimal electric field (see Equation 32)
E_{eq} equal field value obtained when E(r_{c})=E(R)
h hole
i^{e,h}(t) induced current by a charge
L trench length in a rectangular type 3D-Trench detector
l trench depth equal to the distance that the electrodes extend into the bulk along the bulk thickness (applies for all types 3D-Trench detectors disclosed)
N_{eff} effective doping concentration (or space charge density) in the semiconductor bulk
n n-type semiconductor material
n⁺ heavily doped n-type material
n_{eq} neutron-equivalent (a unit of irradiation fluence)
p p-type semiconductor material
p⁺ heavily doped p-type material
q elementary charge 1.6021×10⁻¹⁹ C
Q^{e,h} collected charges for electrons (e) or holes (h)
r radial coordinate in the polar coordinate system
r radius
r₀ position of particle incidence (e.g., the point where an ionizing particle enters the substrate bulk of a detector)
r_{c} radius of second electrode (column) in a hexagonal type 3D-Trench detector as approximated by a cylindrical geometry
R in a single-cell 3D-Trench detector of the hexagonal type approximated by cylindrical geometry, R represents the distance from the center of the column electrode to the inner surface of the trench electrode
SiO₂ silicon dioxide or simply silicon oxide
t time
t_{dr}^{e,h} drift time of electrons (e) or holes (h)
V potential, external voltage
v_{d} drift velocity
V_{fd} full depletion voltage
vₛ^{e,h} saturation velocity of electrons (e) or holes (h)
V^{optima} optimal bias voltage necessary for an optimal operational condition in a 3D-Trench-ORJ detector (see Equation 29)
w depletion width
wₙ depletion width of an n⁺ column (first electrode) in a 3D-Trench detector of hexagonal type
wₚ depletion width in a p-type bulk in a 3D-Trench detector of hexagonal type
W_{T} trench width (in a rectangular type 3D-Trench detector)
x x-direction
y y-direction
z z-direction

### Greek Letters

μm micrometer (1×10⁻⁶ m)
ε₀ permittivity of vacuum, 8.854×10⁻¹² F/m
ε permittivity of semiconductor material (e.g., permittivity of silicon is ε_{Si}=11.7ε₀)
λ_{c} electrode spacing, also referred to as column spacing or electrode pitch
θ angular coordinate or polar angle in the polar coordinate system
Φ radiation fluence
Φ_{neq} neutron equivalent fluence
μ^{e,h} mobility of electrons (e) or holes (h)
τₜ carrier trapping constant
ΔV^{optima} over depletion bias voltage (above optimal bias voltage)

### Acronyms

CCE: Charge Collection Efficiency
CERN: European Organization for Nuclear Research, acronym derived from Conseil Européen pour la Recherche Nucléaire (European Council for Nuclear Research)
LHC: Large Hadron Collider
SLHC: Super Large Hadron Collider is a proposed upgrade to increase luminosity in the LHC projected to be made around 2012
MIP: Minimum Ionizing Particle

### Definitions:

n-type: a semiconductor material for which the predominant charge carriers responsible for electrical conduction are electrons. The purpose of an n-type dopant in a semiconductor material is to create an abundance of electrons.
p-type: a semiconductor material for which the predominant charge carriers responsible for electrical conduction are holes. The purpose of a p-type dopant in a semiconductor material is to create an abundance of holes.
semiconductor junction: a junction formed by bringing into very close contact semiconductors of opposite dopant type. A p-n semiconductor junction is a junction formed by joining p-type and n-type semiconductors together in very close contact. The term junction refers to the region where the two semiconductors meet.
depletion region: under thermal equilibrium or steady state conditions, electrons and holes that meet at a semiconductor junction will recombine and disappear. The region in the immediate neighborhood of the junction that loses all of its mobile electrons and holes is called a semiconductor depletion region. For purposes of this specification, however, the region between the n- and p-type electrodes is the depletion region and thus serves as the detector sensitive volume. Depletion region will also increase with reverse bias voltage.
full depletion voltage (V_{fd}): the absolute value of the reverse bias voltage need to just fully deplete the entire detector with thickness d.
small electrode effect: the effect of high electric field concentration near the junction electrode of very small sizes as compared depletion depth.
trench: a deep and narrow cut or ditch having a predetermined width and depth made in the bulk of a semiconductor material.

Various embodiments of the present invention demonstrate that new 3D detectors with very homogenous electric fields substantially free of saddle point potentials, wherein the highest electric field can be at least 8 times smaller than that of conventional 3D detectors and at least 2 times smaller than that of 2D detectors, can be achieved when at least a first electrode in the new 3D detector is vertically etched into the bulk as a “trench” (rather than a column or rod as in the prior art) and at least a second electrode is etched into the same bulk as a column built inside the trench. The first and second electrodes may be etched into the bulk from only one side, which allows for true single-sided operations in either the fabrication and/or the control of the new 3D-Trench detector. In order to differentiate over conventional technology, this design is termed herein as a “3D-Trench” detector. A number of possible non-limiting and non-exhaustive examples of 3D-Trench configurations are disclosed. Theoretical and simulated calculations for electric fields and other parameters for each configuration are also described.

### 1. Embodiments of 3D-Trench Detectors

### 1.1. 3D-Trench Detectors of Rectangular Type

### 1.1.1. Structure of a 3D-Trench Detector of Rectangular Type

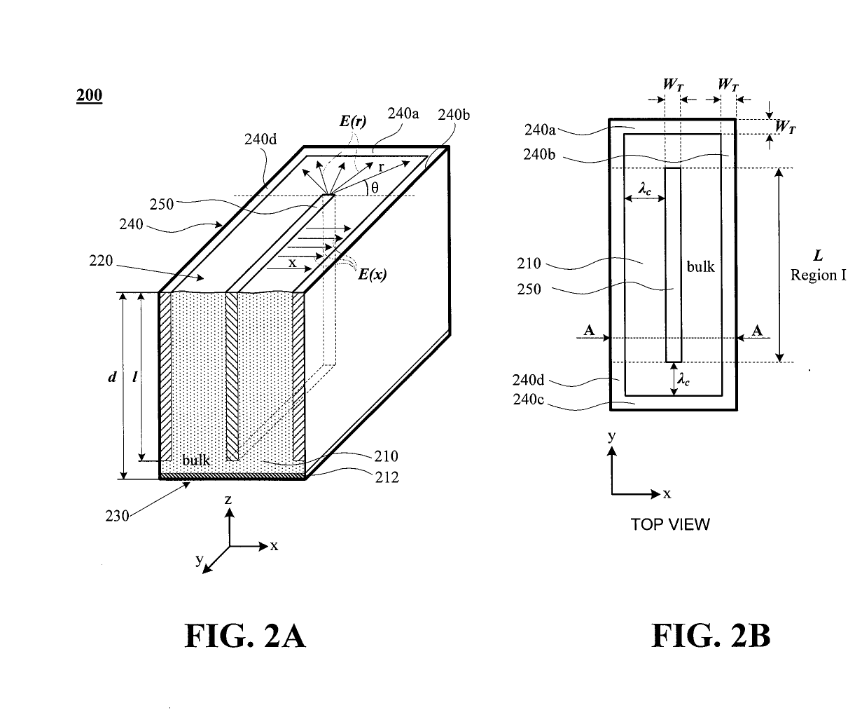

FIG. 2A illustrates the basic components of a first embodiment of a single-cell 3D-Trench electrode detector (3D-Trench detector) 200. The p-type and n-type semiconductor regions are labeled accordingly. The region between the n- and p-type regions is the depletion region and thus serves as the detector sensitive volume. More specifically, detector 200 includes a bulk 210 of n- or p-type doped semiconductor material having an outer region highly doped with p-type dopant (p⁺) and an inner or central region highly doped with n-type dopant (n⁺). The outer (p⁺) and inner (n⁺) highly doped regions are separated from each other by the detector sensitive volume occupied entirely by the semiconductor material. For purposes of this specification, the outer highly doped region (p⁺ in FIG. 2A) is referred to as a first electrode 240, and the inner highly doped region (n⁺) is referred to as a second electrode 250. The n- or p-type semiconductor material is preferably provided in the form of a single crystal of semiconductor material referred to as bulk 210. As illustrated in FIG. 2A, bulk 210 is a monolithic structure having a thickness d and a cube-like shape having six surfaces lying along x, y and z principle planes. A rectangular top surface (first surface 220) lies on a first x-y plane and a rectangular bottom surface (second surface 230) lies on a second x-y plane. The first and second surfaces lie on parallel x-y planes and are separated from each other by the bulk thickness d which in principle is not limited, but it is typically in the range between 200 μm to 2000 μm with a preferred embodiment in the range between 200 μm to 500 μm. The cube-like shape of bulk 210 also defines third and fourth surfaces parallel to each other lying on parallel x-z planes, and fifth and sixth surfaces also parallel to each other lying on y-z planes. The first electrode 240 may be formed, for example, by etching and subsequently filing a deep and narrow ditch or cut (referred to as a “trench”) of a predetermined width and depth around the periphery of the single cell in the bulk 210 so as to define trench walls 240a, 240b, 240c and 240d. The second electrode 250 may preferably be formed, for example, by etching and subsequently filling a deep and narrow cut in the center of bulk 210.

A top view of the first surface 220 is shown in FIG. 2B. As illustrated in the top view of FIG. 2B, the first electrode 240 is preferably formed as an enclosed rectangular strip trench occupying the four edges of the first surface 220. The two longer sides of the rectangular strip trench (first electrode 240) lie along the y direction; and the two shorter sides of the trench lie along the x direction. The second electrode 250 is formed as a long and narrow cut or column substantially in the center of first surface 220; the length of the second electrode lies along the y direction, i.e., a rectangular strip column. The first and second electrodes are separated from each other by a predetermined distance occupied by the bulk 210 of the semiconductor material. The first and second electrodes are substantially concentric to each other and spaced apart by an electrode separation λ_{c} equal to a predetermined distance occupied by a portion of bulk 210.

Returning to the perspective view of FIG. 2A, it is illustrated that the first electrode 240 is formed around the periphery of the single cell in the bulk 210 so as to define trench walls 240a, 240b, 240c and 240d. Preferably, each of the walls has a predetermined trench width W_{T} and a trench depth l, and extends along the bulk thickness d in the z direction. Therefore, the first electrode 240 includes four thin walls (240a, 240b, 240c and 240d), each of which is disposed along the periphery (i.e., along the third, fourth, fifth and sixth surfaces) of the single cell in the bulk 210. The walls extend from the first surface 220 deep into the bulk 210 a predetermined depth l. For example, l=d−20 μm.

In other single cell embodiments described in this specification, the first electrode may not be formed as rectangular trench. Instead, as fully described below, the single cell may be formed as a square, hexagon, cylinder or other geometrical shape. Regardless of its shape, the first electrode is preferably formed as a trench having a predetermined width W_{T} and located around the periphery of the single cell in the bulk and extending into the bulk thickness d a predetermined depth l. Accordingly, for the remainder of this specification, the first electrode shall be referred to a “3D-Trench electrode,” or, interchangeably, it may also be referred to as a “trench electrode” or simply as a “trench.”

A second electrode 250 is formed within the volume of bulk 210, at a predetermined distance from the first electrode 240 and substantially in the center thereof, such that the first electrode 240 completely surrounds the second electrode 250. As illustrated in the perspective view of FIG. 2A, the second electrode 250 is formed as a rectangular column grown in the center of the single cell in the bulk 210 and having a column width W_{T}, depth l and a side surface length L. The surface length L is illustrated in FIG. 2B. Thus, the second electrode 240 may be referred to as a rectangular column substantially concentric and parallel to the first electrode 240. A portion of the bulk 210 occupies the predetermined distance separating the first electrode 240 from the second electrode 250. Accordingly, the second electrode 250 of this embodiment is formed as a thin rectangular column lying along a y-z plane that extends along the thickness d of bulk 210. The side surface length L of second electrode 250 in principle has no limits, but may range between 100 μm and 400 μm. Since walls 240b and 240d of the first electrode and the second electrode 250 are all disposed along y-z planes, the second electrode 250 is said to be substantially parallel to the walls 240b and 240d of first electrode 240. Indeed, it is envisioned that in all of the embodiments described in this specification the first and second electrodes are substantially parallel to each other.

Throughout the description of this specification, the term “first electrode” may be interchangeably referred to as “outer electrode” or “trench”; and the term “second electrode” may be also referred to as “inner electrode,” “center electrode,” or “column.” Notwithstanding the term used to refer to the first and second electrodes, it is to be understood that these terms are merely used for ease of description. In effect, the space between the two electrodes is completely occupied by the semiconductor material of the bulk, and the space referred to as “electrodes” is essentially doped material filled in etched spaces. Thus, no apparent trench or column structures may be readily observable once the detector is fabricated. Moreover, as more fully explained below, the first and second electrodes are not limited to being formed by etching and filling. In fact, the electrodes may be formed within the semiconductor material by any known method, e.g., laser drilling, crystal growth, material deposition, diffusion of dopants, etc.

Still referring to FIGS. 2A and 2B, the first electrode 240 forming the outer walls of the 3D-Trench has a wall with a predetermined width W_{T}. In the embodiment of FIG. 2B, the width W_{T} may be equal to 10 micrometers (W_{T}=10 μm). In practice, however, any appropriate width can be determined in accordance with particular application requirements. For this reason, it should be noted that at least part of the width W_{T} represents a “dead space” in terms of detector sensitivity because the space occupied by this width W_{T} does not interact with impinging radiation. Accordingly, as more fully discussed in section 1.1.3.1 below, the width W_{T} of the trench wall serves as natural separating space between adjacent elements of a multi-element 3D-Trench detector. It should also be noted that it is preferable that the trench depth l not extend the entirety of the bulk thickness d. Indeed, according to the embodiment of FIG. 2A, it is preferable that the trench depth l be equal to the bulk thickness d minus a predetermined value, e.g., 20 μm. Therefore, in the given example where the thickness d of bulk 210 may range between 200 μm and 500 μm, and the trench depth l=d−20 μm, it follows that the trench depth l may, for example, range from about 90% to 96% of the thickness d (0.9d≦l≦0.96d) Preferably, however, at least for ease of calculation and fabrication processes, the trench depth l may range from 90 to 95% of the thickness d, (0.9d≦l≦0.95d). However, in another embodiment, it is also envisioned that the trench depth l may extend the full thickness d (l=d).

Although the 3D-Trench detector has been described above as preferably having both of the first electrode 240 and the second electrode 250 extend into the bulk 210 from the first surface 220, the opposite may also be true. That is, the first electrode 240 and the second electrode 250 may extend into the bulk 210 from the second surface 230. Moreover, where specific designs require, the first and second electrodes may also extend into the bulk from both of the first and second surfaces, respectively. Accordingly, it can be said that in the 3D-Trench detectors of the present invention, the first and second electrodes extend into the bulk from at least one of the first and second surfaces along the thickness of the bulk.

It should be noted, however, that having the first and second electrodes extend into the bulk from only one surface allows for true single-side processing, which may result in significant design and fabrication advantages. For example, single-side processing reduces processing time during fabrication, and allows for single-sided connections during operation. In addition, it is also noted that the specific dimensions disclosed herein are not restrictive, but are merely presented for the purposes of reference and example. Other dimensions may be developed by those skilled in the art without departing from the present disclosure. The dimensions of each of the bulk and first and second electrodes may indeed be determined in accordance with the requirements of specific applications, as long as the overall dimensions of the bulk can accommodate the design characteristics and output performance of the 3D-Trench detector, as set forth herein.

Continuing to refer to FIG. 2A, bulk 210 is preferably chosen from an appropriate semiconductor material lightly doped with a dopant of predetermined conductivity type (n- or p-type). For example, for detectors used in high-energy radiation applications such as experimental physics and/or x-ray imaging, a bulk substrate of silicon has been found to be especially well suited due to silicon's widely accepted use and its excellent energy resolution properties. However, depending on the type of application, other types of material are also envisioned as equally appropriate for the 3D-Trench detectors described. Indeed, 3D semiconductor radiation detectors made of cadmium telluride (CdTe) and gallium arsenide (GaAs) for X- and γ-ray detection have already been proposed, for example, by M. Ruat et al., in “3d Semiconductor Radiation Detectors For Medical Imaging,” Proceedings of the COMSUL Users Conference, 2007, Grenoble, France, which is incorporated herein by reference for all purposes. In addition, other widely available semiconductor materials such as silicon-germanium, germanium, silicon carbide, cadmium zinc telluride (CZT), and others may be also suitable.

Fabrication of the 3D-Trench detector is not limited to any specific process. There are numerous known techniques for creating through-holes or carving trenches within the bulk of a semiconductor substrate, doping the interior of these and filling the same to create the desired structures. For example, the availability of deep reactive ion etching (DRIE) offers the possibility to etch through-holes across the bulk, or the possibility to create deep trenches into the bulk. After etching the bulk to create holes and trenches, a method such chemical vapor deposition (CVD) may be used to form the electrodes by filling the holes and trenches with the material having an appropriate conductivity type. Other known processes may be used to complete fabrication of pertinent and necessary ohmic contacts, protection layers, and the like. It should be kept in mind, however, that in order to optimize detector performance in 3D-Trench detectors, caution should be taken to prevent the creation of voids or other irregularities during the formation of the electrodes.

Because the performance of the detector is largely dictated by the geometry of its design, those of ordinary skill in the art are encouraged to apply the best available techniques suitable for the different embodiments disclosed, to thereby achieve the best performance. For example, extensive details for fabricating 3D detectors are discussed by Parke et al., in U.S. Pat. No. 5,889,313 entitled “Three-dimensional Architecture For Solid-State Radiation Detectors,” issued on May 30, 1999, and in U.S. Pat. No. 6,489,179 by Conder et al., entitled “Process for Fabricating a Charge Coupled Device,” issued on Dec. 3, 2002, both of which are incorporated herein by reference in their entireties. It is to be understood, however, that as long as the general architecture of the 3D-Trench detector is kept within the parameters disclosed herein, such a detector may be encompassed by at least one of the appended claims. A flowchart illustrating exemplary steps of a process for forming a 3D-Trench detector in accordance with at least one embodiment of the present invention is described in section 5 entitled: “Method for Fabricating a 3D-Trench Detector.”

The architecture of the 3D-Trench detector of the rectangular type is not limited to the above-described arrangement. Other electrode forms may be possible based on specific application needs, e.g., based on resolution, radiation hardness, and/or sensitivity requirements. For example, other trench and column shapes including predetermined geometrical shapes, such as square, rectangular, triangular, hexagonal, and the like, are considered to be within the range of configurations that can easily adopt the 3D-Trench and column parameters set forth above in reference to FIGS. 2A and 2B. Indeed, one possible modification in the single-cell 3D-Trench detector may include, for example, designing the inner or second electrode, i.e. the center column, to be rounded, or in the shape of a rod or cylindrical column.

### 1.1.2. Other Embodiments Based on the 3D-Trench Detector of Rectangular Type

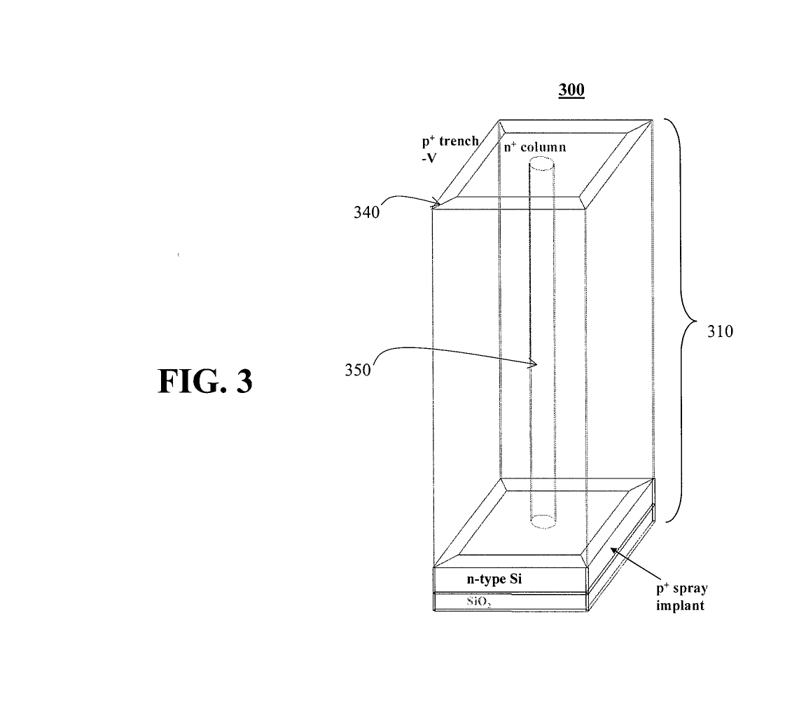

FIG. 3 illustrates one such possible embodiment of a single-cell 3D-Trench detector 300 based on the rectangular type. The 3D-Trench detector 300 of FIG. 3 is preferably formed of a bulk 310 of semiconductor material within which a first electrode 340 and a second electrode 350 have been formed, for example, by etching and filling the p⁺ and n⁺ regions, as illustrated in FIG. 3. Similar to the rectangular type 3D-Trench detector, electrodes 340 and 350 of detector 300 extend into the bulk from one of the first and second surfaces of the bulk and along the thickness d thereof. Preferably, the electrodes do not reach the second surface. As illustrated in FIG. 3, the first electrode 340 is formed as a square structure that defines the outer walls of a three dimensional square trench, while the second electrode 350 is formed as a cylindrical column or rod. All of the exemplary dimensions discussed in reference to the rectangular type single-cell 3D-Trench detector of FIG. 2A may be adapted to the square single-cell 3D-Trench detector. Accordingly, similar to the rectangular type, other 3D-Trench detector arrangements can also be defined as having at least first and second electrodes, wherein the first electrode defines a trench and the second electrode defines a column, the first electrode completely surrounds the second electrode, and the electrodes are spaced apart from each other by a predetermined distance occupied by the semiconductor material.

### 1.1.3. Multi-Pixel 3D-Trench Detector of Rectangular Type

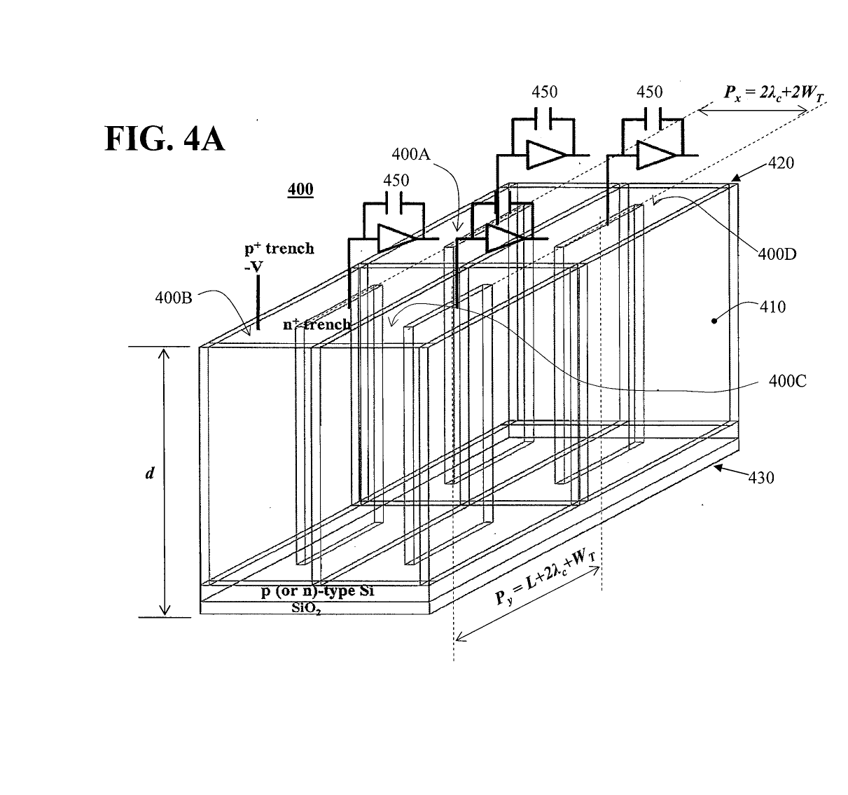

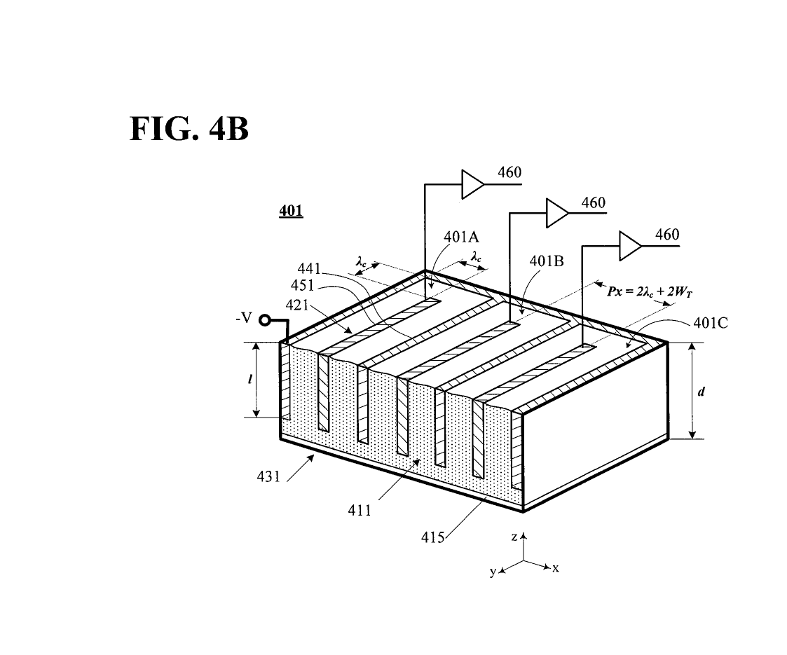

Expanding on the concept of the single-cell 3D-Trench detector of the rectangular type, FIGS. 4A and 4B illustrate multi-pixel 3D-Trench detectors 400 and 401 having a 2×2 matrix of detecting units. The multi-pixel 3D-Trench detector 400 is formed on a semiconductor (n- or p-type) bulk 410 having a first surface 420 and a second surface 430 that is separated from the first surface by a thickness d and includes a plurality of 3D-Trench cells 400A, 400B, 400C and 400D. Each of the cells 400A to 400D is formed in a manner substantially similar to the above-described single-cell 3D-Trench detector illustrated in FIGS. 2A and 2B. As shown in FIG. 4A, all of the 3D-Trench cells are connected to a negative voltage bias (−V) via the first or outer electrode of 3D-Trench cell 400B, and each 3D-Trench cell units is connected to an electronic channel 450 for signal read out via the second or inner electrode of each of the cells 400A to 400D. Electrical connections between each of the cells 400A to 400D and electronic channels 450 may be made in any practical known manner. For example, metalized contacts, e.g. aluminum contacts, may be provided on the top of each first electrode and then connected to readout electronics 450, e.g., by wire bonding.

In the multi-pixel 3D-Trench detector 400 of FIG. 4A, the electrode (or pixel) pitch may preferably be arranged on the basis of the electrode spacing λ_{c} of the basic single-cell detector and the length L or the center electrode (second electrode), as defined in FIG. 2A. Accordingly, the distance between the centers of two adjacent inner electrodes (distance between adjacent second electrodes) in the x direction may be equal to twice the basic electrode spacing such that Pₓ=2λ_{c}+2W_{T}, and the distance between the centers of two adjacent inner electrodes in the y direction may be equal to the length L of an inner electrode plus twice the basic electrode spacing such that P_{y}=L+2λ_{c}+W_{T}, as illustrated in FIG. 4A. A multi-pixel 3D-Trench detector so formed offers the remarkable advantage that the sensitive region in each cell of the detector is isolated from an adjacent cell by a dead space created by the width W_{T} of the trench electrode, where W_{T} may be approximately 10 μm or thicker, depending on the requirements of the particular application. Accordingly, such a multi-pixel detector no longer requires a metallic grid to prevent charge sharing between adjacent pixels. Since the use of a metallic grid generally adds a large dead space (normally a few hundred micrometers) between pixels, a 3D-Trench detector without such a grid may more efficiently use a detector's surface space without sacrificing sensitivity and/or resolution. As a result, smaller and more compact radiation detectors may be produced, and without the metallic grid, the fabrication process of such a detector may be less complicated and expensive.

Other multi-cell 3D-Trench detectors of the rectangular type may also be possible. For example, FIG. 4B illustrates a 3D-Trench detector 401 having a plurality of rectangular 3D-Trench units 401A, 401B, and 401C aligned in a linear array in the y-direction. The 3D-Trench detector 401 may be configured as a strip detector formed of a p- or n-type semiconductor bulk 411 on which heavily doped strip electrodes extend into the bulk 411 from a first surface 421 (or front side). A second surface 431 (or back side) can be treated by a thin protection layer 415 of, for example, SiO₂ to protect bulk 411 from environmental damage. More specifically, in 3D-Trench detector 401, each of detecting units 401A to 401C includes a first electrode 441 and a second electrode 451 formed in the manner described in reference to FIG. 2A. In this embodiment, the first electrode 441 may be configured as a p⁺ strip trench and the second electrode 451 may be configured as an n⁺ strip column. Both electrodes lie along substantially parallel y-z planes and extend into the bulk 411a predetermined depth l in the z direction along the thickness d of the bulk. All of the p⁺ strips (first electrodes 441) may be tied together to a positive bias voltage (−V), while each n⁺ strip (each second electrode 451) may be connected to an electronics channel 460 for signal read out. Accordingly, in this embodiment, the central strip of each detecting unit may be connected as a separate element of a detector, enabling the detector to sequentially read out each detecting unit for position sensitivity, or to generate a composite signal by combining the individual signals of each unit. According to this embodiment, therefore, strip detectors may be configured such that the strip pitch equals Pₓ=2λ_{c}+2W_{T} if inner strip electrodes are arranged in parallel along the x direction (as shown if FIG. 4B), or P_{y}=L+2λ_{c}+W_{T} if inner strip electrodes are arranged in series in the y direction.

### 1.2. 3D-Trench Detectors of Hexagonal Type

1.2.1 3D-Trench Detectors with Central Junction (3D-Trench-CJ)

### 1.2.1.1 Structure of a Single-Cell 3D-Trench-CJ Detector of Hexagonal Type

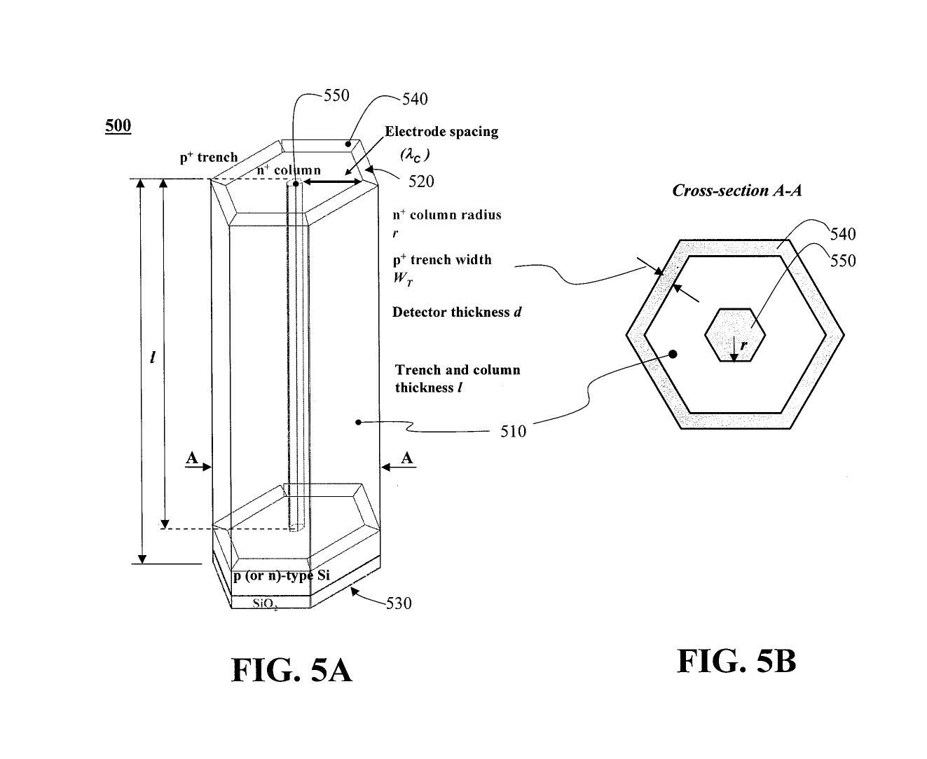

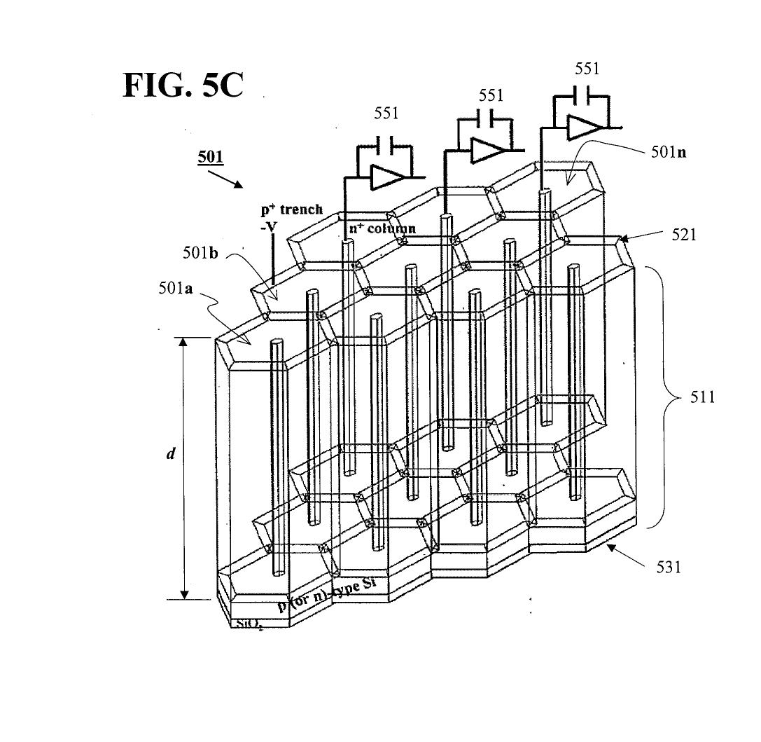

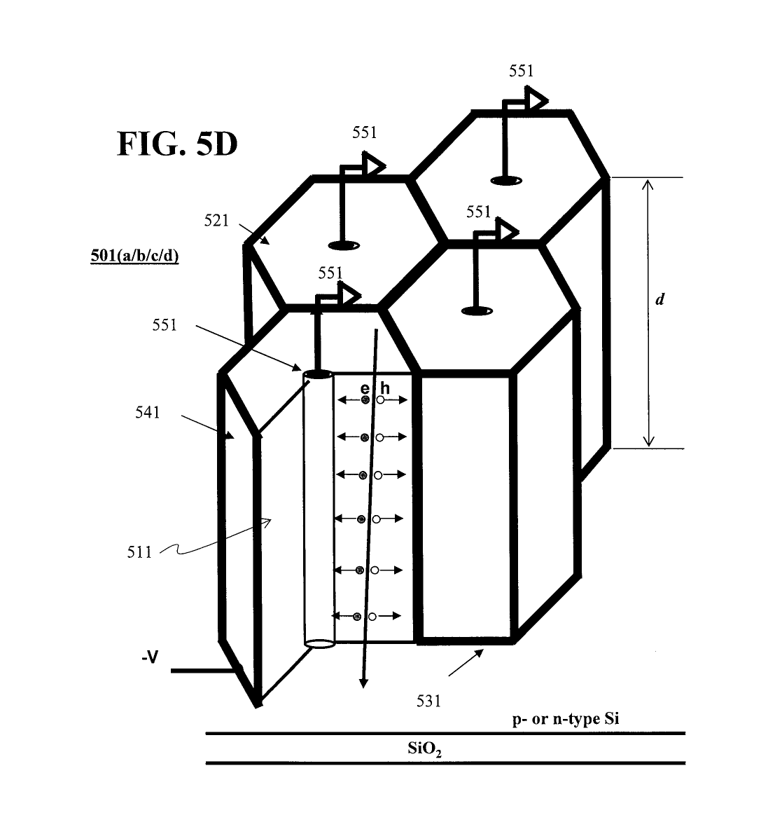

FIG. 5A illustrates another single-cell embodiment of a 3D-Trench detector. The 3D-Trench detector 500 of FIG. 5A is somewhat similar to that of FIG. 2A, but with the substantial difference that in FIG. 5A the first electrode defines a hexagonal trench and the second electrode defines a hexagonal column (or a cylindrical column) rather than rectangular trench and column, respectively. More specifically, as illustrated in FIG. 5A, detector 500 includes a bulk 510 of n- or p-type semiconductor material having highly doped regions p⁺ and n⁺ that are separated from each other by a predetermined distance. In FIG. 5A, the highly doped region p⁺ is referred to as a first electrode 540 and the highly doped region n⁺ is referred to as a second electrode 550. The n- or p-type semiconductor material is preferably a single-crystal semiconductor material referred here as bulk 510. The bulk 510 has a predetermined thickness d which in principle has no limit, but it is preferably between 200 μm and 500 μm. The bulk 510 may be configured as a monolithic structure having a hexagonal shape, but non-monolithic structures may also be possible. In FIG. 5A, a p-n junction (semiconductor junction) is preferably formed between the bulk 510 which is of p-type in this case and the inner or second electrode 550, at a plane where the surface of the second electrode meets the semiconductor material of bulk 510. Hence, in the context of semiconductor junctions, the embodiment of FIG. 5A is discussed under the concept of a detector having central junction (CJ) electrode.

In FIG. 5A, the 3D-Trench-CJ detector preferably includes the bulk 510 of a p-type semiconductor material having a first surface 520 and a second surface 530 separated from the first surface by the bulk thickness d. First and second electrodes 540 and 550, respectively, represent regions of opposite conductivity type. These regions may be formed by etching and filling with pre-doped material, by etching and filling with undoped material that is then doped, or by ion implantation of dopants into the bulk in these regions only, among other fabrication methods. Further processing steps, such as annealing, may be employed to obtain the desired dopant profile or junction location. In this embodiment, the first electrode 540 is heavily p-type (p⁺) and defines a trench having six (6) sides substantially equal in size. The first electrode 540 has a wall or trench width W_{T} of a predetermined value, typically, it may be approximately 10 μm. The second electrode 550 is heavily n-type (n⁺) and defines a column of hexagonal or circular cross-section. The second electrode 550 may also be referred to an inner or central electrode because it resides within a space enclosed by the first electrode 540. Each side of the hexagonal cross-section of second electrode 550 is also substantially equal in size, and lies around a radius r of a predetermined value, typically, it may be approximately 10 μm, measured from the center of the column. The first electrode 540 and the second electrode 550 extend into the bulk 510 a predetermined depth l equal to the detector thickness d minus a predetermined value. Typically l=d−20 μm.

In FIG. 5A, both of the first electrode 540 and second electrode 550 are configured in the same manner as described above in reference to FIG. 2A. In particular, it is preferable that the first and second electrodes (540, 550) extend into the bulk (510) from only one of the first and second surfaces along the thickness d of the bulk a predetermined depth l equal to or less than 95% of the detector thickness. However, in other embodiments that are envisioned, the first and second electrodes (540, 550) extend into the bulk (510) to a depth l that is equal to 100% of the detector thickness (l=d). Again, the feature of having the electrodes extending into the bulk from only one surface is significant because true single-side processing can be achieved during processing and/or connection of the detector. Dual-sided processing is known in the art, and in some conventional 3D detectors the column electrodes penetrate the entirety of the bulk from the first surface to the second surface, requiring the use of a support wafer and/or dual-sided processing. In particular, in a “dual-sided” processing, the steps of etching/diffusing and doping are carried out on one of the sides and repeated on the opposite side. Specifically, during the etching/diffusing step, the bulk of the semiconductor material is etched/diffused and the trench and or column is filled with a pre-doped material (e.g. polysilicon) so as to extend the trench and the hole to a predetermined distance of less than 100% from one of the first and second surfaces. It must be noted that only filling of the trench is needed to provide mechanical strength of the wafer. On the other hand, the column can be either be fully or partially filled. Once the partial trench/column is formed and filled, it is doped with either an n-type or p-type dopant by driving the dopant from the pre-doped material into the pre-filled trench/column, e.g. by high temperature diffusion. After completion of this stage, the etching of trench/column is performed on the opposite surface to match the pattern on the first surface. The next step extends the trench/column to meet the doped portion and it is once again doped with either an n-type or p-type dopant depending on the dopant used to match the dopant from the first surface. The trench/column can be either partially filled or filled on the second surface (back surface). Thus the electrode(s) extending entirely across the thickness of the bulk can be produced without the need for a support wafer. However, in order to simplify the manufacturing process, it is contemplated that at least in some embodiments, the 3D-Trench detectors are manufactured in accordance with a “single-side” process. As used in this specification, a single-side process means that the first and second electrodes are preferably etched from one side, e.g. the front side, but are not etched all the way through the bulk, leaving intact about 5 to 10% of the bulk's thickness. The second surface (or back side) of the bulk is left un-processed except for a thin protective layer of SiO₂ or other protective material applied thereto. Exemplary configurations of the 3D-Trench detectors of hexagonal type manufactured in accordance with present invention based on the dopant selected are presented in Table I.

For simplicity and ease of understanding, only hexagonal type detectors are shown in Table I to demonstrate the variability of configurations based on the depth of the electrode(s) and the selection of dopant for the electrode and/or the bulk of the semiconductor. However, the same attributes would be true if the detector had a rectangular, circular or any other polygonal shape.

FIG. 5B illustrates a cross-sectional view A-A of the 3D-Trench detector 500 shown in FIG. 5A. As illustrated in FIG. 5B, the first electrode 540 surrounds the second electrode 550, and the two electrodes are substantially concentric to and spaced apart from each other. The separation between electrodes (electrode spacing) λ_{c} may vary depending on detector applications. For example, for radiation hard detectors in high energy physics experiments, it may preferably be about 50 μm (λ_{c}=50 μm) such that a predetermined distance exists between the first and second electrode. It is to be understood that although the first and second electrode are indeed spaced apart from each other by the predetermined distance equal to λ_{c}, the space between the first and second electrodes is taken by the semiconductor material of bulk 510. Accordingly, the 3D-Trench detector of the hexagonal type includes at least a semiconductor bulk 510, a first electrode 540, and a second electrode 550 which is formed inside the first electrode, wherein the first electrode is completely surrounded by the second electrode, and the electrodes are spaced apart from each other by a predetermined distance. As stated earlier, the specific dimensions disclosed are not restrictive. Rather, these dimensions are presented for the sole purposes of reference and example. Other dimensions may be developed and adopted by those skilled in the art without departing from the teaching of the present disclosure.

### 1.2.1.2 Multi-Pixel 3D-Trench-CJ Detector of Hexagonal Type

FIG. 5C shows an example of a multi-pixel 3D-Trench-CJ detector of the hexagonal type. The multi-pixel 3D-Trench-CJ detector 501 is formed on a semiconductor (n- or p-type) bulk 511 having a first surface 521 and a second surface 531 that is separated from the first surface by a bulk thickness d. Multi-pixel 3D-Trench detector 501 includes a plurality of single-cell 3D-Trench units 501a to 501n. Each of the single-cell units 501a to 501n may be considered as a detecting unit or pixel that is formed in a manner substantially similar to the above-described single-cell 3D-Trench-CJ detector illustrated in FIG. 5A. As shown in FIG. 5C, all of the outer electrodes of the 3D-Trench-CJ cells may be connected together to a negative bias voltage (−V), and each inner electrode of the 3D-Trench-CJ cells may preferably be connected to an electronics channel 551 for signal readout. In the multi-pixel 3D-Trench-CJ detector 501 of FIG. 5C, the electrode (or pixel) pitch may preferably be arranged on the basis of the electrode spacing A of the basic single-cell 3D-Trench-CJ detector, as defined in FIG. 5A. Accordingly, the distance between the center electrodes of two adjacent unit cells may be equal to twice the distance between the first and second electrodes λ_{c} plus the radius r of the center electrode and the with W_{T} of the outer electrode,

$$space between center electrodes of adjacent unit cells = \frac{\sqrt{3}}{2} {λ}_{c} + r + {W}_{T} .$$

1.2.2. 3D-Trench Detectors with Outer Ring Junction (3D-Trench-ORJ)

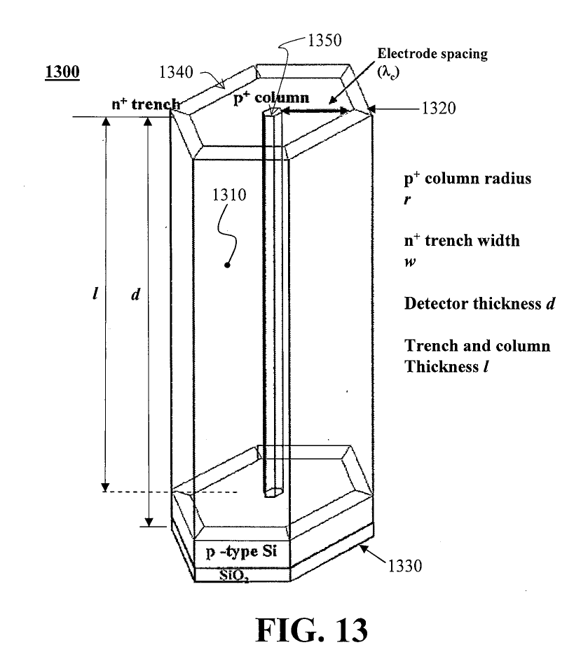

FIG. 13 illustrates another embodiment of a 3D-Trench detector of the hexagonal type. FIG. 13 shows a 3D-Trench detector 1300 similar in structure and physical dimensions to the 3D-Trench detector disclosed section 1.2.1.1, “Structure of a Single-cell 3D-Trench-CJ Detector of Hexagonal Type” in reference to FIGS. 5A and 5B. The main difference in the embodiment of FIG. 13, as compared to that of FIGS. 5A and 5B, is that 3D-Trench detector 1300 includes an outer ring junction, whereas detector 500 (in FIG. 5A) includes a central junction electrode. Specifically, in FIG. 13, the 3D-Trench detector 1300 includes a p-type semiconductor bulk 1310, a first electrode 1340, and a second electrode 1350. The p-type semiconductor bulk 1310 has a first surface 1320 and a second surface 1330 that is separated from the first surface by a bulk thickness d which is about 200 μm to 500 μm. The first electrode 1340 occupies a highly doped outer region of bulk 1310 that has been preferably etched and filled with n-type material (n⁺) so as to form a three-dimensional structure in the shape of a hexagonal trench. The second electrode 1350 occupies a highly doped inner region of bulk 1310 has been preferably etched and filled with p-type material (p⁺) so as to form a 3D column of hexagonal (or circular) cross-section. The hexagonal cross-section of the inner column (second electrode 1350) mirrors the cross-sectional shape of the hexagonal trench (1340). Preferably, the first electrode 1340 and second electrode 1350 extend into bulk 1310 from only one surface (first surface 1320) of the bulk without reaching the second surface. Thus, 3D-Trench detector 1300 is one-sided. The first and second electrodes are preferably concentric to and spaced apart from each other, such that the first electrode 1340 completely surrounds the second electrode 1350 with a portion of the bulk 1310 separating the two electrodes. The depth l that the first and second electrodes extend into the bulk can be determined in accordance with application needs. As an example, a depth l=d−20 μm may be suitable for some applications. On the second surface of bulk 1310 a thin layer of silicon dioxide (SiO₂) no more than a few micrometers in thickness is formed for protecting the bulk from environmental agents.

In the context of diode junctions, an n⁺/p junction (semiconductor junction) is formed between the inner surface of the first electrode 1340 (trench) and the semiconductor material of bulk 1310. For this reason, the first electrode 1340 is considered an outer-ring-junction electrode. Accordingly, for purposes of this specification, the 3D-Trench detector 1300 of this embodiment is referred to as a 3D-Trench outer-ring-junction or 3D-Trench-ORJ detector. The second electrode 1350 (p⁺ column) now serves as an ohmic contact for readout electronics. Thus, in contrast to the embodiment of FIG. 5A in which the inner column electrode forms a central junction (CJ), in the embodiment of FIG. 13 the outer trench electrode forms an outer-ring-junction (ORJ). The reversal from a central junction to an outer-ring-junction in the electrodes of the 3D-Trench detector of the hexagonal type, as discussed more in detail below, reverses the charge collection dynamics and results in considerable differences between the 3D-Trench-ORJ detector and the 3D-Trench-CJ detector.

It should be noted that the concept of 3D-Trench-ORJ detector is not limited to the n⁺/p junction discussed in this section, 1.2.2. If the bulk semiconductor is n-type, then the outer-ring trench will be doped p⁺, and the junction will be n/p⁺. This reversal is also applicable to the 3D-Trench-CJ detector discussed in section 1.2.1.

### 2. Electric Field Calculations

This section describes in some detail numerical calculation and analysis of simulated radiation detection in various embodiments of 3D-Trench detectors, as contemplated by this invention. Computation of applied potential, weighting field, free charge carrier transport dynamics (induced currents and charges), among others, are presented. The simulated system for electrode charge collection analysis is a single-cell monolithic silicon crystal with parameters as described in the respective subsections and illustrated in the corresponding drawings. The results of the following analysis show that excellent charge collection efficiency at nearly linear electric fields, and—in some special cases (e.g., when the over-depletion bias voltage is high enough so that a virtual junction is created)—near constant electric fields, can be obtained by the 3D-Trench detector with an outer-ring-junction.

### 2.1. Electric Field Considerations in a 3D-Trench Detector of Rectangular Type

In a 3D-detector, as previously discussed, the depletion of charge carriers is concentrated within the immediate area surrounding the vertical electrodes. In contrast, in planar 2D detectors depletion of charge carriers depends on the thickness of the semiconductor material. Similarly, the electric field in a 3D-detector is primarily radial with a concentration around the junction electrode, while the electric field in a 2D detector is substantially perpendicular to the cross-sectional area of the semiconductor material. In the embodiment of FIGS. 2A and 2B, the electric field between the first electrode 240 and the second electrode 250 is assumed to be substantially homogeneous. Specifically, it is assumed that in Region I (shown in FIG. 2B) in the x direction, between the parallel planes of the two electrodes, i.e. between the principal plane y-z of the center electrode and the y-z planes of the walls 240b, 240d of the outer electrode, the electric field is linear and uniform. Accordingly, there is an insignificantly low portion of electric field in the y or z directions between these two planes.

### 2.1.1. Electric Field Distribution

In mathematical terms, the electric field in Region I can be calculated from the general electric field distribution E(x y, z), where the E-field in the y and z directions is disregarded, as follows:

$$\begin{matrix}E ( x , y , z ) = E ( x ) \\ = \{ \begin{matrix}\frac{{eN}_{eff}}{{ɛɛ}_{0}} ( w - x ) , \\ ( \frac{1}{2} {W}_{T} < x \leq w , - \frac{1}{2} L < y < \frac{1}{2} L , 0 < z < l ) \\ - \frac{{eN}_{eff}}{{ɛɛ}_{0}} ( w + x ) , \\ ( - w < x \leq - \frac{1}{2} {W}_{T} , - \frac{1}{2} L < y < \frac{1}{2} L , 0 < z < l )\end{matrix}\end{matrix} \qquad ( 1 )$$

where e is the electronic charge, ε₀ is the permittivity of vacuum (8.854×10⁻¹² F/m), ε is the permittivity of the semiconductor material (for silicon ε_{Si}=11.7 ε₀), w is the depletion width (w≦λ_{c}) in the x direction, N_{eff} is the effective doping concentration (or space charge density) of the substrate or bulk. All other parameters are defined in FIGS. 2A and 2B.

A non-uniform electric field (in x and y directions) exists only in the small regions between the two vertical edges of the second electrode 250 and the two internal surfaces of walls 240a and 240c of the first electrode 240. Thus, in regions other than Region I, where

$$[ - ( \frac{1}{2} L + {λ}_{c} ) < y < - \frac{1}{2} L and \frac{1}{2} L < y < ( \frac{1}{2} L + {λ}_{c} ) ] ,$$

the electric field is considered nearly linear (or preferably sub-linear). In these regions the field distributions are given by:

$$\begin{matrix}E ( r ) = \frac{{eN}_{eff}}{{ɛɛ}_{0}} ( w - r ) ( 0 < θ < 180 ) & ( 2 ) \\ and & \\ E ( r ) = \frac{{eN}_{eff}}{2 {ɛɛ}_{0}} ( \frac{{w}^{2}}{r} - r ) ( 0 < θ < 180 ) & ( 3 )\end{matrix}$$

where r and θ are the cylindrical coordinates of the electric field originated from each of the vertical edges of the second electrode 250, respectively.

### 2.2. Electric Field Considerations in a 3D-Trench-CJ Detector of Hexagonal Type

In FIG. 5A, a hexagonal geometry has been adopted for purposes of optimizing packaging in space. However, a more uniform electric field distribution with substantially simplified calculations can be obtained when a 3D-Trench detector of the hexagonal type is approximated by a cylindrical geometry. Specifically, for all the calculations that follow, the 3D-Trench detector of the hexagonal type has been reduce to a cylindrical 3D-Trench detector by substituting the second electrode 550 (hexagonal column or inner electrode) with a cylindrical column having the same radius as that of the hexagonal electrode, e.g., about 10 μm in this embodiment, and substituting the hexagonal trench electrode with a cylindrical surface being coaxial to the cylindrical column and being located a distance R equivalent to the distance from the center the center of the detector cell to the outer surface of the trench. Thus, the electric field in a unit cell of the 3D-Trench detector of the hexagonal type can effectively be approximated by the geometry of a single cylindrical cell 3D-Trench detector.

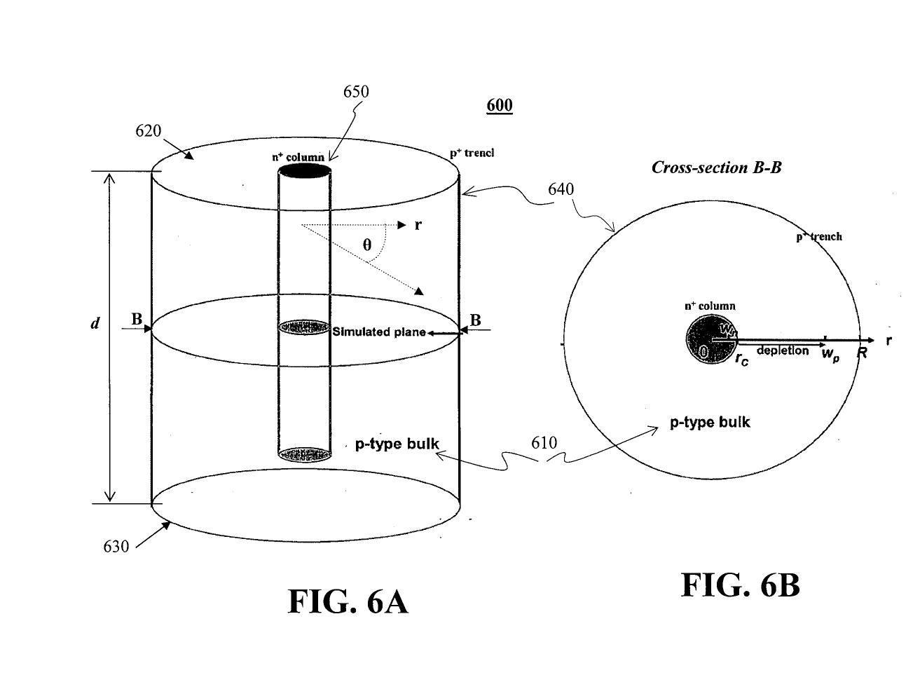

FIG. 6A schematically illustrates a cylindrical geometry of the 3D-Trench-CJ detector used to simulate the electric field in a single-cell 3D-Trench-CJ detector of the hexagonal type. In FIG. 6A, as approximated by the cylindrical geometry, a cylindrical cell 600 is formed by a cylindrical p-type bulk 610 having a thickness d, a first surface 620 and a second surface 630 that is separated from the first surface 620 by the bulk thickness d. Within the p-type bulk 610, the first electrode (or trench) is approximated by a cylindrical surface 640 (p⁺ trench), and the second electrode is approximated by a rod or cylindrical n⁺ column 650. The p-n junction (semiconductor junction), in the context of semiconductor diode junctions, is formed in a region surrounding the center electrode at a plane where the outer surface of n⁺ column 650 joins the semiconductor material of bulk 610. The n⁺ column 650 extends into the bulk 610 from the first surface 620 without reaching the second surface 630.

FIG. 6B illustrates a cross-sectional view, representing a cut B-B along a simulated plane of the cylindrical cell 600. For simulation purposes, the cylindrical geometry of the 3D-Trench-CJ detector defines a center point “0” at the center of the inner electrode (n⁺ column 650) and an outer cylindrical plane (p⁺ trench 640) located at a distance R from said center point “0.” The p-type bulk 610 has a depletion width wₚ and an effective doping concentration N_{eff}. The n⁺ column 650 has a radius r_{c}, a depletion width wₙ and a doping concentration N_{d}. Accordingly, the depletion region as a function of a polar coordinate r is composed of two parts. The first part extends within the depletion width of the n⁺ column 650 in the region where (r_{c}−wₙ≦r<r_{c}), and the second part extends within the depletion width of the p-type bulk in the region where (r_{c}≦r≦wₚ).

As discussed in the Background section of this specification, when an ionizing particle or high-energy photon interacts with the sensitive volume of the semiconductor material, charge carriers (electron-hole pairs) are generated. How quickly electrons and holes are swept from the depletion region is determined by the electric field. In the cylindrical geometry of the hexagonal type 3D-Trench-CJ detector (see e.g., FIG. 5D), the electric field for charge collection is primarily radial with some minor axial components present only at the ends of the cylindrical column 650. The electric field E is determined by the charge distribution through Poisson's equation. In the cylindrical cell 600, Poisson's equation is solved for the case of the electric field in an infinitely long cylinder with a radius determined by the width of the depletion region where the electrical field distribution E(r, θ) satisfies the Poisson equation in the polar (r, θ) coordinate system.

### 2.2.1 Electric Field Distribution

For analytical calculations, the electric profile of a single-cell of a 3D-Trench-CJ detector is considered substantially homogenous within the approximated cylindrical cell 600. Specifically, it is considered that the electric field has no θ dependence and it varies only as a function of the polar coordinate r, except in the regions near the two ends of the central column 650. Accordingly, a negligible non-uniform electric field exists only in the small regions near the ends of the central column 650. Everywhere else along the n⁺ column 650, the electric field is found by solving the Poisson equations in polar coordinates for the two parts of the depletion region, as follows:

$$\{ \begin{matrix}\frac{1}{r} \frac{d}{dr} ( rE ( r ) ) = \frac{{eN}_{d}}{{ɛɛ}_{0}} ( {r}_{C} - {w}_{n} \leq r < {r}_{C} ) \\ \frac{1}{r} \frac{d}{dr} ( rE ( r ) ) = - \frac{{eN}_{eff}}{{ɛɛ}_{0}} ( {r}_{C} \leq r \leq {w}_{p} )\end{matrix} \qquad ( 4 )$$

with boundary conditions:

$$\{ \begin{matrix}E ( {r}_{C} - {w}_{n} ) = 0 \\ E ( {( {r}_{C} )}^{-} ) = E ( {( {r}_{C} )}^{+} ) \\ E ( {w}_{P} ) = 0\end{matrix} \qquad ( 5 )$$

the electric field for a single cylindrical cell of the 3D-Trench-CJ detector is given by:

$$E ( r ) = \{ \begin{matrix}0 & ( r < {r}_{C} - {w}_{n} ) \\ \frac{1}{2} \frac{{eN}_{d}}{{ɛɛ}_{0}} r [ 1 - \frac{{( {r}_{C} - {w}_{n} )}^{2}}{{r}^{2}} ] & ( {r}_{C} - {w}_{n} \leq r < {r}_{C} ) \\ \frac{1}{2} \frac{{eN}_{eff}}{{ɛɛ}_{0}} r [ \frac{{( {r}_{C} + {w}_{p} )}^{2}}{{r}^{2}} - 1 ] & ( {r}_{C} \leq r < {r}_{C} + {w}_{p} ) \\ 0 & ( r \geq {r}_{C} + {w}_{p} )\end{matrix} \qquad ( 6 )$$

where N_{d}, r_{c} and wₙ are the doping concentration, the radius, and the depletion width of the n⁺ column 650, respectively. N_{eff} and wₚ are the effective doping concentration and the depletion width in the p-type substrate or bulk, respectively.

The depletion widths wₙ and wₚ satisfy the following condition:

$${N}_{d} [ 1 - \frac{{( {r}_{C} - {w}_{n} )}^{2}}{{r}_{C}^{2}} ] = {N}_{eff} [ \frac{{( {r}_{C} + {w}_{p} )}^{2}}{{r}_{C}^{2}} - 1 ] \qquad ( 7 )$$

and they can be determined together with the following equation:

$${\int }_{{r}_{C } - {w}_{n}}^{{r}_{C} + {w}_{p}} E ( r ) d r = V + {V}_{bi} \qquad ( 8 )$$

where V is the absolute value of the applied reverse voltage and V_{bi} is the built-in potential. Carrying out the integration in Equation (8) yields Equation (9) as follows:

$$\frac{1}{2} \frac{{eN}_{d}}{{ɛɛ}_{0}} \{ \frac{1}{2} [ {r}_{C}^{r} - {( {r}_{C} - {w}_{n} )}^{2} ] - {( {r}_{C} - {w}_{n} )}^{2} ln \frac{{r}_{C}}{{r}_{C} - {w}_{n}} \} + \frac{1}{2} \frac{{eN}_{eff}}{{ɛɛ}_{0}} \{ {( {r}_{C} + {w}_{p} )}^{2} ln \frac{{r}_{C} + {w}_{p}}{{r}_{C}} - \frac{1}{2} [ {( {r}_{C} + {w}_{p} )}^{2} - {r}_{C}^{2} ] \} = V + {V}_{bi}$$

For most cases, the ratio of the effective doping concentration of the p-type bulk to the doping of the n⁺ column is relatively small, N_{eff}/N_{d}<10⁻⁵ even after irradiation with a 1×10¹⁶ n_{eq}/cm² fluence. Thus, the depletion width wₙ of the n⁺ column calculated from Equations (7) and (9) is much smaller than the depletion width wₚ of the p-type bulk wₚ (wₙ/wₚ<10⁻⁴) and r_{c}(wₙ/r_{c}<10⁻³). Accordingly, Equation (9) can be simplified to solve namely for the depletion width wₚ of the p-type bulk, such that:

$${( {r}_{C} + {w}_{p} )}^{2} ln \frac{{r}_{C} + {w}_{p}}{{r}_{C}} - \frac{1}{2} [ {( {r}_{C} + {w}_{p} )}^{2} - {r}_{C}^{2} ] = \frac{2 {ɛɛ}_{0} ( V + {V}_{bi} )}{{eN}_{eff}} \qquad ( 10 )$$

and the electric field in the p-type bulk can be calculated with:

$$E ( r ) = \frac{1}{2} \frac{{eN}_{eff}}{{ɛɛ}_{0}} r [ \frac{{( {r}_{C} + {w}_{p} )}^{2}}{{r}^{2}} - 1 ] ( {r}_{C} \leq r < {r}_{C} + {w}_{p} ) \qquad ( 11 )$$

### 2.2.1.1 Depletion Voltage in a Non-Irradiated 3D-Trench-CJ Detector

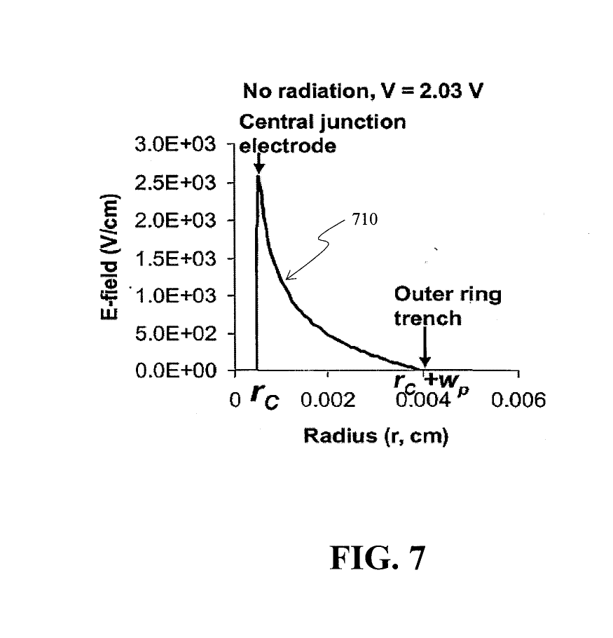

FIG. 7 shows an electric field profile 710 within a single-cell of a non-irradiated 3D-Trench-CJ detector of the hexagonal type (such as the one set forth above in FIG. 5A and approximated by the cylindrical geometry of FIG. 6A). The electric field (E-field) values are plotted on the ordinate (y-axis), while the radius is plotted on the abscissa (x-axis). In the calculations used for FIG. 7 and the other Figures that follow, the simulated 3D-Trench detector includes an inner electrode (column) radius r_{c} of five micrometers (r_{c}=5 μm) and an outer electrode (trench) width W_{T} of 10 micrometers (W_{T}=10 μm), unless otherwise specifically stated. FIG. 7 illustrates that it takes about 2.03 volts to deplete 35 μm of a non-irradiated p-type bulk with an effective doping concentration of 1×10¹² cm⁻³ (N_{eff}=1×10¹² cm⁻³). Since—at small r values—the electric field E is dominated by the form 1/r (see Equation (11)), the electric field is much higher near the inner electrode (i.e., at or near the n⁺ column) than in the p-type bulk 610. Accordingly, the E-field at r=r_{c} (i.e. at the outer surface of the first or central electrode) is much higher than at r=r_{c}+wₚ (at the end of the depletion region in the bulk). This will cause higher depletion voltage for a fixed depletion width as compared to the linear electric field case for the planar 2D detector and the 3D-Trench rectangular type detector (e.g., FIG. 2A and Equation (1)).

### 2.2.1.2. Depletion Voltage in an Irradiated 3D-Trench-CJ Detector

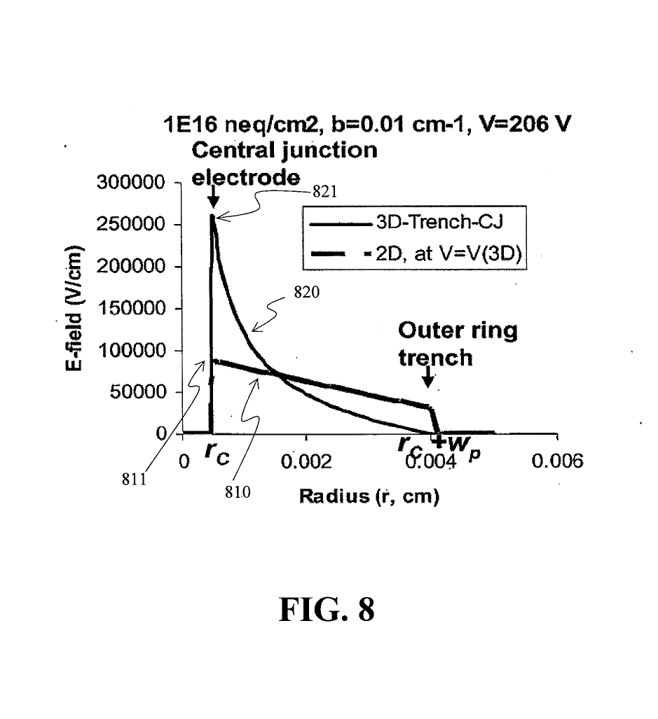

FIG. 8 illustrates an electric field profile of an irradiated 3D-Trench-CJ electrode detector (plot 820) and an electric field profile a 2D planar detector (plot 810), both as function of the coordinate along the depletion width. In FIG. 8, the electric field profile (plot 820) of the 3D-Trench-CJ detector shows the intensity of the electric field as the depletion width of the p-type bulk extends from r=r_{c} to r_{c}+wₚ, as a function of the polar coordinate r. The electric field profile (810) of the planar 2D detector shows that the intensity of the electric field is essentially linear as the depletion width in the detector extends from a junction electrode into the semiconductor material, and to the outer ring trench. In comparing the two plots of FIG. 8, it is evident that the electric field profile (plot 820) of the 3D-Trench-CJ detector near the central junction electrode (at point 821) is about 3 times higher than the electric field profile of the 2D detector near its junction electrode (at point 811). Both electric field profiles consider the same bias voltage (V=206V), an equivalent depletion width (from r_{c} to r_{c}+wₚ), and the same irradiation fluence (1×10¹⁶ n_{eq}/cm²). Similar to the non-irradiated case, the electric field in an irradiated 3D-Trench-CJ detector is much higher near the inner electrode, i.e., at or near the n⁺ column 650, than far into the p-type bulk 610, i.e. near the cylindrical surface R of FIG. 6B.

### 2.2.1.3. Over Depletion Voltage in an Irradiated 3D-Trench-CJ Detector

In case of over depletion, it is shown from the following equations that the high electric field further concentrates around the center electrode (n⁺ column 650 in FIG. 6B). The electric field distribution for over depletion is given by:

$$E ( r ) = \frac{1}{2} \frac{{eN}_{eff}}{{ɛɛ}_{0}} r [ \frac{{R}^{2}}{{r}^{2}} - 1 ] + \frac{V - {V}_{fd}}{r ln \frac{R}{{r}_{C}}} ( {r}_{C} \leq r < R ) ( for 3 D \text{-} Trench \text{-} CJ ) \qquad ( 12 )$$

where the full depletion voltage V_{fd} can be solved by the following equation:

$$\begin{matrix} {R}^{2} ln \frac{R}{{r}_{C}} - \frac{1}{2} ( {R}^{2} - {r}_{C}^{2} ) = \frac{2 {ɛɛ}_{0} ( {V}_{fd} + {V}_{bi} )}{{eN}_{eff}} & ( 13 ) \\ or \text{:} & \\ {V}_{fd} = \frac{{eN}_{eff}}{2 {ɛɛ}_{0}} [ {R}^{2} ln \frac{R}{{r}_{C}} - \frac{1}{2} ( {R}^{2} - {r}_{C}^{2} ) ] - {V}_{bi} ( for 3 D \text{-} Trench \text{-} CJ ) & ( 14 )\end{matrix}$$

If the 3D-Trench-CJ detector is irradiated by neutrons and/or charged particles, the effective doping concentration N_{eff} will fluctuate linearly with 1 MeV neutron-equivalent fluence Φ_{neq}, as shown by:

N_{eff}=bΦ_{neq}(for Φ_{neq}>10¹⁴ n_{eq}/cm²) (15)

where b is the proportionality constant of effective doping concentration to a 1 MeV neutron-equivalent fluence.

The proportionality constant of effective doping concentration to fluence is about 0.01 cm⁻¹ for oxygenated silicon detectors after being irradiated by high-energy protons. Thus, it is reasonable to infer that at higher fluence levels, higher effective doping concentrations may be expected. Indeed, it is expected that by increasing the radiation fluence from 1×10¹⁴ n_{eq}/cm² to a fluence of 1×10¹⁶ n_{eq}/cm², the fluence expected to be obtained in the LHC collider upgrade or SLHC, the value of N_{eff} of a p-type bulk will increase by a factor of 100. In other words, the effective doping concentration N_{eff}=1×10¹² cm⁻³ of a 35-μm p-type bulk of silicon would increase to 1×10¹⁴ cm⁻³, when the 35-μm p-type bulk is irradiated by high-energy protons with a fluence of 1×10¹⁶ n_{eq}/cm². Moreover, as can be seen from Equation (14), the detector full depletion voltage is also proportional to N_{eff}. Thus, the full depletion voltage will increase by this factor as well.

2.2.1.4. Electric Field in Non-Irradiated Vs. Irradiated 3D-Trench-CJ Detector

In comparing FIG. 8 to FIG. 7, it is interesting to note that the form of the electric field profile for the 3D-Trench-CJ detector is almost the same in both Figures, except that the absolute values are increased by a factor of 100 in plot 820 of FIG. 8 as compared to the values of plot 710 in FIG. 7. Since the full depletion voltage in an irradiated detector is 100 times larger than in the non-irradiated detector, it is evident then that both the values of the electric field and the depletion voltage are proportional to the irradiation fluence. This relationship can also be seen from Equations (11) and (14). Therefore, it may be that radiation fluences higher than 1/10¹⁶ n_{eq}/cm² may push the 3D-Trench-CJ detector over the breakdown field limit, e.g., 3×10¹⁵ V/cm for silicon, which would severely hinder the detector's operation or even render the detector inoperable. As fully discussed in section 1.2.2. “3D-Trench Detectors with Outer Ring Junction,” this problem may be overcome by forming the semiconductor junction at the outer electrode (trench) instead of at the center electrode. Nevertheless, it should be noted that the 3D-Trench-CJ detector gives a more homogeneous electric field distribution (no low field regions, no saddle points in electric potential profile), and its first electrode (or trench) creates a dead space that minimizes or prevents charge sharing between adjacent pixels, which may be advantages as compared to some properties of the prior art 3D detectors.

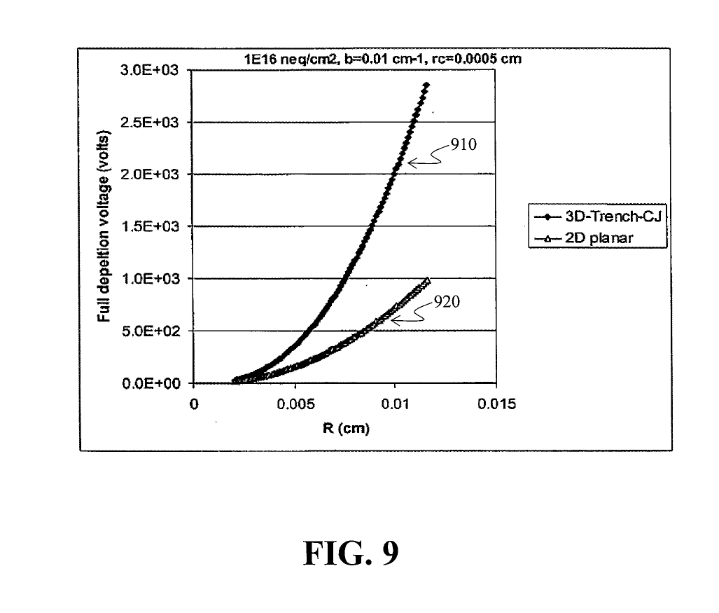

FIG. 9 comparatively illustrates full depletion voltage as a function of outer radius (R) for an irradiated (at 1×10¹⁶ n_{eq}/cm² fluence) 3D-Trench-CJ electrode detector, along with full-depletion voltage of a planar 2D detector as a function of distance between electrodes. In FIG. 9, plot 910 represents full depletion voltage values in a single-cell 3D-Trench-CJ detector for an electric field namely concentrated around the center electrode (column) region and extending outwards as a function of the depletion width. Plot 920 represents full depletion voltages values necessary to deplete a planar 2D detector of a thickness equivalent to the radius of the 3D-Trench-CJ detector. FIG. 9 shows that he full depletion voltage in a 3D-Trench-CJ detector increases much faster with radius as compared to that of a 2D planar detector with thickness, under the same irradiation fluence of 1×10¹⁶ n_{eq}/cm². This effect is believed to be caused by the small electrode effect around the central junction column. Specifically, the much higher depletion voltages produce very high electrical field profiles that are focused on to the small junction column (inner electrode). This high concentration of electric fields can be unstable and can cause intrinsic breakdown near or at the junction column, especially at over depletion levels.

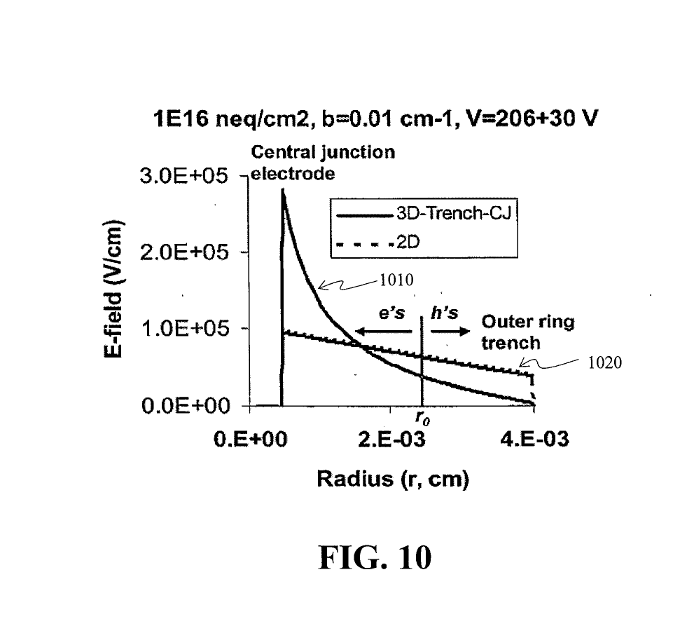

FIG. 10 illustrates electronic field profiles for the over depletion case. FIG. 10 shows an electric field profile 1010 for charge collection of an ionizing particle with fluence 1×10¹⁶ n_{eq}/cm² hitting a 3D-Trench-CJ detector at an incidence point r₀, from where the generated charge carriers (e's and h's) drift towards a central junction electrode and an outer ring trench, respectively. The electric field profile 1020 shows the same detection process for a planar 2D detector, under the same fluence and over an equivalent distance between its electrodes. As illustrated in FIG. 10 (when compared to FIG. 8), adding 30V over the full depletion voltage further increases the concentration of the electric field near the central junction electrode, where the high field is already located. Therefore, even if the bias voltage is driven beyond the full depletion level of a 3D-Trench-CJ detector, this does not prevent the electric field from further concentrating near the central junction electrode.

This effect can be expected when considering Equation (12). In Equation (12) the electric field due to over depletion is proportional to 1/r. At large values of r (e.g., near r=R), an increase in bias voltage beyond full depletion levels (at over depletion) does not increase the electric field near the low field region. However, at small values of r (e.g., near r=r_{c}) over depletion significantly increases the electric field in the high field region. As illustrated in FIG. 10, the addition of 30V over the full depletion voltage (V=206+30V) merely increases the electric field from 0V/cm to 4×10³V/cm near the low field region. However, plot 1010 in FIG. 10 illustrates that the same increase in bias voltage increases the electric field from 2.5×10⁵V/cm to 2.8×10⁵V/cm in the high field region, i.e., at r=r_{c}. Thus, increasing the bias voltage over the full depletion level appears to only increase the probability of eventually damaging the detector rather than improving the electrical field profile. Notwithstanding these shortcomings, the electric field in the 3D-Trench-CJ detector is still considered better than that of conventional 3D detectors. For example, due to the non-dependence on the θ coordinate, a 3D-Trench-CJ detector gives a more homogeneous electric field distribution (no low field regions, no saddle points in electric potential profile), as compared to the conventional 3D detectors. It will also have the usual advantages of a 3D detector over the 2D planar detector in terms of full depletion voltage and CCE as discussed in the Background section.

### 2.2.2. Calculation of Weighting Fields in a 3D-Trench-CJ Detector of Hexagonal Type

The introduction of signal into the electrodes of a detector is governed by the principle that the instantaneous current induced on a given electrode is equal to the products of the charge of the carrier, its drift velocity (which is proportional to the electric field) and the weighting field E_{w}. The weighting field is determined by applying unit potential to the measurement electrode and zero potential to all others while treating the bulk as a vacuum with no space charges. While the electric field determines the charge trajectory and drift velocity, the weighting field depends only on the geometry of the detector and determines charge carriers' coupling to a specific electrode.

In the case of a single-cell 3D-Trench detector of the hexagonal type, which may be accurately approximated by a cylindrical geometry in which there is no dependence on the polar coordinate θ, as discussed above, the calculation of the weighting potential Φ_{w} and weighting field E_{w} is obtained from:

$$\frac{1}{r} \frac{d}{dr} ( {rE}_{w} ( r ) ) = 0 ( {r}_{C} \leq r < R ) \qquad ( 16 )$$

with boundary conditions:

$$\{ \begin{matrix}{Φ}_{w} ( {r}_{C} ) = 1 \\ {Φ}_{w} ( R ) = 0 \\ {E}_{w} ( r ) = - \frac{d Φ ( r )}{dr}\end{matrix} \qquad ( 17 )$$

The solutions are:

$$\{ \begin{matrix}{Φ}_{w} ( r ) = \frac{ln ( r / R )}{ln ( {r}_{C} / R )} \\ {E}_{w} ( r ) = \frac{1}{r} \cdot \frac{1}{ln ( R / {r}_{C} )}\end{matrix} \qquad ( 18 )$$

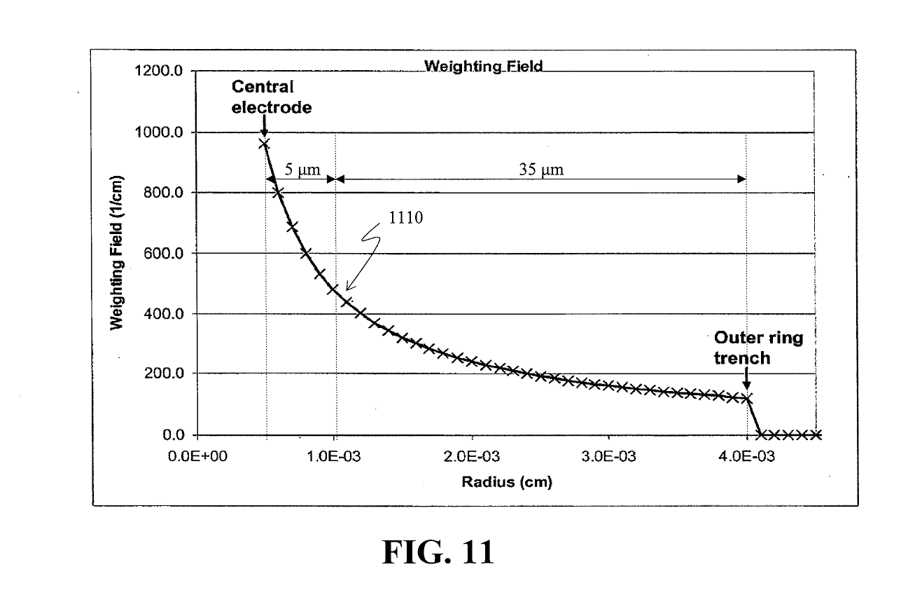

FIG. 11 illustrates the weighting field profile of a single-cell 3D-Trench-CJ detector. In FIG. 11, curve 1110 represents the weighting field for the single-cell 3D-Trench-CJ detector as that described in reference to FIG. 6 above, in which the radius r_{c} of the inner electrode (center n⁺ column 650) is equal to 5 micrometers (r_{c}=5 μm), and the distance from the center of the inner electrode to the outer surface of the outer electrode R is equal to 40 micrometers (R=40 μm). FIG. 11 shows that the weighting field is highly concentrated near the central collecting electrode (column n⁺). The concentration of the weighting field near the central (or inner) electrode is attributed to the small electrode effect. Specifically, as illustrated in FIG. 11, curve 1110 starts rather high and sharply drops from approximately 1000 cm⁻¹ to about 450 cm⁻¹ within the first 5 μm from the central collecting electrode column. Subsequently, the field decreases slowly from about 450 cm⁻¹ to 120 cm⁻¹ (in the region from 5 μm to 35 μm away from the central collecting electrode column).

### 2.2.3. Induced Current in a 3D-Trench-CJ Detector

The current induced by free carriers drifting in the electric field is proportional to the product of the weighting field and the carrier drift velocity v_{dr}:

$${v}_{dr}^{e , h} ( r ) = \frac{{μ}^{e , h} E ( r )}{1 + \frac{{μ}^{e , h} E ( r )}{{v}_{s}^{e , h}}} \qquad ( 19 )$$

where μ^{e,h} is the mobility of the saturation velocity Vₛ^{e,h} for electrons (e) or holes (h).

For a minimum ionizing particle (MIP), the generated charge per unit distance in a silicon bulk is Qₒ/d=80 e's/μm. A MIP is a particle whose mean energy loss rate through matter is close to a minimum. When a fast charged particle passes through matter, it ionizes or excites the atoms or molecules that it encounters, losing energy in small steps. The mean rate at which it loses energy depends on the material, the kind of particle, and the particle's momentum. In practical cases, most relativistic particles, e.g., cosmic-ray muons, are minimum ionizing particles. For a 3D electrode detector, the charge generated by a MIP is along the thickness d of the bulk, i.e., independent of the drift direction, and it is 80 e's/μm*d. In the case of a one-sided 3D-detector, the generated charge is 80 e's/μm*d_{eff}, where d_{eff} is the effective thickness of the substrate, which generally is slightly less that the thickness d. Thus, in a single-cell 3D-Trench-CJ detector, the induced current by a charge at rₒ is:

$${i}^{e , h} ( t ) = 80 {e}^{′} s / μm \cdot {d}_{eff} \cdot {E}_{W} \cdot {v}_{dr}^{e , h} \cdot {e}^{\frac{t}{{τ}_{t}}} \qquad ( 20 )$$

and the collected charges are:

$$\begin{matrix}{Q}^{e , h} = 80 {e}^{′} s / μm \cdot {d}_{eff} {\int }_{0}^{{t}_{dr}^{e , h} ( {r}_{0} )} {E}_{W} \cdot {v}_{dr}^{e , h} \cdot {e}^{\frac{t}{{τ}_{t}}} d t & ( 21 ) \\ and Q = {Q}^{e} + {Q}^{h} & \end{matrix}$$

where t_{dr}^{e} is the drift time for electrons from rₒ→r_{c}, and t_{dr}^{h} is the drift time for holes from rₒ→R, and τₜ is the carrier trapping constant given by:

$$\frac{1}{{τ}_{t}} = 5 \cdot {10}^{- 7} {Φ}_{{n}_{eq}} \qquad ( 22 )$$

where Φₙ_{_{eq}} is the 1 MeV neutron equivalent fluence.

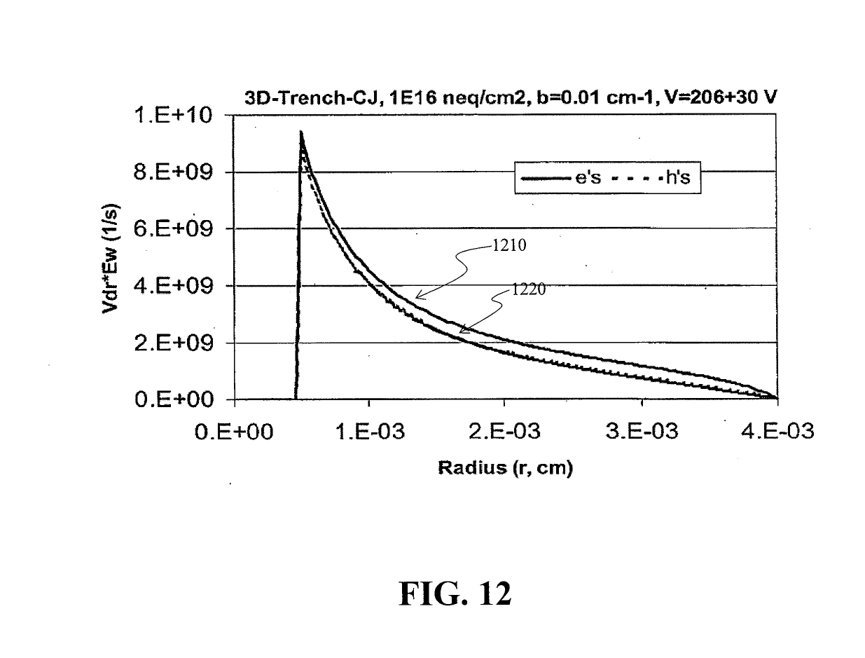

FIG. 12 illustrates a product of carrier drift velocity and weighting field in a single cell of a 3D-Trench-CJ detector as a function of the distance (radius) traveled by the carriers. In FIG. 12, plots 1210 and 1220 illustrate the product of carrier drift velocity and weighting field (v_{dr}*E_{w}(1/s)) of electrons (e's) and holes (h's), respectively, in a single-cell 3D-Trench-CJ detector of the hexagonal type. As illustrated in FIG. 12, it is evident that there is little induced current of a moving free carrier until it moves near the central collecting electrode column. Specifically, from plots 1210 and 1220, it can be inferred that significant induced current is detected only from within about 10 μm from the central electrode. For very highly irradiated detectors, in applications such as high-energy physics, for example, this situation may not be desirable since charges (electrons in this case) more than about 20 μm away from the central collecting electrode may be negatively affected by trapping before making significant contribution to the induced current (and therefore collected charge). In other applications, however, a high weighting field concentration near the central electrode may be advantageous for 3D-Trench-CJ detector. For example, in CZT detectors for medical imaging applications and gamma spectroscopy, the small electrode (or pixel) effect allows one to weight almost all of the induced charge to those charge carriers moving nearest the collection electrode region, thereby negating problems from poor hole collection, and collect nearly the total charge.

### 2.3. Electric Field Considerations in the 3D-Trench-ORJ Detector

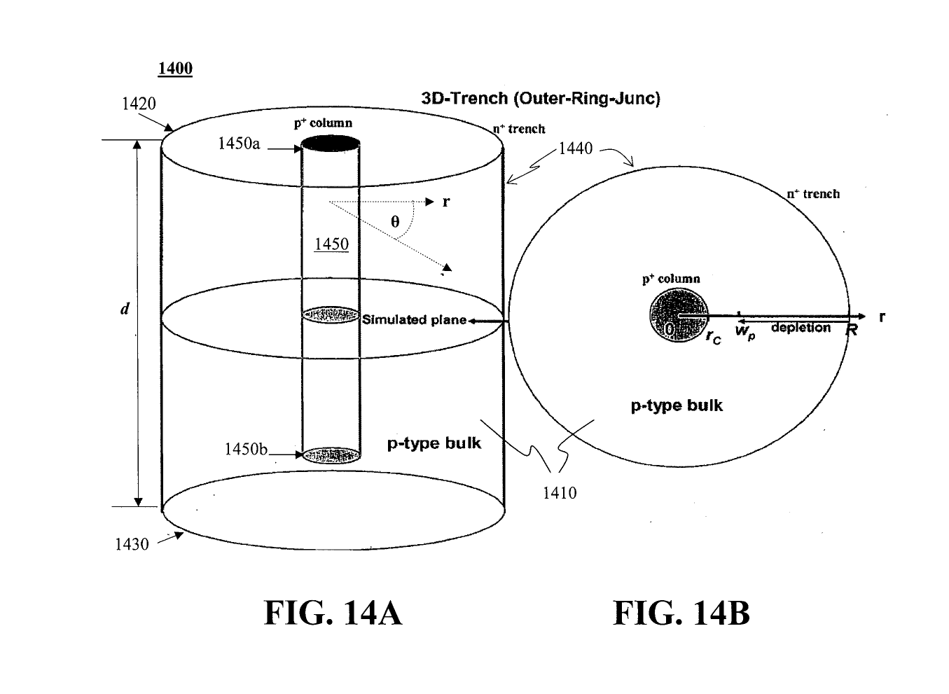

Although a hexagonal geometry is preferably adopted for purposes of optimizing packaging, calculations of electric field distribution in a 3D-Trench detector of the hexagonal type can be simplified when such a detector is approximated by a cylindrical geometry. FIGS. 14A and 14B illustrate schematically perspective and cross-sectional views, respectively, of a cylindrical geometry for electric field calculations in a single-cell 3D-Trench-ORJ detector. In FIG. 14A, a single-cell 3D detector 1400 is formed by a cylindrical p-type bulk 1410 which extends from a first surface 1420 to a second surface 1430 separated from the first surface by a thickness d. Within the p-type bulk 1410, the first electrode is approximated by a cylindrical surface 1440 (n⁺ trench), while the second electrode is approximated by a p⁺ rod or column 1450. The p⁺ column 1450 has a first end 1420a and a second end 1420b. The first end 1420a of the p⁺ column 1450 is joined to bulk 1410 at the first surface 1420. The second end 1420b of p⁺ column 650 is located deep within the p-type bulk 1410, but does not reach to the second surface 1430.

A cross-sectional view along a simulated plane C-C of the single-cell 3D detector 1400 is represented at FIG. 14B. For simulation purposes, it is assumed that the electric field originates at point R and extends inwardly as a function of polar coordinate r across depletion region wₚ. For analytical calculations, the electric profile of a single-cell 3D-Trench-ORJ detector is considered substantially homogenous within the cell. Specifically, it is considered that the electric field has no θ dependence and varies only as a function of r, except in the regions near the two ends of the central column 1450. In other words, the carrier transport dynamics of the 3D-Trench-ORJ detector are substantially similar to those of the 3D-Trench-CJ detector, except that the electric field for charge collection, as discussed below, is concentrated primarily on the outer region of the cell.

### 2.3.1 Electric Field Distribution

The electric field in the p-type bulk can be calculated using the geometry of FIGS. 14A and 14B, as set forth below. It is to be noted, however, that this embodiment is not limited to the p-type bulk. Indeed, a detector with an n-type bulk may also be easily fabricated. In which case, for an n-type bulk, one would simply switch n⁺ [symbol] p⁺, p [symbol] n, and e [symbol] h in all of the calculations and figures below. In the cylindrical geometry of FIG. 14, the electric field is given by:

$$\frac{1}{r} \frac{d}{dr} ( rE ( r ) ) = - \frac{{eN}_{eff}}{{ɛɛ}_{0}} ( {r}_{C} < R - {w}_{p} \leq r \leq R ) \qquad ( 23 )$$

with boundary conditions:

$$\{ \begin{matrix}E ( R - {w}_{p} ) = 0 \\ {\int }_{R - {w}_{p}}^{R} E ( r ) d r = - ( V + {V}_{bi} )\end{matrix} \qquad ( 24 )$$

which yields:

$$E ( r ) = - \frac{{eN}_{eff}}{2 {ɛɛ}_{0}} r [ 1 - \frac{{( R - {w}_{p} )}^{2}}{{r}^{2}} ] ( {r}_{C} < R - {w}_{p} \leq r \leq R ) \qquad ( 25 )$$

where wₚ is determined from:

$$\frac{1}{2} [ {R}^{2} - {( R - {w}_{p} )}^{2} ] - {( R - {w}_{p} )}^{2} ln \frac{R}{R - {w}_{p}} = \frac{2 {ɛɛ}_{0} ( V + {V}_{bi} )}{{eN}_{eff}} \qquad ( 26 )$$

### 2.3.1.1 Electric Field at Full Depletion Voltage

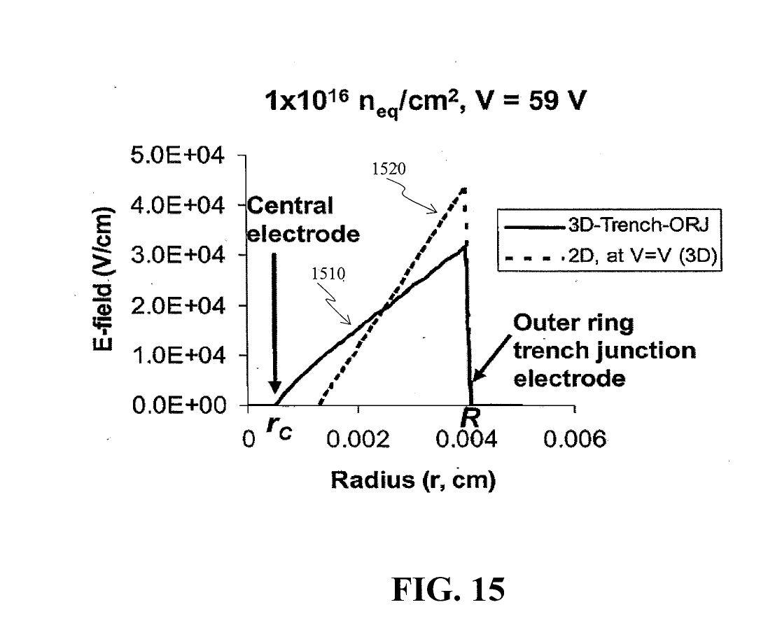

FIG. 15 shows a graph that comparatively illustrates electric field profiles in a 3D-Trench-ORJ and a planar 2D detector. In FIG. 15, plot 1510 represents the electric field of a 3D-Trench-ORJ and plot 1520 represents the electric field of a planar 2D detector. It is noted that for comparison and better illustration purposes, in FIGS. 15 and 17-19, the values plotted are absolute values because the E-fields are negative. In both plots (1510 and 1520) of FIG. 15, a 35 μm bulk of silicon under an irradiation of 1×10¹⁶ n_{eq}/cm² and a charge collection electric field under a full depletion bias voltage of 59 volts are assumed.

### 2.3.1.2 Electric Field at Over Depletion Voltage

At the condition of over-depletion, the electric field profile in a 3D-Trench-ORJ detector can be expressed as:

$$E ( r ) = - \frac{1}{2} \frac{{eN}_{eff}}{{ɛɛ}_{0}} r [ 1 - \frac{{r}_{C}^{2}}{{r}^{2}} ] - \frac{V - {V}_{fd}}{r ln \frac{R}{{r}_{C}}} ( {r}_{C} \leq r \leq R ) ( for 3 D \text{-} Trench \text{-} ORJ ) \qquad ( 27 )$$

wherefrom the full depletion voltage V_{fd} can be calculated from:

$${V}_{fd} = \frac{{eN}_{eff}}{2 {ɛɛ}_{0}} [ [ \frac{1}{2} ( {R}^{2} - {r}_{C}^{2} ) - {r}_{C}^{2} ln \frac{R}{{r}_{C}} ] ] - {V}_{bi} ( for 3 D \text{-} Trench \text{-} ORJ ) \qquad ( 28 )$$

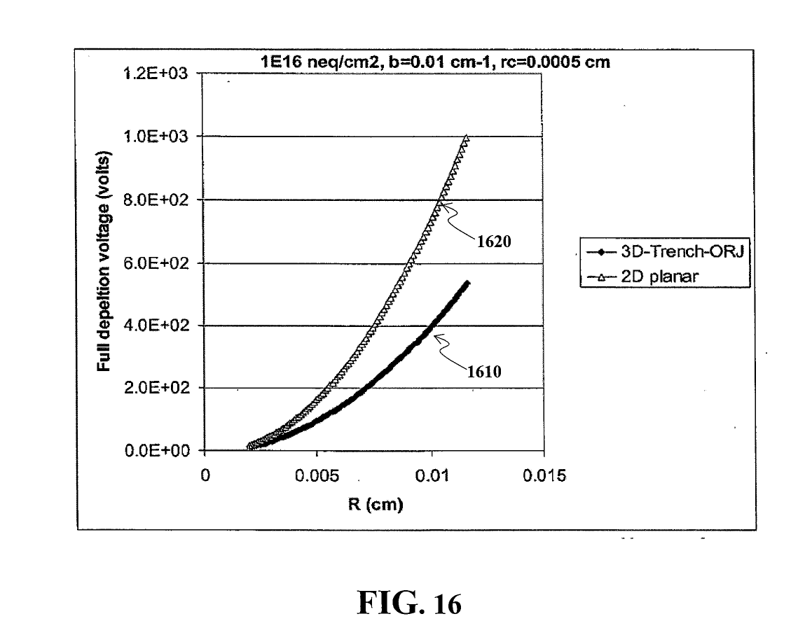

FIG. 16 illustrates a graph of the full depletion voltage as a function of the depletion width in a single-cell 3D-Trench-ORJ detector and that of a planar 2D detector. Specifically, in FIG. 16, plot 1610 shows that the full depletion voltage values in a single-cell 3D-Trench-ORJ detector increase as the depletion width wₚ (in FIG. 14B) increases from an initial location of r=R to a final location of r=r_{c}. Thus in plot 1610, the full depletion voltage increases as the depletion width wₚ radially increases in the negative direction of polar coordinate r from the cylindrical surface R (n⁺ trench) towards the surface of the cylindrical column at r=r_{c}. Similarly, plot 1620 represents the full depletion voltage values in a 2D detector for an electric field between the two planar electrodes separated by a bulk thickness d equivalent to a distance from r=R to r=r_{c}. In plot 1620, the full depletion voltage increases as the depletion width w along the thickness d of the bulk increases. It is to be noted that in plots 1610 and 1620 the full depletion voltage values in the 3D-Trench-ORJ detector increase much more slowly than do the full depletion values in the 2D detector. More specifically in this case, FIG. 16 shows that—upon irradiation with a fluence of 1×10¹⁶ n_{eq}/cm²—the full depletion voltage in a 3D-Trench-ORJ Si detector increases much more slowly with radius than that of a 2D detector does with thickness. This result is attributable to the fact that there is minimum influence of the “small electrode effect” around the central column, which in this case is not the junction electrode. When comparing FIG. 16 to FIG. 9, it is evident that the full depletion voltage in a 3D-Trench-ORJ detector is at least 3 times smaller than that of a 3D-Trench-CJ detector. This particular effect is considered advantageous in the 3D-Trench-ORJ detector because such a detector may be configured to withstand much higher depletion voltages than the 3D-Trench-CJ detector.

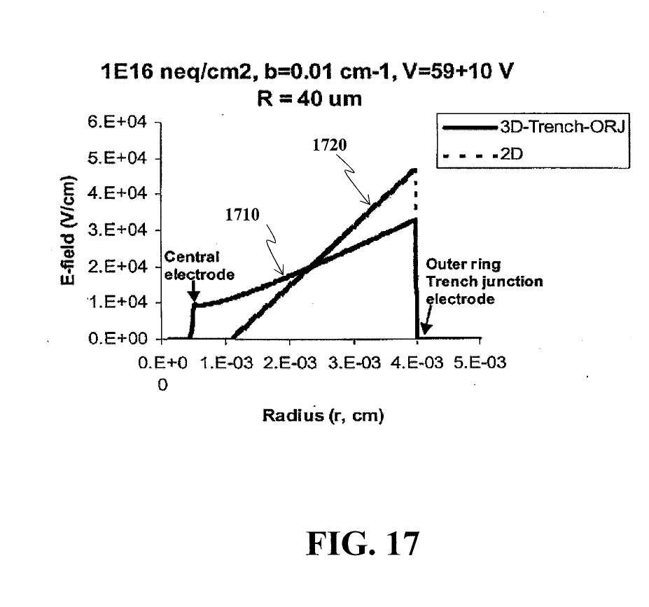

Another advantage of the 3D-Trench-ORJ detector over 3D-Trench-CJ or planar 2D detectors is its resilience to over-depletion bias. Specifically, as can be seen from Equation (27), the over-depletion term has strong dependence on the 1/r term. Consequently, at over-depletion bias, the 3D-Trench-ORJ detector will add electric field mostly near the central electrode (at r=r_{c}), which is where the low electric field is originally located. This particular effect of the electric field in the 3D-Trench-ORJ detector is in direct contrast with the electric field of the 3D-Trench-CJ detector. FIG. 17 exemplifies this concept.

FIG. 17 shows a graph of electric field profiles of a 3D-Trench-ORJ detector (at over-depletion) and that of a planar 2D detector. In FIG. 17, plot 1710 represents an electric field profile of a 3D-Trench-ORJ detector, while plot 1720 represents an electric profile of a planar 2D detector both at a bias voltage of 69 volts. More specifically, when comparing plot 1510 of FIG. 15 to plot 1710 of FIG. 17, plot 1710 shows that an over-depletion bias of 10 volts in the 3D-Trench-ORJ detector can significantly increase the electric field at r=r_{c} while leaving essentially unchanged the electric field profile at r=R. In particular, as illustrated in FIG. 17, an over-depletion bias of 10 volts increases the electric field from 0V/cm to 1×10⁴V/cm at r=r_{c} of a 3D-Trench-ORJ detector (plot 1710) upon an irradiation of 1×10¹⁶ n_{eq}/cm² fluence. Notably, however, it is observed that the same over-depletion bias produces minimal or no increase of the electric field in the high-field region at r=R. On the other hand, when comparing plot 1520 of FIG. 15 to plot 1720 of FIG. 17, plot 1720 illustrates that even at 69 volts of bias voltage, the 2D detector is not fully depleted. This leads one to conclude that the 3D-Trench-ORJ detector requires much lower levels of bias voltage (even at over depletion), as compared to conventional 2D detectors.

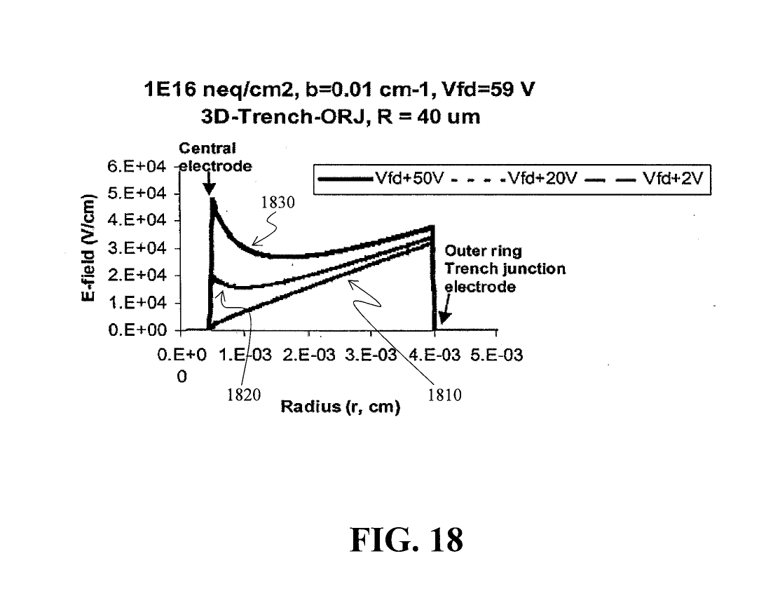

FIG. 18 shows another graph that comparatively illustrates various examples of over-depletion bias in a 3D-Trench-ORJ detector. In particular, FIG. 18 illustrates electric field profiles (absolute values plotted since E-fields are negative) in a singe-cell 3D-Trench-ORJ detector at three different levels of bias voltage. Plot 1810 shows an over-depletion bias of 2 volts; here, it is observed that the electric field profile still remains linear and no change is noted when comparing plot 1810 to plot 1510 of FIG. 15. Plot 1820 shows an over-depletion bias of 20 volts over the full depletion voltage (V_{fd}). When comparing plot 1820 to plot 1510 of FIG. 15, it is observed that the electric field at r=r_{c} has increased from 0V/cm to about 2×10⁴V/cm while the electric field profile at the outer ring junction (r=R) has remained essentially steady at 3×10⁴V/cm. Finally, plot 1830 depicts the case of an over-depletion bias of 50 volts above the full-depletion voltage of 59 volts illustrated by plot 1510 of FIG. 15. When comparing plot 1830 to plot 1510 of FIG. 15, it is observed that the electric field at r=r_{c} has increased from 0V/cm to about 5×10⁴V/cm, while the electric field at r=R has only increased from 3×10⁴V/cm to 3.5×10⁴V/cm. As shown in FIG. 18, an increase in bias voltage over the full depletion level can raise the electric field at r=r_{c} so much that the electric field at r=r_{c} can eventually exceed the electric field at r=R. Thus, this increase in over-depletion voltage eventually makes the central electrode into a “virtual” junction.

### 2.3.2. Optimal Depletion Voltage in a 3D-Trench-ORJ Detector

As shown above in Equation (28), the full depletion voltage V_{fd} is proportional to the effective doping concentration N_{eff}. Under high irradiation fluence, N_{eff} undergoes changes because of defects in the bulk. Bulk defects may lead to the inversion of the type of material. During irradiation, by increasing the irradiation fluence, an initially positive bulk doping concentration may decrease up to the type inversion of the semiconductor bulk and become negative. The negative N_{eff} means that an n-type bulk material can invert to an effective p-type bulk material. With an inverted bulk material, the region of the high electric field moves from the initial junction electrode towards the ohmic contact electrode, thereby creating an effective virtual junction electrode at the central electrode. The increase in electric field due to over-depletion bias is of considerable benefit to the charge collection efficiency (CCE) of this detector because in the case that a virtual junction is created at the second or central electrode both the electric field and the weighting field will be on the same side of the collection electrode. The advantage of this effect is that a substantially uniform field may be achieved across the entire volume of the bulk semiconductor material, thereby preventing highly concentrated fields at the central electrode that may damage the detector.

Another interesting aspect in a 3D-Trench-ORJ detector is that when the electric fields at both ends of the depletion region are equal, i.e., when E(r_{c})=E(R), a near constant (or near uniform) electric field can be achieved across the entire single-cell detector (or pixel). This condition may be an optimal operational condition for applications in high radiation environments where detectors with high CCE and resistance to high electric fields are highly desirable. For example, 3D-Trench-ORJ detectors with nearly constant electric field can give extremely fast charge collection without tails caused by low field regions (i.e., with E(r_{c})=E(R)). 3D-Trench-ORJ detectors operated in such special conditions may be optimally suitable for the high luminosity and high radiation environments of particle colliders such as those expected in the SLHC, or in other high-energy physics and in photon science experiments.

The optimal over-depletion bias voltage, ΔVₒᵥₑᵣ^{optima}, required to achieve the E(r_{c})=E(R) condition is given by:

$$Δ {V}_{over}^{optima} = {V}^{optima} - {V}_{fd} = \frac{{eN}_{eff}}{2 {ɛɛ}_{0}} [ {r}_{C} ( R + {r}_{C} ) ln \frac{R}{{r}_{C}} ] \qquad ( 29 )$$

and the equal field value is:

$${E}_{eq} = - \frac{{eN}_{eff}}{2 {ɛɛ}_{0}} ( R + {r}_{C} ) \qquad ( 30 )$$

From the above Equations (29) and (30), it is clear that both ΔVₒᵥₑᵣ^{optima} and E_{eq} depend namely on the geometry (r_{c} and R) and effective doping concentration (N_{eff}) of the detector. As previously discussed, N_{eff} increases linearly proportional to irradiation fluence. Accordingly, ΔVₒᵥₑᵣ^{optima} and E_{eq} also increase linearly with N_{eff} and near linearly with R.

For a 3D-Trench-ORJ silicon detector under a radiation fluence of 1×10¹⁶ n_{eq}/cm², having a center column of 5-micrometer radius (r_{c}=5 μm) and a trench electrode (outer electrode) placed at 40 micrometers from the center thereof (R=40 μm), the optimal full-depletion bias voltage and the equal field value can be calculated, by using Equations (29) and (30), as follows:

$$\{ \begin{matrix}Δ {V}_{over}^{optima} = 3.74 \times {10}^{- 15} {Φ}_{{n}_{eq}} , ( V ) \\ {E}_{eq} = - 3.60 \times {10}^{- 12} {Φ}_{{n}_{eq}} , ( V / cm )\end{matrix} \qquad ( 31 )$$

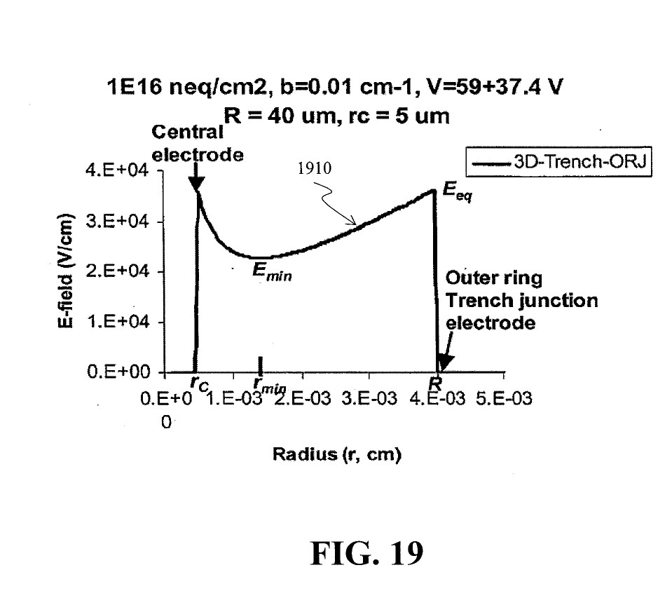

which results in ΔVₒᵥₑᵣ^{optima}=37.4V and E_{eq}=−3.6×10⁴V/cm. The electric field profile corresponding to this example is plotted in FIG. 19.

FIG. 19 illustrates an electric field profile 1910 in a single-cell 3D-Trench-ORJ detector biased at the optimal over-depletion voltage that makes the electric field equal at the two ends of the depletion region. That is the electric field E(r_{c}) at the center column (r=r_{c}) is equal to the electric field E(R) at the outer-ring-junction (r=R). FIG. 19 is plotted in absolute values to better illustrate the negative values of the E-field. In FIG. 19, the optimal electric field profile for the 3D-Trench ORJ detector has the following form:

$${E}^{optima} ( r ) = - \frac{1}{2} \frac{{eN}_{eff}}{2 {ɛɛ}_{0}} r [ 1 + \frac{{r}_{C} R}{{r}^{2}} ] ( {r}_{C} \leq r \leq R ) ( for 3 D \text{-} Trench \text{-} ORJ ) \qquad ( 32 )$$

with the minimum electric field (Eₘᵢₙ) located at rₘᵢₙ, where:

$$\{ \begin{matrix}{r}_{min} = \sqrt{{r}_{C} R} \\ {E}_{min} = - \frac{{eN}_{eff}}{{ɛɛ}_{0}} \sqrt{{r}_{C} R}\end{matrix} \qquad ( 33 )$$

The ratio of the two characteristic fields is then:

$$\frac{{E}_{eq}}{{E}_{min}} = \frac{( {r}_{C} + R ) / 2}{\sqrt{{r}_{C} R}} ≅ \frac{1}{2} \sqrt{\frac{R}{{r}_{C}}} , ( if R >> {r}_{C} ) \qquad ( 34 )$$

As a result, it can be seen from Equation (34) that the ratio of the two characteristic fields E_{eq}/Eₘᵢₙ depends only on the detector geometry (r_{c} and R) and therefore it is not affected by irradiation.

### 2.3.3 Weighting Fields and Carrier Drift Dynamics in a 3D-Trench-ORJ Detector

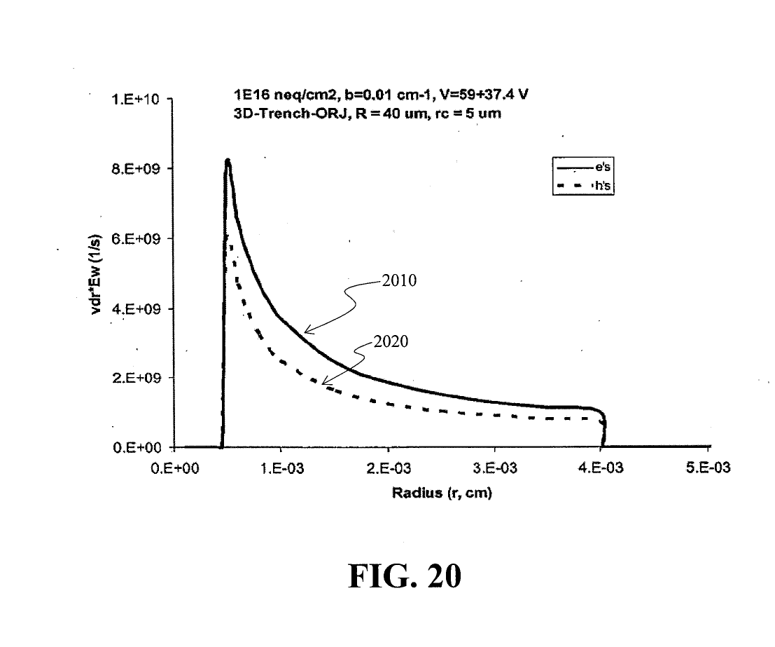

FIG. 20 shows products of carrier drift velocity and weighting field for a 3D-Trench-ORJ detector. In FIG. 20, plots 2010 and 2020 illustrate the product of carrier drift velocity and weighting field of electrons (e's) and holes (h's), respectively, in a single-cell 3D-Trench-ORJ detector of the hexagonal type. As illustrated in FIG. 20, it is evident that the products for both electrons and holes peak at r=r_{c}, and they are non-zero throughout the entirety of the cell. The lowest value of both plots 2010 and 2020 is approximately ⅕ of the corresponding peak value. These plots demonstrate that the 3D-Trench-ORJ detector could be operated at full depletion with the maximum electric field being concentrated at the outer-ring-junction.

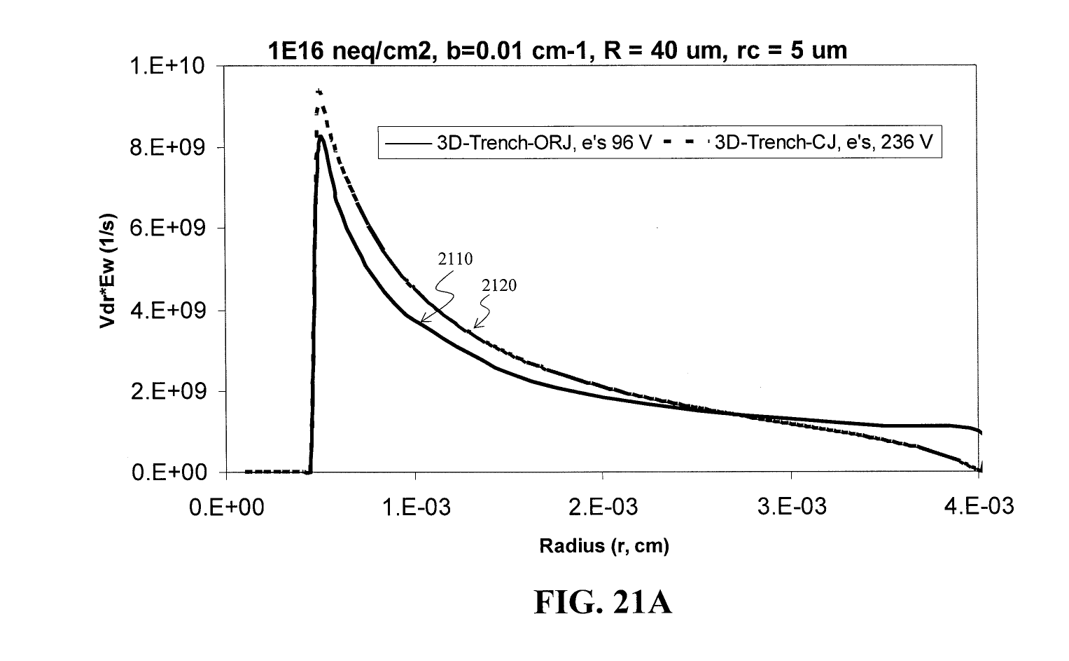

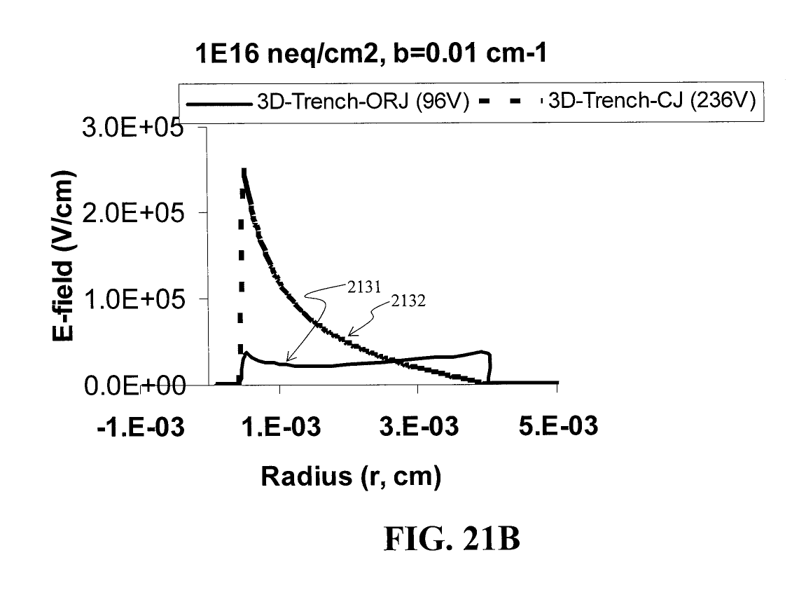

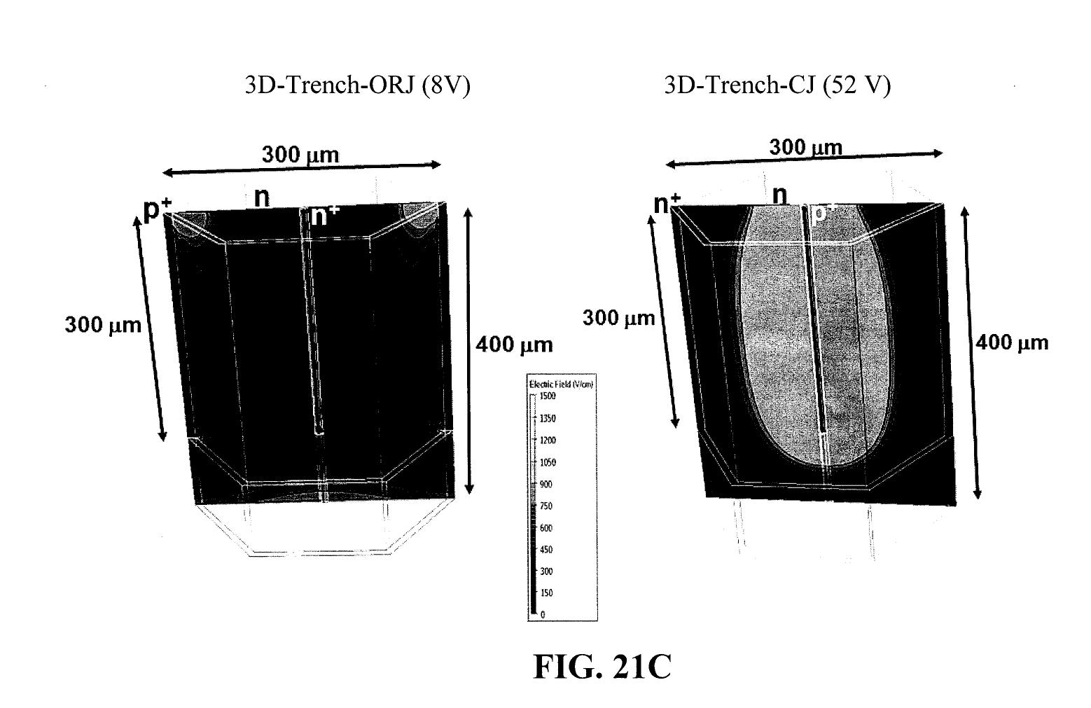

FIG. 21A shows a graph illustrating, for comparison purposes, calculated products of carrier drift velocity and weighting field of a 3D-Trench-ORJ detector and that of a 3D-Trench-CJ detector. FIG. 21B depicts electric field profiles corresponding to the detectors discussed in FIG. 21A. As shown in FIG. 21A, the product of carrier drift velocity and weighting field for electrons in the 3D-Trench-ORJ detector (plot 2110) is somewhat similar to that of the 3D-Trench-CJ (plot 2120) detector. In FIG. 21A, plot 2110 shows that the product of carrier drift velocity and weighting field for electrons in a single-cell 3D-Trench-ORJ detector peaks at r=r_{c} and is maintained at non-zero levels throughout the entirety of the cell. In contrast, plot 2120 shows that the product of carrier drift velocity and weighting field for electrons in a single-cell 3D-Trench-CJ detector peaks at r=r_{c}, but it promptly drops to zero levels at r=R. Moreover, the electric field profiles of FIG. 21B further demonstrate the results in terms of bias voltage and electric field. More specifically, FIG. 21B shows that the bias voltage of the 3D-Trench-ORJ detector (96V) is about 2.4 times smaller than the bias voltage of the 3D-Trench-CJ detector (236V). In addition, the maximum electric field intensity of a 3D-Trench-ORJ detector (plot 2131) is about 7 times smaller than the maximum electric filed intensity of the 3D-Trench-CJ detector (plot 2132). However, for an ease of understanding, similar simulations (shown in FIG. 21C) were performed in a 3D space to illustrate an electric field across the cross-section of the 3D-Trench detector of hexagonal type with either an outer ring junction (ORJ) electrode or a central junction (CJ) electrode. FIG. 21C shows that in a detector with 150 μm electrode spacing and 1 μm SiO₂ layers (top and bottom), the bias voltage of the 3D-Trench-ORJ detector (8V) is about 6.5 times smaller than the bias voltage of the 3D-Trench-CJ detector (52V) and about 2 times smaller than the bias voltage of the 2D conventional planar detector with a thickness of 150 μm. In additional, the electric field in both 3D-Trench-ORJ and the 3D-Trench-CJ detectors is very uniform.

These results show that a 3D-Trench-ORJ detector architecture can be advantageously used in radiation environments with higher radiation fluences than where 3D-Trench-CJ detectors and prior art 3D detector architectures can be used.

### 2.4. Summary of Characteristics of 3D-Trench Detectors

From the foregoing detailed description and sample calculations of 3D-Trench detectors, the characteristics of 3D-Trench detectors may be summarized as follows: (1) the electric field profile in the 3D-Trench-ORJ is slightly sub-linear; (2) when compared to 3D-Trench-CJ and planar 2D detectors, the bias voltage to deplete a 35-μm bulk in a 3D-Trench-ORJ detector (after a radiation to 1×10¹⁶ n_{eq}/cm²) is 40% less than that of a 2D detector and 3 times smaller than that of a 3D-Trench-CJ detector (see FIG. 8 as compared to FIG. 15); (3) the maximum electric field is near the outer ring trench and it is about 30% less than that of a 2D detector and can be up to 7 times smaller that that of a 3D-Trench-CJ detector (compare FIG. 8 to FIG. 15). The comparisons between planar 2D, 3D-Trench-CJ and 3D-Trench-ORJ detectors are summarized in Table II. From those comparisons it is concluded that even at extremely high radiation fluences (e.g., at 1×10¹⁶ n_{eq}/cm²), a silicon 3D-Trench-ORJ detector could be operated at full depletion with maximum electric field and still be maintained below the breakdown field of 3×10⁵V/cm of Si.

TABLE II
Comparative characteristics of 2D planar, 3D-Trench-CJ and 3D-Trench-
ORJ Si detectors under irradiation fluence of 1 × 10¹⁶ n_{eq}/cm².

| | | Maximum E-field | | |
|---|---|---|---|---|
| | Full depletion | located at/value | | Depletion width |
| | voltage for 35 μm | (at V = V_{fd}) | Form of E-field | (w) at 59 volts |
| 2D planar* | 99 volts | Junction electrode | Linear | 27 μm |
| | | 5.7 × 10⁴ V/cm (99 V) | | |
| 3D-Trench-CJ | 206 volts | Central electrode | Super-Linear | 21 μm |
| | | column/2.55 × 10⁵ | | |
| | | V/cm (206 V) | | |
| 3D-Trench-ORJ | 59 volts | Outer-ring trench/ | Slightly sub-linear | 35 μm |
| | | 3.19 × 10⁴ V/cm | | |
| | | (59 V) | | |

*For purposes of comparison 3D-Trench electrodes of the rectangular type may be approximated by a 2D planar model at least in the planes where the first and second electrodes are parallel to each other (e.g., Region I in FIG. 2A).

### 3. Analysis of Collected Charges in 3D-Trench Silicon Detectors

As previously stated, the generated charge for a MIP along the thickness of the bulk (independent of the drift direction) is given by Equation (21) which is reproduced below.

$$\begin{matrix}{Q}^{e , h} = 80 {e}^{′} s / μm \cdot {d}_{eff} {\int }_{0}^{{r}_{dt}^{e , h} ( {r}_{0} )} {E}_{W} \cdot {v}_{dr}^{e , h} \cdot {e}^{- \frac{t}{{τ}_{t}}} d t and & ( 21 ) \\ Q = {Q}^{e} + {Q}^{h} & \end{matrix}$$

From Equation (21) one needs to first calculate the drift of electrons and holes r^{e,h}(t, r₀) originating from r₀ (in FIG. 10), where:

$$\frac{{dr}^{e , h} ( t , {r}_{0} )}{dt} = {v}_{dr}^{e , h} ( r ) = \frac{{μ}^{e , h} E ( {r}^{e , h} ( t , {r}_{0} ) )}{1 + \frac{{μ}^{e , h} E ( {r}^{e , h} ( t , {r}_{0} ) )}{{v}_{S}^{e , h}}} \qquad ( 35 )$$

Equation (35) can be solved using the electric field profiles listed in Equation (12) for 3D-Trench-CJ and Equation (27) for 3D-Trench-ORJ detectors.

### 3.1 Collected Charge in 3D-Trench-CJ Silicon Detectors

For 3D-Trench-CJ detectors made of silicon, the drift of electrons and holes can be calculated as follows:

$$\begin{matrix}t = \frac{{r}_{0} - {r}^{e} ( t , {r}_{0} )}{{v}_{s}^{e}} + \frac{{ɛɛ}_{0}}{e {μ}^{e} {N}_{eff}} ln \{ \frac{\frac{1}{2} \frac{{eN}_{eff}}{{ɛɛ}_{0}} [ {R}^{2} - {{r}^{e} ( t , {r}_{0} )}^{2} ] + \frac{V - {V}_{fd}}{ln ( R / {r}_{C} )}}{\frac{1}{2} \frac{{eN}_{eff}}{{ɛɛ}_{0}} [ {R}^{2} - {r}_{0}^{2} ] + \frac{V - {V}_{fd}}{ln ( R / {r}_{C} )}} \} ( {e}^{′} s , {r}_{C} \leq {r}^{e} ( t , {r}_{0} ) \leq {r}_{0} \leq R ) & ( 36 ) \\ and & \\ t = \frac{{r}^{h} ( t , {r}_{0} ) - {r}_{0}}{{v}_{s}^{h}} + \frac{{ɛɛ}_{0}}{e {μ}^{h} {N}_{eff}} ln \{ \frac{\frac{1}{2} \frac{{eN}_{eff}}{{ɛɛ}_{0}} [ {R}^{2} - {r}_{0}^{2} ] + \frac{V - {V}_{fd}}{ln ( R / {r}_{C} )}}{\frac{1}{2} \frac{{eN}_{eff}}{{ɛɛ}_{0}} [ {R}^{2} - {{r}^{h} ( t , {r}_{0} )}^{2} ] + \frac{V - {V}_{fd}}{ln ( R / {r}_{C} )}} \} ( {h}^{′} s , {r}_{C} \leq {r}_{0} \leq {r}^{h} ( t , {r}_{0} ) \leq R ) \\ \text{?} \\ \text{?} \text{indicates text missing or illegible when filed} & ( 37 )\end{matrix}$$

where drift times are:

$$\begin{matrix}{t}_{dr}^{e} ( {r}_{0} ) = \frac{{r}_{0} - {r}_{C}}{{v}_{s}^{e}} + \frac{{ɛɛ}_{0}}{e {μ}^{e} {N}_{eff}} ln \{ \frac{\frac{1}{2} \frac{{eN}_{eff}}{{ɛɛ}_{0}} [ {R}^{2} - {r}_{C}^{2} ] + \frac{V - {V}_{fd}}{ln ( R / {r}_{C} )}}{\frac{1}{2} \frac{{eN}_{eff}}{{ɛɛ}_{0}} [ {R}^{2} - {r}_{0}^{2} ] + \frac{V - {V}_{fd}}{ln ( R / {r}_{C} )}} \} ( {e}^{′} s , {r}_{C} \leq {r}_{0} \leq R ) & ( 38 ) \\ {t}_{dr}^{h} ( {r}_{0} ) = \frac{R - {r}_{0}}{{v}_{s}^{h}} + \frac{{ɛɛ}_{0}}{e {μ}^{h} {N}_{eff}} ln \{ \frac{\frac{1}{2} \frac{{eN}_{eff}}{{ɛɛ}_{0}} [ {R}^{2} - {r}_{0}^{2} ] + \frac{V - {V}_{fd}}{ln ( R / {r}_{C} )}}{\frac{V - {V}_{fd}}{ln ( R / {r}_{C} )}} \} ( {h}^{′} s , {r}_{C} \leq {r}_{0} \leq R ) & ( 39 )\end{matrix}$$

In the above equations, the maximum drift times, or the transient times, are times needed for carriers drifting the entire distance R to r_{c}. Accordingly,

$$\begin{matrix}{t}_{dr}^{e} = \frac{R - {r}_{C}}{{v}_{s}^{e}} + \frac{{ɛɛ}_{0}}{e {μ}^{e} {N}_{eff}} ln \{ \frac{\frac{1}{2} \frac{{eN}_{eff}}{{ɛɛ}_{0}} [ {R}^{2} - {r}_{C}^{2} ] + \frac{V - {V}_{fd}}{ln ( R / {r}_{C} )}}{\frac{V - {V}_{fd}}{ln ( R / {r}_{C} )}} \} ( {e}^{′} s drifting from R \to {r}_{C} ) & ( 40 ) \\ {t}_{dr}^{h} = \frac{R - {r}_{C}}{{v}_{s}^{h}} + \frac{{ɛɛ}_{0}}{e {μ}^{h} {N}_{eff}} ln \{ \frac{\frac{1}{2} \frac{{eN}_{eff}}{{ɛɛ}_{0}} [ {R}^{2} - {r}_{C}^{2} ] + \frac{V - {V}_{fd}}{ln ( R / {r}_{C} )}}{\frac{V - {V}_{fd}}{ln ( R / {r}_{C} )}} \} ( {h}^{′} s drifting from {r}_{C} \to R ) & ( 41 )\end{matrix}$$

Calculations can now be performed in Equations (20) and (21) using Equations (35)-(39) for induced currents and collected charges for electrons (e) and holes (h).

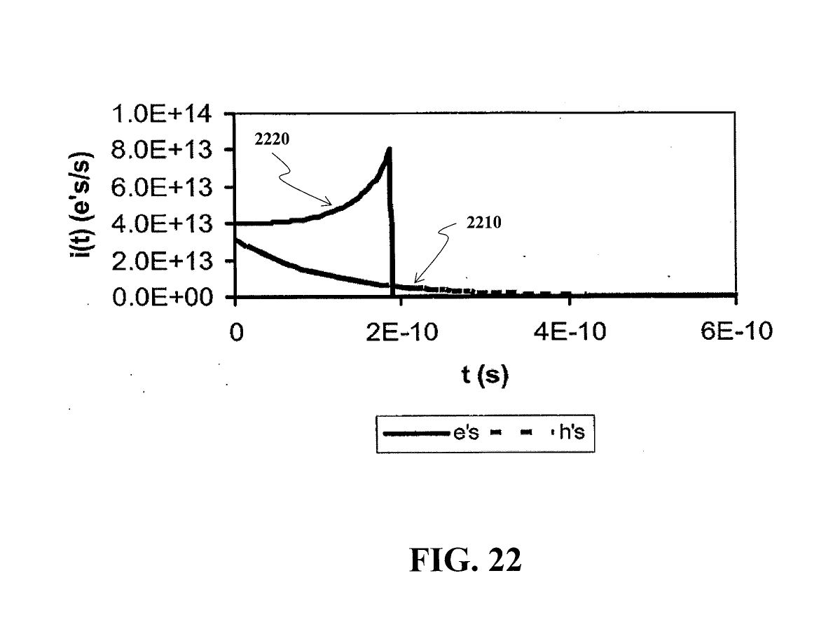

An example of induced currents and collected charges is illustrated in FIG. 22. FIG. 22 illustrates electron and hole induced currents by a MIP in an irradiated (1×10¹⁶ n_{eq}/cm²) 3D-Trench-CJ detector made of silicon. For the example of FIG. 22, the following conditions have been assumed: r₀=22.5 μm; r_{c}=5 μm; R=40 μm; d_{eff}=290 μm, V=243V (V_{fd}=206V); and Eₘₐₓ=2.91×10⁵V/cm. Accordingly, FIG. 22 shows plots of electrons (plot 2210) and holes (plot 2220) induced currents by a MIP hitting at the bulk at r₀=22.5 μm. That is, an electron and hole generated by a MIP hitting the middle point between the outer surface of central junction column (r_{c}=5 μm) and the outer ring surface (R=40 μm) in an irradiated (1×10¹⁶ n_{eq}/cm²) 3D-Trench-CJ Si detector.

From FIG. 22, it is evident that the total induced current and therefore the total collected charge is dominated, in this case, by electrons. Indeed, it was found that integrations of the induced currents taken during simulations give a total collected charge of 12,100 e's, or a CCE=56% of the original 21,600 e's, out of which 9,010 e's are due to electron drift (or about 75% of the total collected charge). The total collected charge is 5-6 times more than by a standard planar (2D) Si detector. The charge collection time is also very short. It is less than 0.2×10⁻⁹ seconds (0.2 ns) for electrons, and less than 0.45 ns for holes. Thus, the overall charge collection time is less than 0.45 ns. However, the detector is operated at a very high bias voltage of 243 volts with 37 volts of over-depletion voltage. The highest electric field is 291×10³V/cm, which is very close to the intrinsic breakdown voltage in Si. It is estimated that an operation bias voltage of less than or equal to the full depletion voltage would increase the charge collection time to about 1.5 ns or even greater.

### 3.2 Collected Charge in 3D-Trench-ORJ Silicon Detectors

For 3D-Trench-ORJ detectors made of silicon, the drift of electrons and holes can be calculated as follows:

$$\begin{matrix}t = \frac{{r}^{e} ( t , {r}_{0} ) - {r}_{0}}{{v}_{s}^{e}} + \frac{{ɛɛ}_{0}}{e {μ}^{e} {N}_{eff}} ln \{ \frac{\frac{1}{2} \frac{{eN}_{eff}}{{ɛɛ}_{0}} [ {{r}^{e} ( t , {r}_{0} )}^{2} - {r}_{C}^{2} ] + \frac{V - {V}_{fd}}{ln ( R / {r}_{C} )}}{\frac{1}{2} \frac{{eN}_{eff}}{{ɛɛ}_{0}} [ {r}_{0}^{2} - {r}_{C}^{2} ] + \frac{V - {V}_{fd}}{ln ( R / {r}_{C} )}} \} ( {e}^{′} s , {r}_{C} \leq {r}_{0} \leq {r}^{e} ( t , {r}_{0} ) \leq R ) & ( 42 ) \\ t = \frac{{r}_{0} - {r}^{h} ( t , {r}_{0} )}{{v}_{s}^{h}} + \frac{{ɛɛ}_{0}}{e {μ}^{h} {N}_{eff}} ln \{ \frac{\frac{1}{2} \frac{{eN}_{eff}}{{ɛɛ}_{0}} [ {r}_{0}^{2} - {r}_{C}^{2} ] + \frac{V - {V}_{fd}}{ln ( R / {r}_{C} )}}{\frac{1}{2} \frac{{eN}_{eff}}{{ɛɛ}_{0}} [ {{r}^{h} ( t , {r}_{0} )}^{2} - {r}_{C}^{2} ] + \frac{V - {V}_{fd}}{ln ( R / {r}_{C} )}} \} ( {h}^{′} s , {r}_{C} \leq {r}^{h} ( t , {r}_{0} ) \leq {r}_{0} \leq R ) & ( 43 )\end{matrix}$$

and the drift times are:

$$\begin{matrix}{t}_{dr}^{e} ( {r}_{0} ) = \frac{R - {r}_{0}}{{v}_{s}^{e}} + \frac{{ɛɛ}_{0}}{e {μ}^{e} {N}_{eff}} ln \{ \frac{\frac{1}{2} \frac{{eN}_{eff}}{{ɛɛ}_{0}} [ {R}^{2} - {r}_{C}^{2} ] + \frac{V - {V}_{fd}}{ln ( R / {r}_{C} )}}{\frac{1}{2} \frac{{eN}_{eff}}{{ɛɛ}_{0}} [ {r}_{0}^{2} - {r}_{C}^{2} ] + \frac{V - {V}_{fd}}{ln ( R / {r}_{C} )}} \} ( {e}^{′} s , {r}_{C} \leq {r}_{0} \leq R ) & ( 44 ) \\ {t}_{dr}^{h} ( {r}_{0} ) = \frac{{r}_{0} - {r}_{C}}{{v}_{s}^{h}} + \frac{{ɛɛ}_{0}}{e {μ}^{h} {N}_{eff}} ln \{ \frac{\frac{1}{2} \frac{{eN}_{eff}}{{ɛɛ}_{0}} [ {r}_{0}^{2} - {r}_{C}^{2} ] + \frac{V - {V}_{fd}}{ln ( R / {r}_{C} )}}{\frac{V - {V}_{fd}}{ln ( R / {r}_{C} )}} \} ( {h}^{′} s , {r}_{C} \leq {r}_{0} \leq R ) & ( 45 )\end{matrix}$$

From the foregoing Equations (43)-(45), it is noted that the maximum drift times for electrons and holes in a 3D-Trench-ORJ detector can be determined from Equations (44) and (45) which are essentially the same as Equations (38) and (39), respectively. However, a notable difference in the case of a 3D-Trench-ORJ detector is that electrons and holes drift in directions opposite to those of a 3D-Trench-CJ detector. Specifically, as noted above, in a 3D-Trench-ORJ detector (FIG. 14), electrons drift from R→r_{c} and holes drift from r_{c}→R, whereas in a 3D-Trench-CJ detector (FIG. 6), electrons drift from r_{c}→R and holes drift from R→r_{c}.

As noted in Table II, the full depletion voltage in a 3D-Trench-CJ detector tends to be much higher than that of a 3D-Trench-ORJ detector with the same separation of electrodes (λ_{C}). Accordingly, the voltage needed to reach the same transient time in a 3D-Trench-CJ detector is much higher than what is required in a 3D-Trench-ORJ detector.

In addition, the foregoing calculations are to be applied taking into consideration the detector's architecture and polarity. Specifically, in the calculation of the above examples a p-type bulk is assumed, i.e., n⁺ central junction column for a 3D-Trench-CJ detector, and p⁺ Ohmic column for a 3D-Trench-ORJ detector. For an n-type bulk, one needs to make the following switches:

$$\{ \begin{matrix}{n}^{+} ↔ {p}^{+} \\ p \to n \\ e ↔ h \\ E ( r ) \to - E ( r )\end{matrix} ( \begin{matrix}for n \text{-} type bulk \text{:} {p}^{+} central column in \\ 3 D \text{-} Trench \text{-} CJ and {n}^{+} central column in ORJ\end{matrix} ) \qquad ( 46 )$$

Taking the above caveats into consideration, induced currents and collected charges for electrons and holes in a 3D-Trench-ORJ detector may be determined by carrying out the calculations in Equations (20) and (21) using Equations (42)-(45).

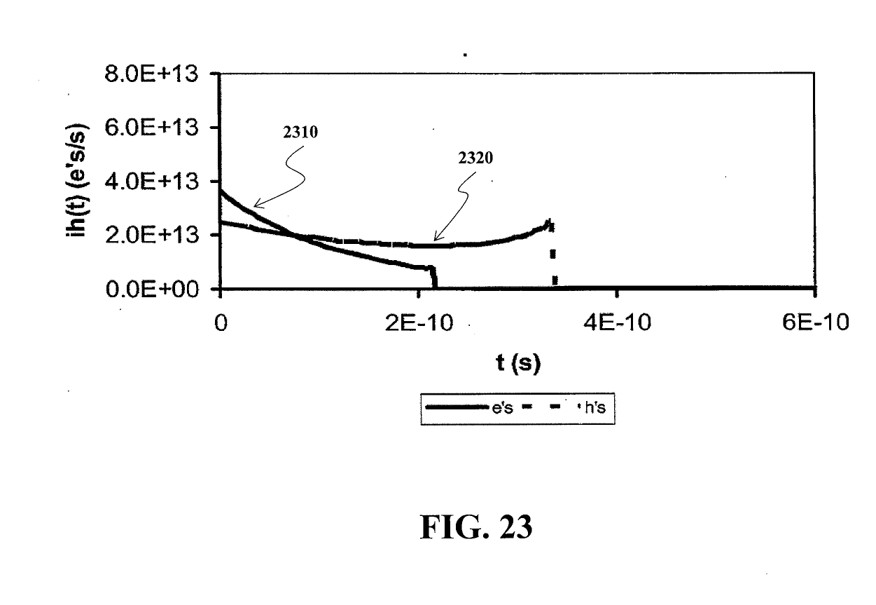

FIG. 23 illustrates electron and hole induced currents for a MIP hitting a 3D-Trench-ORJ detector at an incidence position r₀ with an irradiation affluence of 1×10¹⁶ n_{eq}/cm². More specifically, FIG. 23 assumes a 3D-Trench-ORJ detector under the following conditions: r₀=22.5 μm, r_{c}=5 μm, R=40 μm, and irradiation fluence=1×10¹⁶ n_{eq}/cm², where r₀ is the middle point between the outer surface of the central junction column (r_{c}=5 μm) and the inner surface of the trench electrode (R=40 μm). As illustrated in FIG. 23, the total induced current and therefore the total collected charge are slightly dominated by holes (plot 2320). In a total collected charge of 10,200 e's, or a CCE=47.3% of the original 21,600 e's, 6,280 e's are estimated to be due to hole drift (or about 62% of the total collected charge). It is noted that in FIG. 23, a bias voltage of 97 volts was used. The 97 volts of bias voltage included a 38 volt over depletion voltage to reach the optimal operation field, as calculated from Equation (32). The maximum electric field is 36 kV/cm, which is 8 times less than that of a 3D-Trench-CJ electrode Si detector with the same irradiation, and is comfortably below the Si intrinsic breakdown field of 300 kV/cm.

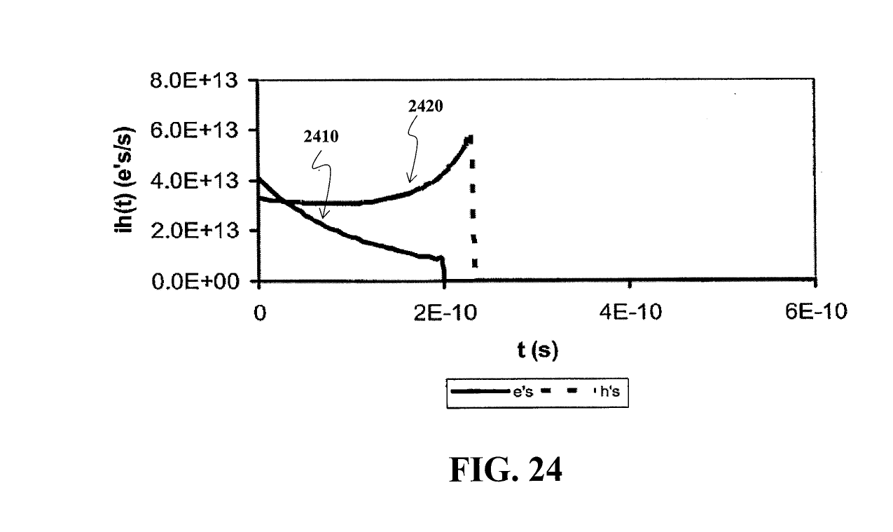

It is noted that in FIG. 23, the total collected charge is slightly less than the collected charge for the 3D-Trench-CJ detector described above in reference to FIG. 22. The lower average electric field of FIG. 23 is attributed to the much smaller bias voltage used in the 3D-Trench-ORJ detector (97 volts) as compared to the bias voltage used in the 3D-Trench-CJ (243 volts). Indeed, FIG. 24 further evidences this result.

FIG. 24 illustrates a case where electron (plot 2410) and hole (plot 2420) induced currents by a MIP have been collected from the above-described 3D-Trench-ORJ detector. The distinction in FIG. 24, as compared to that of FIG. 23, is that a bias voltage of 224 volts has been now used. More specifically, FIG. 24 depicts the case in which the bias in the 3D-Trench-ORJ Si detector has been increased from 97 volts to 224 volts. In this case, the total induced current and therefore the total collected charge are still dominated by holes (plot 2420). A total collected charge of about 12,100 e's is obtained, in the same manner as the 3D-Trench-CJ detector described in section 3.1., but with substantially less value in the maximum electric field (i.e., 159 kV/cm). The collected charge due to hole drifts is 7992 e's, or about 66% of the total collected charge.

The charge collection times t(s) for both cases, FIG. 23 and FIG. 24, are very short. In FIG. 23, it is less than 0.35 ns for V=97 volts; and in FIG. 24, it is less than 0.25 ns for V=224 volts. It is therefore significant to note that the charge collection times for 3D-Trench-ORJ detectors are shorter than those of 3D-Trench-CJ detectors, even if both types of detectors are made of the same material. The shorter collections times in the 3D-Trench-ORJ detectors may be due to the more uniform electric field profiles.

### 3.3 Dependence of Collected Charge on the Position of Particle Incidence and Carrier Trapping in 3D-Trench Electrode Detectors

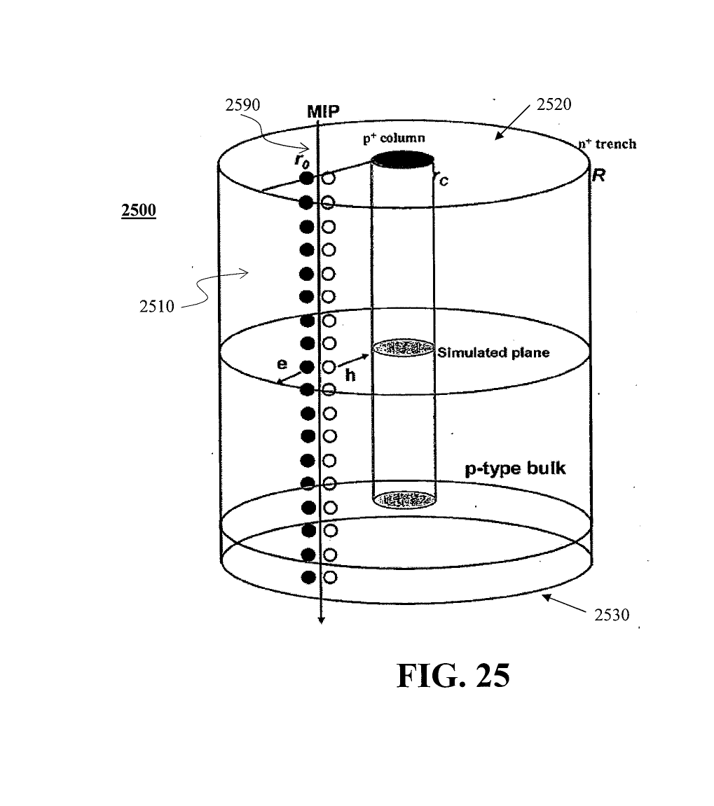

For any 3D electrode detector, conventional 3D and/or 3D-Trench (rectangular or hexagonal type) discussed herein, free carriers are generated by particles which drift parallel to the surface plane of the detector and perpendicular to the detector thickness. For a MIP entering the detector normal to the detector surface, as shown in FIG. 25, electron and hole pairs are generated along the MIP path parallel to the central column and the outer ring (as illustrated).

FIG. 25 schematically illustrates drifting of free carriers generated by a MIP in a single-cell 3D-Trench-ORJ detector. In FIG. 25, 3D-Trench-ORJ detector 2500 is structurally similar to detector 1400 of FIG. 14A, which has been described above at section 2.3. “Electric Field Considerations in the 3D-Trench-ORJ Detector.” Thus, to avoid duplication, reference is made to that section. In FIG. 25, a MIP 2590 is envisioned as entering the detector in a direction normal to the detector's first surface 2520 and hitting the bulk 2510 at a distance r₀ (a point between cylindrical surface R and the external surface of p⁺ column). Upon hitting bulk 2510 at r₀, MIP 2590 travels in a path substantially parallel to the central column (p⁺ column) and the outer ring (n⁺ trench), thereby generating electron (e)-hole (h) pairs. The free carriers (e and h pairs) generated by MIP 2510 drift parallel to the detector's surface plane (i.e. parallel to first surface 2520 and/or second surface 2530). Specifically, in the case of FIG. 25, electrons will move perpendicular to and towards R (the inner surface of the outer ring); similarly, holes will move perpendicularly to and towards r_{c} (the outer surface of the inner column).

Depending on the position of entry point (rₒ) of the MIP and the number of generated carriers, the contribution to total collected charge from the drifting of electrons and holes will be different. At one extreme when r₀≈r_{c} (i.e., when the MIP enters the detector at a position substantially close to the inner column), the hole contribution to the collected charge would be essentially zero, and all of the induced current and collected charge can be attributed to electrons drifting across the cell from r_{c} to R. At the other extreme, when r₀=R, the electron contribution would be essentially zero, and all of the induced current and collected charge would be due to holes drifting across the cell from R to r_{c}.

For Si detector applications in high-energy physics experiments, such as those in the LHC at CERN, the above description remains true if the level of radiation environment is on the order of 1×10¹⁵ n_{eq}/cm² when the trapping of free carriers by radiation-induced defects is not significant. However, for extremely high radiation environments such as in the LHC upgrade (SLHC) where the radiation level is expected to reach up to 1×10¹⁶ n_{eq}/cm² (10 times higher), the trapping of free carriers becomes a seriously limiting factor. In FIG. 25, if MIP 2510 is stopped inside the detector, the measured charge is proportional to the energy of the particle; otherwise, if the particle traverses the detector, the measured signal is proportional to the energy loss of the particle. Particle stoppage or energy loss is due to Coulomb interaction, and scattering with the electrons and the core of the silicon atoms. In particular, the displacement of an atom of the semiconductor material from its normal lattice site, upon interaction of a charge particle with the semiconductor material, may be considered as the chief type of radiation-induced defect. The vacancy left behind, together with the original atom at an interstitial (displaced) position, constitutes a trapping site for normal charge carriers. The trapping site can capture a hole or an electron and keep it immobilized for a relatively long period of time. Although the trapping center will eventually release the carrier, the time delay is often sufficiently long to delay the average transient time, and/or to prevent the carrier from contributing to the measurable charge.

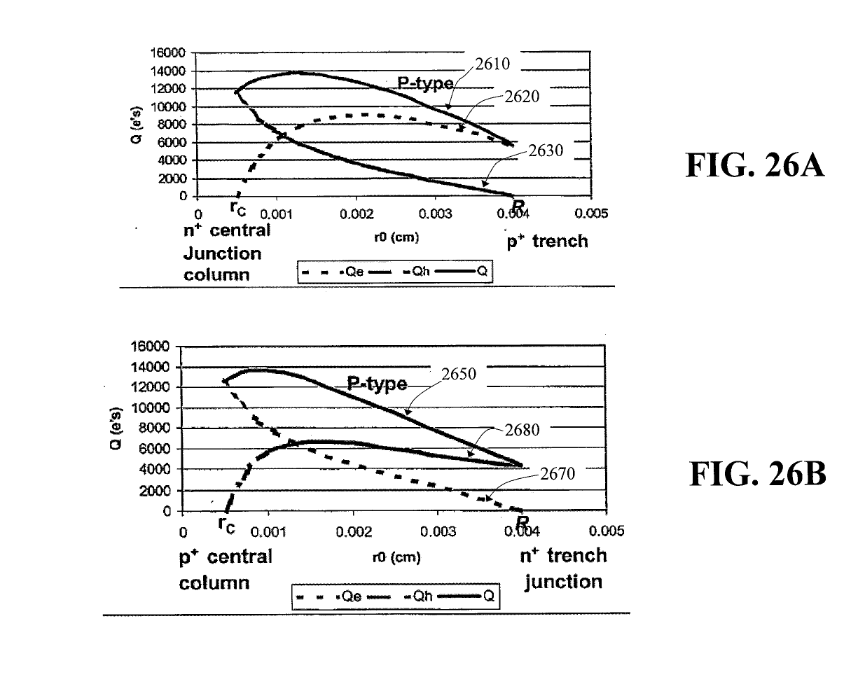

The defect of free carrier trapping is also closely related to particle incident position. For example, in extremely high-radiation applications such as in the LHC or the SLHC upgrade, with large trapping of free carriers, the total collected charge in a 3D-Trench detector may vary substantially depending on particle incident position on the detector. This is due to the fact that the probability of electron and/or hole trapping changes with the particle incident position, which when added to the weighting field profile affects the composition of electron and hole contributions to the total charge collected. FIGS. 26A and 26B depict the dependence of total collected charges and the contributions of electrons and holes to the total charges as a function of the particle incident position r₀.

FIG. 26A illustrates the total collected charge (plot 2610) and contributions thereof by electrons (plot 2620) and holes (plot 2630) in a single-cell 3D-Trench-CJ detector made of silicon. FIG. 26B is that of a 3D-Trench-ORJ detector of the same material, in which the total collected charge is plot 2650, and contributions thereof by electrons is plot 2670 and holes is plot 2680. The following conditions are assumed in both of FIGS. 26A and 26B: radiation fluence=1×10¹⁶ n_{eq}/cm²; r_{c}=5 μm; R=40 μm, d_{eff}=290 μm (Q₀=21,600 e's); V=243V (V_{fd}=206V) for 3D-Trench-CJ detector; and V=96V (V_{fd}=59V) for a 3D-Trench-ORJ detector. In general, as depicted in FIGS. 26A and 26B, the total collected charge is high when the particle incident position (r₀) is within the high weighting field region (see FIG. 11), or at least within about 10 μm of the inner electrode (central collecting column). In contrast, the charge is at its lowest when the particle incident position is away from the high weighting field, or near the outer electrode (i.e., near the inner surface of the outer ring trench).

The results depicted in FIGS. 26A and 26B are easily explained when the following considerations are taken into account: (1) the most effective charge collection distance is about 20 μm, thus electrons and/or holes generated at or near the outer ring (n⁺ trench) have a high probability of being trapped by irradiation-induced trapping centers before moving into the high weighting field region near the collection electrode 35 μm away. That is, when electrons and holes are drifting in the electric field in the region with low weighting field, the induced current and therefore electron/hole contributions to the total collected charge will be low. (2) As previously observed, at the extreme case of r₀=R, only one type of carrier contributes to the total induced current and collected charge. Therefore, when r₀=R, all free carriers will have to move from the inner surface of the trench (r=R) to the outer surface of the column (r=r_{c}), which means that there is a maximum trapping probably and therefore a low collected charge, e.g., (5000 to 6000 e's) when a MIP hits the detector at r₀=R. Turning back to FIGS. 26A and 26B, it is depicted that in a 3D-Trench-CJ detector the average charge collection is about 10,800 e's or a CCE of 50% (FIG. 26A). In a 3D-Trench-ORJ detector the average charge collection is about 9,650 e's or a CCE of 45%. Thus, it is again demonstrated that the average total collected charge is slightly less in an irradiated 3D-Trench-ORJ detector than in a 3D-Trench-CJ detector, which is attributed to the smaller bias voltage required by the 3D-Trench-ORJ detector.

For situations with low or no irradiation of particles, such as in applications of x-ray or γ-ray imaging, and low luminosity collider experiments, e.g., the relativistic heavy ion collider (RHIC), there is little or no trapping of free carriers. Therefore, the total collected charge would be essentially the full charge, and it is not dependent on the incident position of particles. As a result, for no irradiation or low luminosity, the overall charge collection time should be that of the maximum drift time of holes alone, as defined by Equation (41).

### 3.4 Considerations of Dead Space Between Pixels in a Multi-Pixel 3D-Trench Detector

One of the disadvantages in conventional radiation detectors is dead space in the detector sensitive volume. Specifically, as previously discussed, in conventional 2D and 3D detectors, metallic grids are necessary in multi-element (multi-pixel) x-ray detectors in order to prevent x-rays from entering the boundary regions between neighboring pixels to prevent charge sharing. Metallic grids complicate fabrication of the detector, and take up hundreds of micrometers within the detector sensitive volume. Thus, a dead space is created in the detector sensitive volume, and the use of such a detector is not optimal. Another area where dead space typically exists in conventional radiation detectors is around the edges of the bulk. In the case of planar 2D detectors, the sensitive region of the bulk is preferably kept away from the physical edge to protect the bulk from physical damage, e.g., cracks, current injection due to the extension of electric field to the edges at high bias voltages, and possible leakage caused by radiation. In conventional 3D detectors, the dead space of the bulk is minimized by providing electrode columns (rods) with minimum radius (about 5 μm) and large enough column spacing (about 50 μm or larger).

In a 3D-Trench detector, dead space in the detector sensitive volume is created due to trench etching. Specifically, the trench (outer or second electrode in this specification) acts as a “void” in the sensitive volume of the detector. Thus, initially it would appear that in such a 3D-Trench detector a dead space causing a fill factor degradation would be present. However, as fully demonstrated below, this reduction in sensitive volume may not necessary cause a significant problem in at least some applications of 3D-Trench detectors. Indeed, for applications in x-ray detection and energy spectroscopy, for example, the use of trenches in the fabrication of a detector can be considered extremely advantageous. Specifically, because in x-ray detection and energy spectroscopy no particle radiation is present, there is little or no trapping at all. Accordingly, in a 3D-Trench detector of the hexagonal type, R can be made comfortably large so at to meet specific application requirements. For example, it is estimated that with an R=100 μm, a dead space of only about 8% can be obtained. Moreover, with an R=500 μm the dead space would be only about 2% or less of the detector's sensitive surface. Thus, metallic grids in the order of 100 μm or larger would be entirely avoided by the use a more space-efficient trench based detector.

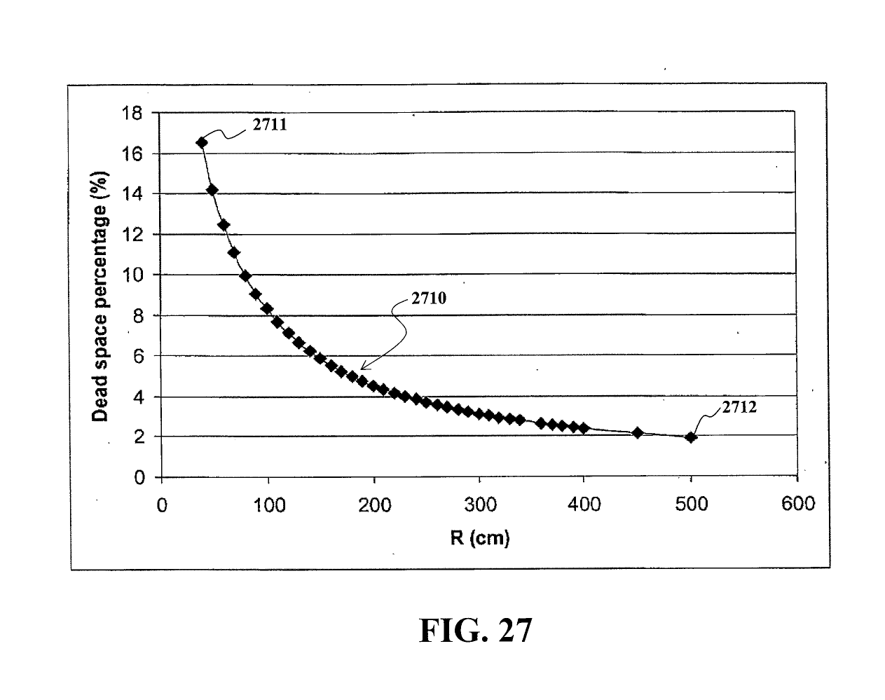

FIG. 27 illustrates a plot 2710 representing dead space percentage as a function of the distance R for a single-cell 3D-Trench detector of the hexagonal type. In FIG. 27, a 3D-Trench electrode Si detector with an inner electrode diameter of 10 μm (r_{c}=5 μm) and an outer electrode width equal to 10 μm (trench width w=10 μm) is considered. As depicted in FIG. 27, it is evident that as the distance R increases, the percentage of dead space is reduced considerably. At one extreme, at point 2711, where R would be approximately 40 μm, the dead space is over 16%. Since the application of small R 3D-Trench detectors is in the high-energy physics experiments with extremely large trapping, 16% dead space is still much less than the default charge loss due trapping of more than 95% in 2D detectors having 300-μm thickness. Also it is not too much larger than the 4% dead space of a conventional 3D detector with 50-μm pitch and 5-μm radius columns, but with more homogenous electric field distribution and much lower full depletion voltages. On the other hand, at point 2712, where R is 500 μm, the dead space goes down to 2%. As a result, depending on the specific geometry of the detector, the new 3D-Trench design can provide a remarkable improvement over conventional 2D detectors.

### 4. Examples of 3D-Trench Detectors for Practical Applications

There may be numerous applications where the above-described embodiments of the new 3D-Trench detector may be suitable. This description makes no attempt to exhaustively enumerate all possible embodiments or applications of the present invention. Rather, a bona fide effort has been made to disclose sufficient information that would enable one of ordinary skill in the art to practice the various embodiments of this invention without undue experimentation. To that end, what follows is one possible example of how one of the described embodiments may be adapted for a practical application.

Due to its near uniform electric field distribution and relatively low full depletion voltage, the new 3D-Trench-ORJ detector appears to provide excellent basis for hard x-ray and/or γ-ray applications, for example, in photon science. One of the advantages in x-ray applications is that there is little or no displacement damage (bulk substrate damage) that could cause free carrier trapping. This advantage alone may greatly relax the requirement for close electrode spacing. For example, the extremely high irradiation fluences expected in the LHC upgrade (SLHC) may potentially produce a large number of trapping defects in a 3D-Trench detector. In principle, therefore, R should be made small to minimize trapping. However, as demonstrated above, a 3D-Trench-ORJ detector allows for R to be made as large as 500 μm without affecting the efficiency of the detector. Moreover, due to the much smaller depletion voltage needed in a 3D-Trench-ORJ detector, one can easily make the electrode spacing as large as 500 μm, which can produce a pixel pitch as large as 1 mm. Then, as the electrode spacing increases (or R increases), the percentage of dead space between pixels due to trenches will be greatly reduced to even less than 2%. As a result, a 3D-Trench-ORJ detector appears to be ideally suited for photon science applications such as x-ray and/or γ-ray detection.

In addition, with ever advancing improvements in modern etching technology, which enables the etching of vertical structures with an aspect ratio (AR) of trench depth l to trench width W_{T}(AR=l/W_{T}) of 25-50 to 1, it is envisaged that detector thicknesses as large as 1 mm to 2 mm or more can be used for high detection efficiencies well into the 10's of keV of hard x-ray radiation. Also, in a multi-pixel detector, based on a 3D-Trench-ORJ detector cell, all pixels would be isolated from each other solely due to the natural separation provided by the trench wall. More specifically, in a multi-pixel 3D-Trench detector, the sensitive volume of each cell would be naturally separated from each other due to the dead space or void created by the etching of the outer electrode (trench). Accordingly, there will be no charge sharing between neighboring pixels. Less charge sharing may in turn greatly reduce the tail in energy spectrum, thus improving the peak to valley ratio and energy resolution.

4.1. Single-Cell 3D-Trench Detector with Enhanced Electrode Separation

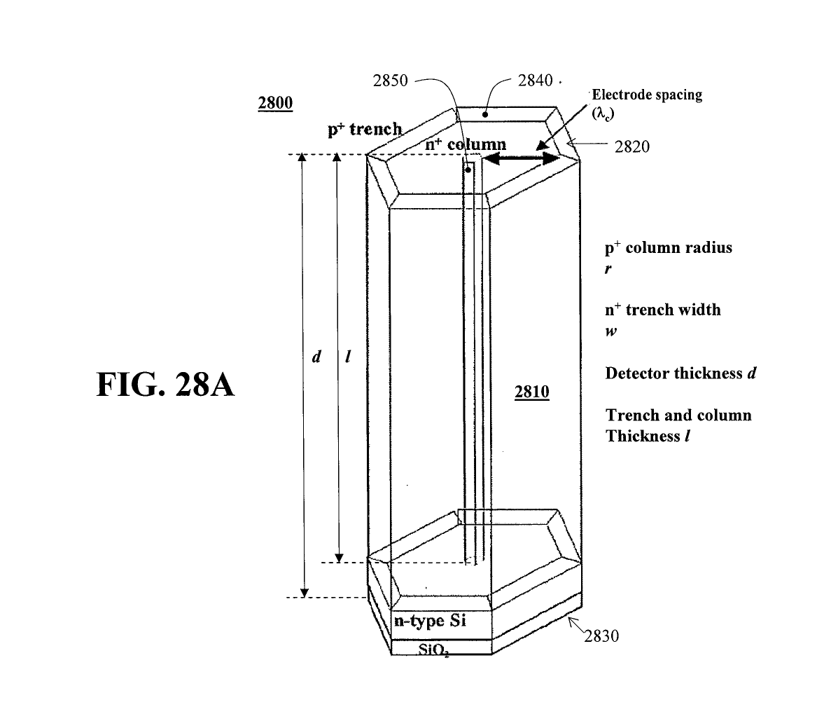

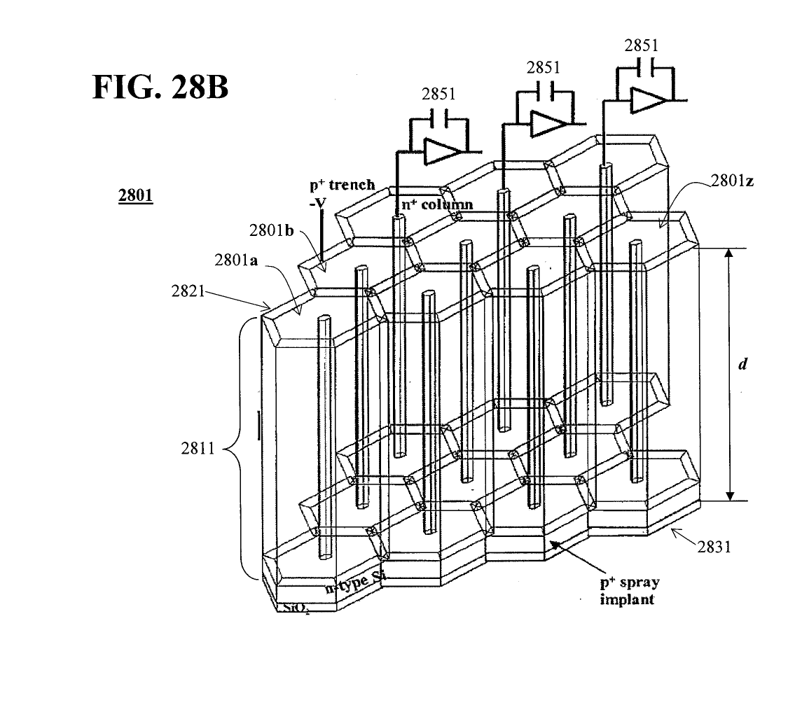

FIG. 28A schematically illustrates an example of a single-cell 3D-Trench-ORJ detector 2800 which can be used, among other things, for x-ray applications. The 3D-Trench-ORJ detector 2800 is preferably configured substantially similar to the detector 1300 of FIG. 13. The principal difference between detector 2800 as compared with detector 1300 is that, for hard x-ray applications, detector 2800 may be configured on a relatively larger scale. In particular, the first and second electrodes of detector 2800 are preferably spaced apart from each other between 30 μm and 500 μm and more preferably between 100 μm and 500 μm. As illustrated in FIG. 28A, detector 2800 is formed of an n-type bulk 2810 with a thickness d into which a first electrode 2840 and a second electrode 2850 have been formed, for example, by etching and filling corresponding first and second doped regions. The first electrode 2840 is formed in a shape of hexagonal tubular structure (trench) and includes a material of a first conductivity type (p⁺). The second electrode 2850 is formed in a shape of hexagonal (or circular) column that includes a material of a second conductivity type (n⁺). In the context of diode junctions, the p⁺/n junction is formed at the outer or first electrode, i.e., between the inner surface of first electrode 2840 (p⁺ trench) and the n-type bulk 2810.

As discussed above, the improved CCE and low depletion voltage characteristics of the 3D-Trench-ORJ detector allow for such a detector to be fabricated on a relatively large scale as compared to conventional 3D detectors. In the example of FIG. 28A, the bulk thickness d can range between 500 μm and 2000 μm. The first and second electrodes 2840 and 2850 penetrate into the bulk from a first surface 2820 without reaching a second surface 2830, so as to reach a predetermined trench and column depth l along the bulk thickness d. Preferably, the first and second electrodes extend into the bulk from the first surface 2820 a depth l ranging between 90 and 95% of the bulk thickness d (0.9d≦l≦0.95d). Electrode spacing λ_{c}, in this embodiment, is not particularly limited to specific dimensions, but it can range between 100 μm and 500 μm (λ_{c}˜100-500 μm). As in the previous embodiments, the 3D-Trench-ORJ detector 2800 thus formed comprises at least a bulk of a predetermined thickness having first and second surfaces separated by said thickness, a first electrode shaped as a trench and a second electrode shaped as a column, the first and second electrodes being concentric to each other and penetrating from the first surface into the bulk along the thickness of the bulk for a predetermined distance equal to or less than 95% of said thickness, and the second electrode being completely surrounded by the first electrode along the entire predetermined distance.

4.2. Multi-Pixel 3D-Trench Detector with Enhanced Electrode Separation and Increased Pixel Pitch

FIG. 28B illustrates a multi-pixel 3D-Trench-ORJ detector that includes an array of single-cell units (detecting units) of the type described above in reference to FIG. 28A. Specifically, in FIG. 28B, a multi-pixel 3D-Trench-ORJ 2801 represents an exemplary embodiment of a multi-pixel detector for x-ray radiation applications. The multi-pixel 3D-Trench-ORJ detector 2801 is formed on a semiconductor bulk 2811 (n-type, for this embodiment) having a first surface 2821 and a second surface 2831 that is separated from the first surface by a bulk thickness d, and includes a plurality of 3D-Trench-ORJ cells (detecting units) 2801a to 2801z. Each of the single cells 2801a to 2801z may be considered as a detecting unit or pixel that is formed in a manner substantially similar to the above-described single-cell 3D-Trench-ORJ detector illustrated in FIG. 28A. As shown in FIG. 28B, all of the outer electrodes of the multi-pixel 3D-Trench-ORJ detector may be connected together to a common negative voltage bias (−V), and each inner electrode of the 3D-Trench-ORJ detector may be connected to an electronics channel 2851 for signal readout.

In order to isolate the central collecting n⁺ columns (first electrodes) of the multi-pixel 3D-Trench-ORJ detector 2801 of FIG. 28B, a p⁺ spray ion implantation of a few micrometers in thickness may be applied on the backside of the bulk substrate before full detector processing is performed. In addition, on the second surface of bulk 2811a thin layer of silicon dioxide (SiO₂) no more than a few micrometers in thickness is formed for protecting the bulk from environmental agents. Other appropriate protective materials, such as silicon nitride, parylene, or multiple layers of protective materials, may be used in addition to or instead of the silicon dioxide. Since no lithography is needed for this step, and no further processing is required for the backside, the detector processing remains truly one-sided.

Referring back to FIG. 28A, it should be noted that among the parameters for the 3D-Trench-ORJ detector for x-ray applications, the radius for the collecting n⁺ column (second electrode 2850) is indicated as being only 5 μm (r=5 μm). As a result, the areas of the collecting electrodes in the multi-pixel detector of FIG. 28B are very small. The small inner electrode surface results in a notable advantage for this type of detector. Specifically, in FIG. 28B, the capacitance of each pixel is dominated by the depth of column n⁺, which can be a maximum of about 0.2 cm. Typical capacitance for this type of electrode geometries is about 0.5 pF/cm. Thus, for this embodiment, total capacitance per single-cell (C_{cell}) could be as low as 0.1 pF (C_{cell}=0.2 cm×0.5 pF/cm=0.1 pF). Depending on the number of cells (pixels) required, this would represent a fairly small overall capacitance for the entire detector. A small capacitance in turn ensures low noise, and improves the x-ray energy resolution, as well as signal to noise ratio.

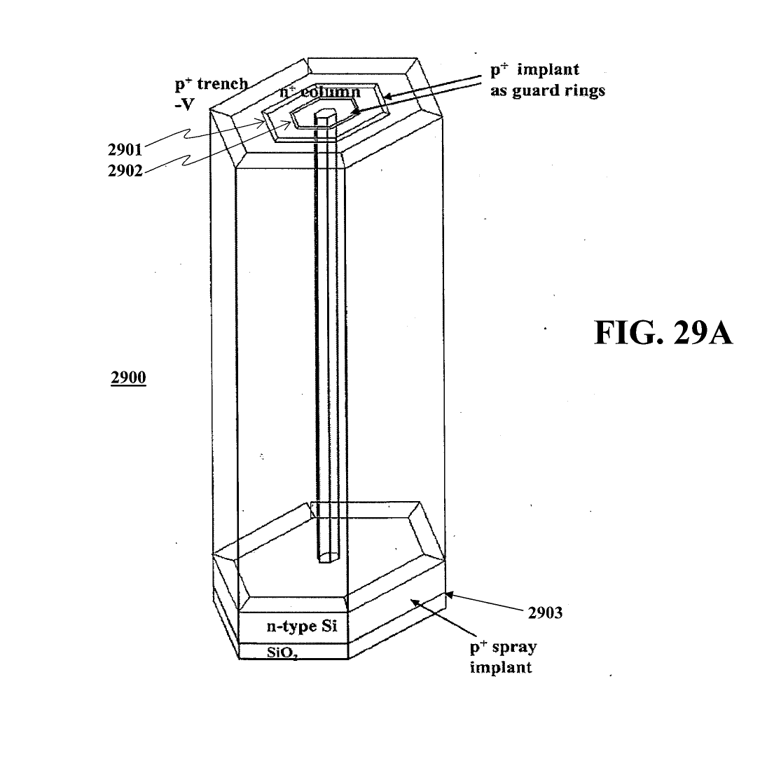

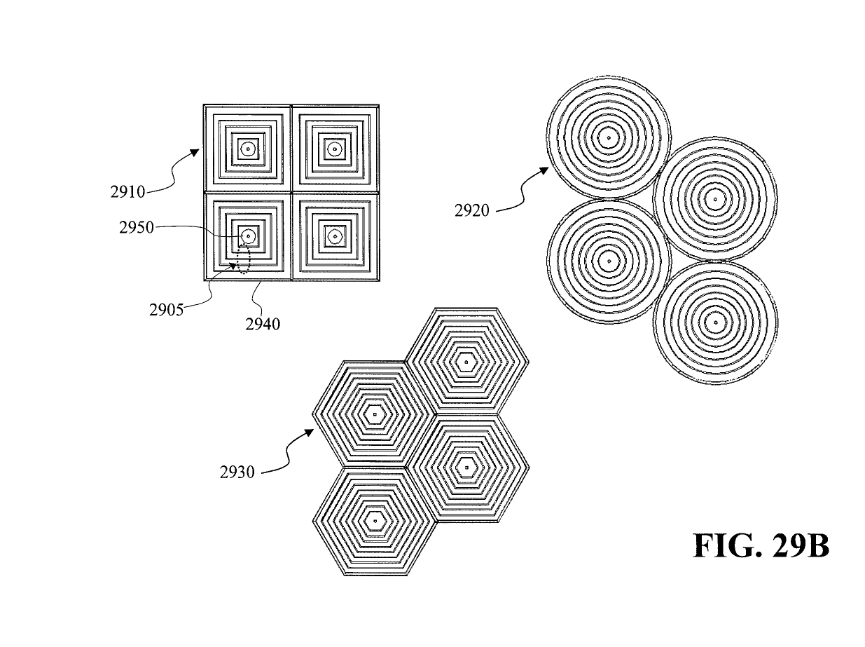

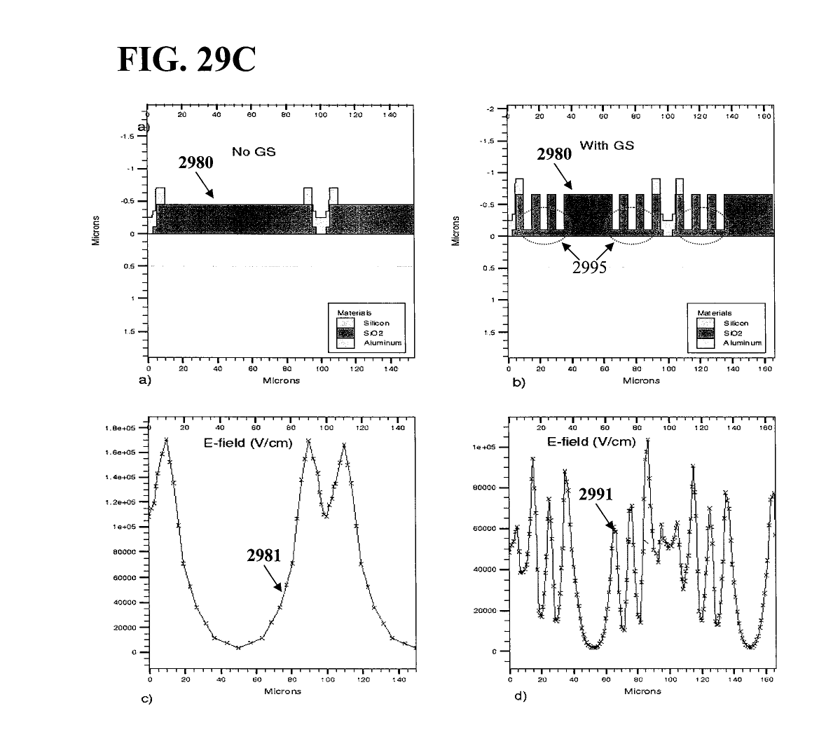

There may be a risk of running an electric field that is high enough to approach the breakdown field of the semiconductor material, especially along the front surface of the detector, when very thin collection electrodes are used in this embodiment. To reduce the lateral field along the front surface, a multi-guard-ring-system (MGRS) with ion implantations may be used. FIG. 29A illustrates such an embodiment.

In FIG. 29A, a perspective view of a single-cell 3D-Trench-ORJ detector 2900 of a configuration substantially similar to that of detector 2800 in FIG. 28A is illustrated. One notable difference, with respect to detector 2800, is that 3D-Trench-ORJ detector 2900 includes a plurality of concentric p⁺ implants (2901 and 2902) as guard rings that have been formed on the front surface of the detector surrounding the collecting n⁺ column (second electrode). Detector 2900 also includes a p⁺ spray ion implantation of a few micrometers for isolating the n⁺ column on the backside (or back surface) of the bulk, and a thin layer 2903 of silicon dioxide (SiO₂) for protection of the bulk. The p⁺ spray and SiO₂ layer are preferably applied to the backside of the bulk before full detector processing is performed. Thus, even if guard ring implants are required on the front side of the bulk, the processing of the detector still remains single-sided.

FIG. 29B illustrates possible configurations of multi-guard-systems adapted to front surfaces of multi-pixel 3D-Trench detectors. Detector 2910 is a top view of a multi-pixel 3D-Trench detector of the rectangular type in which a MGRS 2905 has been formed between a first electrode 2940 and second electrode 2950. Detectors 2920 and 2930 are top views of 3D-Trench detectors of the circular and hexagonal type, respectively, each of which also includes the MGRS between the first and second electrodes.

The multi-guard-ring system is preferably formed by known techniques of ion implantation of the dopant type that formed the junction. The ion implantation may reach a depth of few hundred nanometers from the surface of the detector. Preferably, the depth of the ion implantation may be in the range of 10 nm to 10000 nm. The MGRS helps control electric field potential drop over the detector's sensitive region between the first and second electrodes, and prevents concentration of high electric fields around the junction electrode. FIG. 29C illustrates the effect of an exemplary MGRS in strip detectors. Subset (a) of FIG. 29C illustrates a silicon strip detector 2980 without guard strip (GS) on its surface. The electric field profile 2981 of strip detector 2980 is shown in subset (c) of FIG. 29C. From subset (c) of FIG. 29C, it can be observed that the electric field potential is highly concentrated around 10 μm and 100 μm of the strip detector's surface. The guard strips between the two electrodes are preferably left floating, while the two electrodes are biased. In contrast, subset (b) of FIG. 29C illustrates a strip detector 2990 with a MGRS 2995. The electric field profile 2991 of strip detector 2990 is illustrated in subset (d) of FIG. 29C. In the case where the MGRS is used, it can be observed that the electric field is more evenly distributed across the entire sensitive region of the front surface of detector 2990. As a result, it appears that a MGRS prevents concentration of high electric fields near the junction electrode of the detector.

### 5. Method of Forming a 3D-Trench Detector

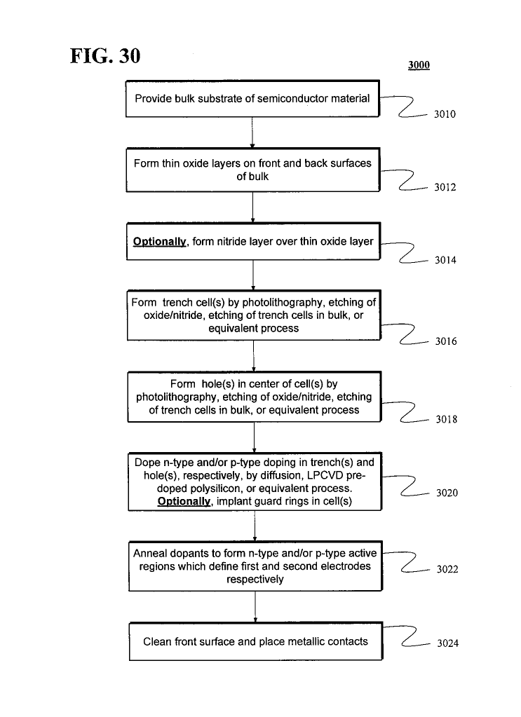

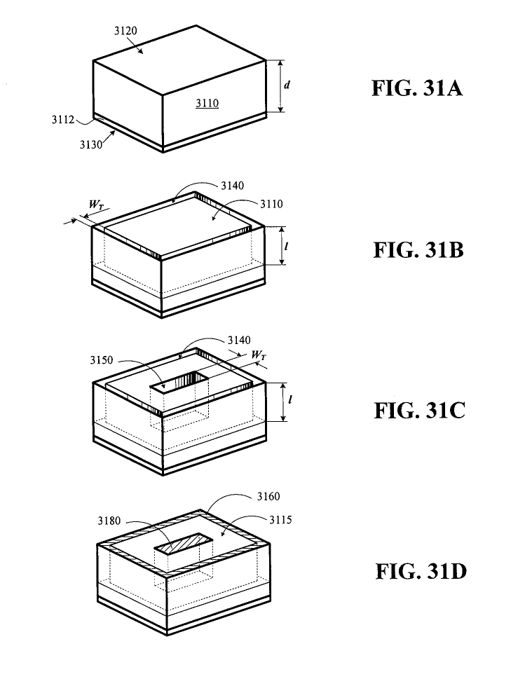

FIG. 30 is a flowchart illustrating exemplary manufacturing steps of a process used for manufacturing a single-cell 3D-Trench detector in accordance with one embodiment of the present invention. The process steps of FIG. 30 are described in conjunction with, and in reference to, FIGS. 31A to 31D which show perspective views of the single-cell 3D-Trench detector at progressive stages of fabrication.

Referring to FIG. 30, fabrication process 3000 begins at step S3010 where a bulk of semiconductor material is provided, as shown in FIG. 31A. Referring to FIG. 31A, a 3D-Trench detector is formed on a bulk 3110 of lightly doped semiconductor material, such as a silicon wafer. Bulk 3110 is preferably formed as a single crystal of semiconductor material having a front or first surface 3120, a second or back surface 3130 and a predetermined bulk thickness d. A thin oxide layer 3112 having a thickness of a few micrometers is formed on at least one of the surfaces of the bulk (preferably at least on the back surface). The thin oxide layer protects the bulk during the processing steps. Then, an optional silicon nitride layer (not shown) may be deposited over the thin oxide layer 3112. The thin oxide layer 3112 and optional silicon nitride layer are preferably formed by a conventional thermal oxidation process. These steps are illustrated as steps S3012 and S3014. Preferred the semiconductor materials may include silicon, germanium, silicon-germanium, silicon-carbide, CdTe, CZT, or equivalents thereof. Other semiconductor materials that also may be used are CdMnTe, HgI₂, TlBr, HgCdTe, CdMnTe, HgZnSe, GaAs, PbI₂, AlSb, InP, ZnSe, ZnTe, PbO, BiI₃, SiC, HgₓBr₁₋ₓI₂, HgₓCd₁₋ₓI₂, wherein x is greater than 0 and less than 1, InI₂, Ga₂Se₃, Ga₂Te₃, TlPbI₃, Tl₄HgI₆, Tl₃As₂Se₃, TlGaSe₂, or AgGaTe₂. It should be noted, however, that the embodiments of the present invention are not limited to specific semiconductor materials. Those materials can be selected, in accordance with application's requirements, as best understood by those of ordinary skill in the art.

Next, at step S3016 a deep and narrow cut or ditch, also known as a “trench,” is made around the periphery (outer edges) of a single cell in the bulk 3110 such that a rectangular trench 3140 is formed therein, as shown in FIG. 31B. Trench 3140 may be formed by conventional photolithographic techniques. For example, trench 3140 may be formed by using a process such as reactive ion etching (RIE) or preferably deep reactive ion etching (DRIE) in a manner conventionally known to form, for example, trench capacitors for integrated circuit memory devices. As shown in FIG. 31B, trench 3140 is made by removing a portion of semiconductor material from the bulk. Preferably, a volume of semiconductor material from around the periphery of a single cell in the bulk 3110 that is delimited a predetermined width W_{T} and a predetermined depth l is removed from a single cell in the bulk 3110, by processing the bulk from the first surface 3120 along the bulk thickness d.

At step S3018, a rectangular hole 3150 is formed in the center region a single cell in the bulk 3110. Hole 3150 may be formed using the same or an equivalent process as that used for forming the trench 3140; depending on specific design requirements, other known processes may be used. For example, in some of the above-described embodiments of the present invention, a 3D-Trench detector may require a deep cylindrical hole of a narrow diameter in the center of bulk 1310 instead of a rectangular one as shown in FIG. 31C. In such a case, an alternative process such as laser ablation may also be suitable for forming a narrow and deep cylindrical hole. This step S3018 is illustrated in FIG. 31C. As shown in FIG. 31C, hole 3150 also has a width W_{T} and extends into the bulk 310 a depth l from the first surface 3120 of bulk 3110 along the bulk thickness d. In alternate embodiments, the trench 3140 may be etched from the first surface, while the hole 3150 may be etched from the second surface.

Prior to forming trench 3140 and hole 3150, a mask (not shown) defining therein predetermine shapes corresponding to the cross-sections of trench 3140 and hole 3150 is preferably laid over the surface of the bulk 3110.

Returning to the process of FIG. 30, at step S3020, the trench 3140 and hole 3150 formed at steps S3016 and S3018, respectively, are each filled with material doped with one of a first conductivity type dopant and a second conductivity type dopant. Specifically, n-type and/or p-type dopants are deposited into trench 3140 and hole 3150, respectively, for example, by diffusion into undoped material or low-pressure chemical vapor deposition (LPCVD) of pre-doped polysilicon, or equivalent processes. In addition, where appropriate and required, a plurality of guard rings (as discussed in the last paragraph of section 4.2 and shown in FIG. 29) can be formed by doping at least one surface of a single cell detector with the above-described doping processes. After the n-type and/or p-type regions have been doped into the trench 3140 and hole 3150, the bulk 3110 is subjected to a high temperature annealing process (step S3022) to provide slight diffusion of the dopants into the single crystal bulk and to activate the n-type and p-type regions. Dopant materials can be selectively chosen in accordance with particular application requirements. Suitable dopants may be selected based on the atomic properties of the dopant and the material to be doped.

For example, for group 4 semiconductors such as silicon, germanium, and silicon carbide, the most common dopants are acceptors from group 3 or donors from group 5 elements. Boron, arsenic, phosphorus, and occasionally gallium are used to dope silicon. Boron is the p-type dopant of choice for silicon integrated circuit production because it diffuses at a rate that makes junction depths easily controllable. Phosphorus is typically used for bulk-doping of silicon wafers, while arsenic is used to create junctions, because it diffuses more slowly than phosphorus and is thus more controllable. By doping pure silicon with group 5 elements such as phosphorus, extra valence electrons are added that become unbonded from individual atoms and allow the compound to be an electrically conductive n-type semiconductor. Doping with group 3 elements, which are missing the fourth valence electron, creates “broken bonds” (holes) in the silicon lattice that are free to move. The result is an electrically conductive p-type semiconductor. In this context, a group 5 element is said to behave as an electron donor, and a group 3 element as an acceptor. Doping concentrations for the above-described trench and column electrodes may be in the range of 10¹⁶ cm⁻³ to 10²⁰ cm⁻³, or preferably in the range of 10¹⁹ atoms per cubic centimeter (cm³) in the volume of the semiconductor material.

However, it is also envisioned in an alternative embodiment that the doping concentration for the above-described trench and column electrodes can be so high that it acts more like a metal conductor than a semiconductor and referred to as degenerate semiconductor. Without being bound by a theory, it is anticipated that at high enough dopant concentrations the individual dopant atoms may become close enough neighbors that their doping levels merge into an dopant band and the behavior of such a system ceases to show the typical traits of a semiconductor, e.g. its increase in conductivity with temperature. Nonetheless, a degenerate semiconductor still has far fewer charge carriers than a true metal so that its behavior is in many ways intermediary between semiconductor and metal.

Yet in another alternative, and in particular for the high-Z semiconductor materials, instead of the highly doped semiconductor(s) described above, the electrodes may be produced from the metallic conducting material, such as for example gold (Au) or any other similarly situated metallic materials.

FIG. 31D illustrates a first doped region which defines an outer or first electrode 3160 and a second doped region which defines an inner or second electrode 3180. The electrodes 3160 and 3180, in this embodiment, are the result of the etching and filling of trench 3140 and hole 3150, respectively. Accordingly, the first electrode 3160 is also referred to as a “trench electrode,” and the second electrode 3180 is also referred to as a “column.” The doping and annealing processes form alternate p-type and n-type doped regions which are separated from each other by a predetermined distance occupied by a region 3115 of the lightly doped semiconductor material of bulk 3110. This region 3115 of the lightly doped semiconductor material of bulk 3110 constitutes the detector's sensitive region. Depending on the type of dopant used in the lightly doped semiconductor material of bulk 3110, a p-n junction (semiconductor junction) is formed between one of first and second electrodes and the portion 3115 of bulk 3110. When the semiconductor junction is formed between the inner or second electrode and the bulk, a central junction (CJ) electrode is formed. Alternatively, when the semiconductor junction is formed between the outer or first electrode (trench) and the bulk, and outer ring junction (ORJ) is formed. To complete the process of forming the 3D-Trench detector, at step S324, the first surface is cleaned and readied for placement of metallic contacts (not shown).

In the foregoing exemplary steps of the fabrication process 3000 of FIG. 30 and the progressive fabrication stages illustrated by FIGS. 31A to 31D, it should be noted that preferably (1) the trench 3140 and hole 3150 both extend into the bulk a predetermined depth l which is less than the bulk thickness d such that none of the first and second electrodes traverses the bulk from the front to the back surface; (2) the first electrode completely surrounds the second electrode such that the two electrodes are substantially parallel and concentric to each other; (3) the backside of the bulk 3110 is covered at least by a thin layer of silicon oxide and there is no etching or implantation on the back side. Thus, the process of fabricating the 3D-Trench detector may be completely single-sided. However, the 3D-Trench detector is not limited to these parameters. For example, when specific design parameters are required, at least one of the first and second electrodes may be allowed to traverse the entire thickness d of the bulk from the front to back surfaces. In addition, the 3D-Trench detector may be modified such that one electrode extends from the front surface and the second electrode extends from the back surface.

In addition, although a rectangular trench electrode and a corresponding rectangular column have been described, it should be understood that other electrode shapes are possible. Indeed, as described in section 1.1., 1.1.3. and 1.2., 3D-Trench detectors with 3D trench electrodes and 3D column electrodes having cross-sections that are circular or polygonal, such as triangular, square, hexagonal, octagonal, and the like, are considered within the possible embodiments of the present invention. Moreover, as will be readily understood by those of ordinary skill in the art, the foregoing exemplary steps of the fabrication process may be easily adapted to fabricate a multi-cell (e.g., multi-pixel or strip) detector by fabricating a plurality of single-cell detecting units, as set forth above in a mask designed with arrays of single cells. For the case of a multi-cell detecting unit, it should be understood that adjacent detecting units may be configured to share at least part of the first electrode. Accordingly, fabrication of a multi-cell detecting unit contemplates forming a plurality of trenches and holes, and subsequently filling said trenches and holes as described above.

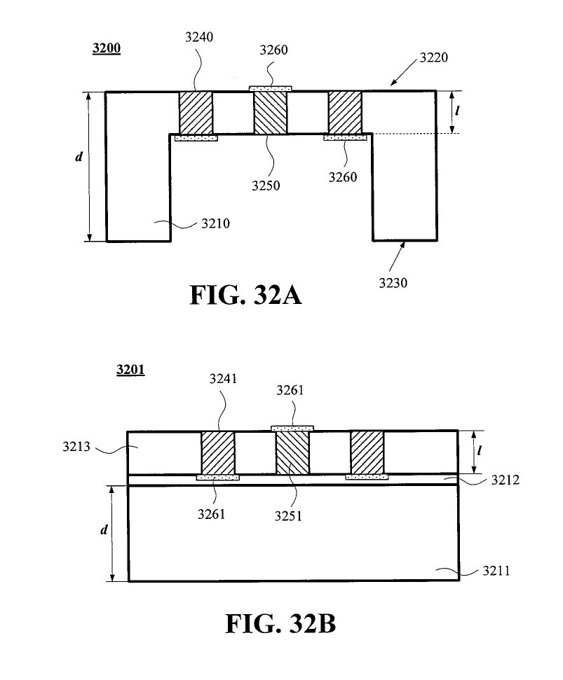

FIGS. 32A and 32B illustrate 3D-Trench detectors 3200 and 3201, respectively, which may be formed by an alternate manufacturing process, as contemplated by a further embodiment of the present invention. Specifically, the above description in section 5, considered a method for forming a 3D-Trench electrodes by forming trenches and subsequently filling the trenches with predetermined dopants, or by diffusing said dopants into the bulk semiconductor material to form the 3D electrodes. In an alternate embodiment, however, it is possible that 3D detectors of relatively reduced thicknesses may be formed by enhanced implantation techniques.

FIG. 32A illustrates a 3D detector 3200 formed in a bulk 3210 of semiconductor material having a first surface 3120 and a second surface 3230. Bulk 3210 may have a predetermined thickness d similar to those described in reference to previous embodiments. In FIG. 32A, however, a first electrode 3240 and a second electrode 3250 may be formed by implanting predetermined conductive type ionized dopants to a predetermined depth l. The energy of the ions, as well as the ion species and the composition of the target material can be selected in accordance with specific application parameters such that the depth of penetration of the ions into the semiconductor material may be optimized. A monoenergetic ion beam will generally have a broad depth distribution. The average penetration depth, also called the range of ions, will determine the depth l of the desired electrode, and consequently the effective thickness of the detector.

Current technology and known semiconductor materials allow for ion ranges between 10 nanometers and 1 micrometer, up to a few micrometers. Thus, ion implantation is especially useful in cases where the chemical or structural change in semiconductor material is desired to be near the surface of the detector. However, it may be possible that ion implantation with very high-energy ion sources and appropriated masking materials could reach ion ranges of up to 10 or even 20 micrometers. It is foreseen therefore that an enhanced implantation process would enable the fabrication of 3D detectors with substantially thin substrates equivalent to the average range of ions. Advantageously, forming a 3D detector with 3D electrodes, where the electrodes are formed by high-energy implantation processes can be equivalent to forming a planar or 2D detector, which implies that the manufacturing process can be a simplified one. In FIG. 32A, bulk 3210 first undergoes ion implantation from the first surface 3220 and later is back-etched on the second surface 3230 so as to reduce the thickness d of the bulk semiconductor material to a depth l. Alternatively, the bulk material can first be processed to a reduced thickness and then it can then undergo an implantation process. In any case, after the 3D electrodes have been formed, and the bulk thickness has been reduced, metallic contacts 3260 such as solder bumps or the like may be formed on ether side of the bulk material.

FIG. 32B illustrates a 3D detector 3201 in which 3D electrodes may be formed by an enhanced implantation process as described above. In FIG. 32B, a bulk semiconductor material 3211 having a predetermined thickness d is used as a support wafer. A thin coat of silicon dioxide (SiO₂) 3212 serves to protect a thin semiconductor wafer 3213. The support wafer of semiconductor material 3211, SiO₂ 3212 and semiconductor wafer 3213 may be arranged as shown in FIG. 32B in accordance with any known technique for preparing silicon on insulator (SOI) substrates. Semiconductor wafer 3213 is to be selected so as to closely match the range of ions and the capacity of the ion implanting source such that a minimum ion implantation depth l may be achieved. The remaining parameters such as electrode separation (λ_{c}), electrode width W_{T}, electrode (trench or column) cross-section and other parameters of the detector 3201 can then be optimized in accordance with any of the embodiments described in the previous sections of this specification. Specifically, an ion implanted 3D outer or first electrode 3241 can be formed in any one of a rectangular, triangular, circular, or hexagonal type of trench. Similarly, a central or second electrode 3251 can be formed as a polygonal or circular column. Finally, metallic contacts 3261 such as solder bumps or the like may be formed on ether side of the thin wafer 3213.

Although the disclosure has been described in connection with specific embodiments, it should be understood that the invention as claimed should not be unduly limited to such specific embodiments. Indeed, those skilled in the art will recognize, and be able to ascertain using no more than routine experimentation, many equivalents to the specific embodiments described herein. Such equivalents and modifications thereof are intended to be encompassed by the following claims.

1. A radiation detector, comprising:
a semiconductor material having a bulk thickness and defining thereon a first surface opposite to a second surface, the second surface being separated from the first surface by said bulk thickness;
a first electrode defining a three-dimensional (3D) trench and extending into the bulk from one or both of the first and second surfaces along the bulk thickness; and
a second electrode defining a 3D column, the second electrode also extending into the bulk from one or both of the first and second surfaces along the bulk thickness,
wherein the first electrode surrounds the second electrode such that the first and second electrodes are substantially parallel and concentric to each other, and
wherein the first and second electrodes are separated from each other by a predetermined distance determined by a region of the semiconductor bulk contained between the first and second electrodes.

2. The radiation detector according to claim 1, wherein both the first electrode and the second electrode extend into the bulk of the semiconductor from the same surface of said one of the first and second surfaces.

3. The radiation detector according to claim 1, wherein the first electrode and the second electrode extend into the bulk of the semiconductor from a different surface of said one of the first and second surfaces.

4. The radiation detector according to claim 1, wherein the first and second electrode extend into the bulk of the semiconductor so as to reach a depth equal to or less than 95% of the bulk thickness.

5. The radiation detector according to claim 1, wherein the first and second electrode fully extend 100% through the bulk thickness from one of the first and second surfaces to the other of the first and second surfaces.

6. The radiation detector according to claim 1, wherein the first electrode includes a first conductivity type dopant, the second electrode includes a second conductivity type dopant different from the first conductivity type dopant, and wherein the bulk of the semiconductor is doped with one of the first and second conductivity type dopant.

7. The radiation detector according to claim 1, wherein the first electrode defines a rectangular strip trench and the second electrode defines a rectangular strip column arranged in the center of the rectangular strip trench.

8. The radiation detector according to claim 1, wherein the first electrode defines a trench of a polygonal or circular cross-section and the second electrode defines a column of a polygonal or circular cross-section.

9. The radiation detector according to claim 8, wherein the first electrode defines the trench having a hexagonal cross-section and the second electrode defines the column having a hexagonal or circular cross-section.

10. The radiation detector according to claim 8, wherein the first electrode defining a trench of a polygonal cross-section has a gap in each side of the polygonal cross section.

11. The radiation detector according to claim 8, wherein the first electrode defining a trench of a circular cross-section has one or more gaps.

12. The radiation detector according to claim 1, wherein a semiconductor junction is formed at a region where the bulk of semiconductor material joins the second electrode, the second electrode defining a central junction electrode.

13. The radiation detector according to claim 1, wherein a semiconductor junction is formed at a region where the bulk of semiconductor material joins the first electrode, the first electrode defining an outer ring junction.

14. The radiation detector according to claim 1, wherein a predetermined bias voltage is applied to the first and second electrodes such that an electric field is created between the first electrode and the second electrode.

15. The radiation detector according to claim 14, wherein an intensity of the electric field at the first electrode is substantially equal to an intensity of the electric field at the second electrode.

16. The radiation detector according to claim 14, wherein the intensity of the electric field between the first and second electrodes is substantially uniform throughout the entire volume of the bulk of the semiconductor contained between the first and second electrodes.

17. The radiation detector according to claim 1, wherein the bulk of the semiconductor is a single crystal of said semiconductor material doped with a p-type dopant or an n-type dopant.

18. The radiation detector according to claim 17, wherein the first electrode includes a conductivity type dopant of the p-type, and the second electrode includes a conductivity type dopant of the n-type.

19. The radiation detector according to claim 17, wherein the first electrode includes a conductivity type dopant of the n-type, and the second electrode includes a conductivity type dopant of the p-type.

20. The radiation detector according to claim 17, wherein the semiconductor material is silicon (Si), germanium (Ge), silicon-germanium (Si₁₋ₓGeₓ, wherein x is greater than 0 and less than 1), silicon carbide (SiC), cadmium telluride (CdTe) or cadmium zinc telluride (CdZnTe).

21. The radiation detector of claim 17, wherein the semiconductor material is CdMnTe, HgI₂, TlBr, HgCdTe, HgZnSe, GaAs, PbI₂, AlSb, InP, ZnSe, ZnTe, PbO, BiI₃, SiC, HgₓBr₁₋ₓI₂, HgₓCd₁₋ₓI₂, wherein x is greater than 0 and less than 1, InI₂, Ga₂Se₃, Ga₂Te₃, TlPbI₃, Tl₄HgI₆, Tl₃As₂Se₃, TlGaSe₂, or AgGaTe₂.

22. The radiation detector according to claim 18, wherein the semiconductor material is silicon, germanium, silicon-germanium, or silicon carbide, and wherein the conductivity type dopant of the p-type includes at least one of a group 3 element and the conductivity type dopant of the n-type includes at least one of a group 5 element.

23. The radiation detector according to claim 22, wherein the semiconductor material is silicon and the dopant of electrode is boron, arsenic, phosphorus or gallium.

24. The radiation detector according to claim 22, wherein the doping concentration of electrode is in the range of about 10¹⁶ cm⁻³ to about 10²⁰ cm⁻³ (atoms per cubic centimeter) in the volume of the semiconductor material.

25. The radiation detector according to claim 24, wherein the doping concentration of electrode is about 10¹⁹ cm⁻³ (atoms per cubic centimeter) in the volume of the semiconductor material.

26. The radiation detector according to claim 1, further comprising a plurality guard rings concentric to the second electrode, wherein said guard rings are formed on the one of the first and second surfaces from which the second electrode extends into the bulk, and wherein said guard rings are formed from at least one of a p-type dopant and an n-type dopant.

27. The radiation detector according to claim 1, wherein the thickness of the bulk of semiconductor material ranges between 200 μm and 2000 μm.

28. The radiation detector according to claim 27, wherein the thickness of the bulk of semiconductor material ranges between 200 μm and 500 μm.

29. The radiation detector according to claim 1, wherein the predetermined distance that separates the first and second electrode ranges between 30 μm and 500 μm.

30. The radiation detector according to claim 29, wherein the predetermined distance that separates the first and second electrode ranges between 100 μm and 500 μm.

31. The radiation detector according to claim 1, wherein the width of the first electrode defining the 3D trench and the diameter of the second electrode defining the 3D column are determined based on application requirements of voltage, resistance, selection of dopant, semiconductor material, or size of the semiconductor

32. The radiation detector according to claim 1, wherein the first electrode defining the 3D trench has a predetermined trench width of raging from 5 μm to 30 μm, and the second electrode defining the 3D column has a column diameter that ranges from 5 μm to 10 μm.

33. The radiation detector according to claim 32, wherein the first electrode defining the 3D trench has a predetermined trench width of about 10 μm, and the second electrode defining the 3D column has a column diameter of about 10 μm.

34. The radiation detector according to claim 1, wherein the first electrode defining the 3D trench has a predetermined trench width which defines a dead space equal to or less than 16% of the region of the bulk contained between the first and second electrodes.

35. A multi-pixel radiation detector, comprising:
a plurality of adjacently positioned radiation detecting units that comprises: a semiconductor material having a bulk thickness and defining thereon a first surface opposite to a second surface, the second surface being separated from the first surface by said bulk thickness; a first electrode defining a three-dimensional (3D) trench and extending into the bulk from one (or both) of the first and second surfaces along the bulk thickness; and a second electrode defining a 3D column, the second electrode also extending into the bulk from one (or both) of the first and second surfaces along the bulk thickness, wherein the first electrode surrounds the second electrode such that the first and second electrodes are substantially parallel and concentric to each other, and wherein the first and second electrodes are separated from each other by a predetermined distance determined by a region of the bulk contained between the first and second electrodes, and
wherein adjacent detecting units share at least part of the first electrode.

36. The multi-pixel radiation detector according to claim 35, wherein a distance between second electrodes of two adjacent radiation detecting units is equal to twice the predetermined distance separating the first and second electrodes plus the sum of the electrode thickness.

37. A radiation detector system comprising the multi-pixel radiation detector according to claim 35, an application-specific integrated circuit (ASIC) connected to the multi-pixel radiation detector operable to receive a signal from said multi-pixel radiation detector, and a microprocessor connected with the ASIC operable to control the ASIC.

38. A strip radiation detector, comprising:
a plurality of radiation detecting units arranged next to each other,
wherein each of the radiation detecting units includes one radiation detector according to claim 7, and wherein adjacent detecting units share at least part of the first electrode.

39. A method for fabricating a radiation detector, comprising:
providing a semiconductor material having a bulk thickness and defining thereon a first surface opposite to a second surface, the second surface being separated from the first surface by said bulk thickness; and
forming, around the periphery of the bulk, a trench having a predetermined width and extending into the bulk from one (or both) of the first and second surfaces along the bulk thickness;
forming, in the center of the bulk and at a predetermined distance from the trench, a hole also having the predetermined width and extending into the bulk from one (or both) of the first and second surfaces along the bulk thickness,
doping the trench with either an n-type dopant or a p-type dopant and activating said trench dopant such that a first electrode is formed therein; and
doping the hole with either the n-type dopant or the p-type dopant and activating said hole dopant such that a second electrode is formed therein.

40. The method according to claim 39, wherein forming steps include etching or diffusing around said periphery and in said center of the bulk, respectively, a portion of semiconductor material, and
wherein said doping and activating steps include implanting and annealing, respectively, said one of the n-type dopant and the p-type dopant into each of the trench and the hole.

41. The method according to claim 40, wherein the forming steps include etching or diffusing around the periphery and in the center of the bulk of the semiconductor material, respectively, a portion of semiconductor material equal to or less than 95% of the bulk thickness of the semiconductor material.

42. The method according to claim 40, wherein the forming steps include etching or diffusing around the periphery and in the center of the bulk of the semiconductor material, respectively, extending 100% of the bulk thickness of the semiconductor material from one of the first and second surfaces to the other of the first and second surfaces.

43. The method according to claim 39, wherein the forming step includes (i) etching or diffusing around the periphery and in the center of the bulk of the semiconductor material, respectively, a portion of semiconductor material to extend the trench and the hole to less than 100% through the bulk thickness of the semiconductor material from one of the first and second surfaces towards the opposite surface, (ii) fill and doping the trench and/or the hole with either an n-type dopant or a p-type dopant, (iii) etching or diffusing around the periphery and in the center of the bulk thickness, respectively, a portion of semiconductor material from the opposite surface to match the pattern of trench/hole on the first surface to extend the trench and the hole to the remaining bulk thickness of the semiconductor up to 100% of the semiconductor material thickness, whereby the trench and the hole extends from the first to the second surface, (iv) doping the remaining portion of the trench or the hole with either an n-type dopant or a p-type dopant which match that of the first surface, and (v) activating the trench and the hole dopant such that the first and the second electrodes are formed therein.

44. The method according to claim 39, wherein forming the trench includes forming a trench having a circular cross-section or a first polygonal cross-section, and wherein forming the hole includes forming a hole having a circular cross-section or a second polygonal cross-section or a circular cross-section.

45. The method for fabricating a radiation detector according to claim 44, wherein forming the trench includes forming the trench having the circular cross-section with one or more gaps or forming the trench having the first polygonal cross-section with a gap in each side of the polygonal cross section.

46. The method for fabricating a radiation detector according to claim 44, wherein the first and second polygonal cross-sections include one of a rectangular cross-section and a hexagonal cross-section.

47. The method according to claim 46, further comprising forming a semiconductor junction at a region where the bulk of semiconductor material joins one of the first electrode and the second electrode, wherein the semiconductor junction defines one of a central junction electrode and an outer ring junction, respectively.

48. The method according to claim 44, wherein both of the steps of forming said trench and said hole are performed from the same surface of said one of the first and second surfaces.

49. The method according to claim 44, wherein each of the steps of forming said trench and said hole is performed from a different surface of said one of the first and second surfaces.

50. The method according to claim 39, wherein forming steps include implanting around said periphery and in said center of the bulk, respectively, one of a p-type and n-type ionized dopant material, to a predetermined depth equal to an average range of ions.

51. A method for fabricating a multi-pixel radiation detector, comprising:
forming a plurality of radiation detecting units arranged next to each other,
wherein each of the plurality of radiation detecting units includes one radiation detector fabricated according to the method of claim 44, and
wherein adjacent detecting units share at least part of the first electrode.

52. A detector comprising:
a semiconductor material having a first surface substantially parallel to a second surface, said second surface being separated from said first surface by a predetermined thickness of the semiconductor material, wherein
a first region of said semiconductor material is highly doped with a first conductivity type dopant to a predetermined width, said first region occupying a peripheral volume of said semiconductor material contained between the first and second surface, said first region extending from one of the first and second surfaces along said thickness of the semiconductor material,
a second region of said semiconductor material is highly doped with a second conductivity type dopant to said predetermined width, the second conductivity type dopant being different from the first conductivity type dopant, said second region occupying a central volume of said semiconductor material also contained between said first and second surfaces, said second region also extending from one of the first and second surfaces along the thickness of the semiconductor material,
said first region surrounding said second region such that the first and second regions are substantially parallel and concentric to each other, and
wherein the first and second regions are separated from each other by a predetermined distance determined by a lightly doped region of the semiconductor material contained between the first and second regions.

53. The detector according to claim 52, wherein the first and second regions extend into the semiconductor material from the first surface or from the second surface.

54. The detector according to claim 52, wherein the first and second regions extend into the semiconductor material from a different one of the first and second surfaces.

55. The detector according to claim 52, wherein the first and second regions extend into the semiconductor material a predetermined depth equal to or less than 95% of said predetermined thickness of the semiconductor material.

56. The method according to claim 52, wherein the first and second regions extends fully through the bulk thickness of the semiconductor material from one of the first and second surfaces to the other of the first and second surfaces.

57. The detector according to claim 52, wherein said first region is formed by etching and subsequently filling said peripheral volume with a material containing said first conductivity type dopant, and wherein second region is formed by etching and subsequently filling said central volume with a material containing said second conductivity type dopant.

58. The detector according to claim 52, wherein said semiconductor material is lightly doped with one of the first conductivity type dopant and second conductivity type dopant, and wherein a semiconductor junction is formed at a plane where the semiconductor material joins one of the first region and the second region.

59. The detector according to claim 52, wherein the first region defines a hexagonal trench and the second region defines a hexagonal or cylindrical column.

60. A multi-pixel detector, comprising:
a plurality of detecting units arranged next to each other,
wherein each of the plurality of detecting units includes a detector as defined in claim 36, and
wherein adjacent detecting units share at least part of the first region.

61. A radiation detector system comprising the multi-pixel radiation detector according to claim 60, an application-specific integrated circuit (ASIC) connected to the multi-pixel radiation detector operable to receive a signal from said multi-pixel radiation detector, and a microprocessor connected with the ASIC operable to control the ASIC.

62. The radiation detector according to claim 22, where the doping concentration is high enough to act as a degenerate semiconductor.

63. The radiation detector according to claim 1, wherein the semiconductor is made from a high-Z semiconductor material, the electrodes are made from conducting metal, wherein the conducting metal used for the first electrode and the conducting metal used from the second electrode may be the same or different.
